(19) United States
(12) Patent Application Publication
(10) Pub. No.: US 2025/0185442 A1
(43) Pub. Date: Jun. 5, 2025

(54) POLYMER DOPANTS FOR HIGH ELECTRON CONDUCTIVITY IN FLEXIBLE ENERGY DEVICES

(71) Applicant: THE JOHNS HOPKINS UNIVERSITY, Baltimore, MD (US)

(72) Inventors: Howard KATZ, Baltimore, MD (US); Jinfeng HAN, Baltimore, MD (US)

(73) Assignee: The Johns Hopkins University, Baltimore, MD (US)

(21) Appl. No.: 18/834,522

(22) PCT Filed: Jan. 31, 2023
(86) PCT No.: PCT/US2023/012020

§ 371 Date: Jul. 30, 2024

Related U.S. Application Data
(60) Provisional application No. 63/304,973, filed on Jan. 31, 2022.

(51) Int. Cl. H10K 10/84; C08F 8/02; C08L 65/00; H10K 10/46; H10K 85/10

(52) U.S. Cl. CPC H10K 10/84; C08F 8/02; C08L 65/00; H10K 10/462; H10K 85/113; H10K 85/141; H10K 85/151; C08F 2810/50; C08L 2203/20

(57) ABSTRACT

A polymer having the structure N⁺ Ar is a N-containing monocyclic or bicyclic aromatic ring having 1 or 2 N atoms, at least one of the N atoms is substituted with R^{a} to have a positive charge and the ring is optionally substituted with R^{b}, R^{a} is H, thiophene, furan, pyridine, benzene, thiazole, C₁-C₁₂ alkyl optionally substituted with one or more F atoms, or polyoxyethylene (—(CH₂CH₂O)ₙ—H and R^{b} is H, C₁-C₁₂ alkyl, aralkyl, or C₁-C₁₂ alkoxy. Ar is a phenyl or naphthalene ring, optionally substituted with R^{c} or CO₂Ph. Any of the phenyl or naphthalene rings is substituted with R^{c} which is H, C₁-C₁₂ alkyl, or C₁-C₁₂ alkoxy, and R^{d} is H or Me. X is halogen, bicarbonate (HCO₃⁻), carbonate, bisulfate (HSO₄⁻), bisulfite (HSO₃−), methane sulfonate (MeSO₃−). triethyl borohydride (Et₃BH⁻) or a C₁-C₆ carboxylate. The ratio of x:y is from about 99:1 to about 1:99.

### CROSS-REFERENCE TO RELATED APPLICATIONS

The present patent application claims priority benefit to U.S. Provisional Patent Application No. 63/304,973, filed on Jan. 31, 2022, the entire content of which is incorporated herein by reference. All references cited anywhere in this specification, including the Background and Detailed Description sections, are incorporated by reference as if each had been individually incorporated.

### GOVERNMENT SUPPORT CLAUSE

This invention was made with government support under grants 1708245 and 2107360 awarded by the National Science Foundation. The government has certain rights in the invention.

### BACKGROUND

### 1. Field of the Invention

The currently claimed embodiments of the present invention relate to organic conductive materials, and more specifically to polymeric dopants for N-type organic conductive materials, devices that include those materials, and methods of production thereof.

### 2. Discussion of Related Art

Many devices that interconvert types of energy (e.g., heat, light, electricity) require electrical conductors that transport only holes (positive charges) or only electrons (negative charges). These everyday devices include, but are not limited to, solar cells, light-emitting diodes (LEDs), photodetectors, and thermoelectric generators and coolers. In these devices, holes and electrons must enter or exit devices from separate contacts or be transported in the devices along separate pathways.

Energy-converting devices made from printable, flexible materials are of increasing interest. They can be applied to bendable objects such as clothing and canvas. Most flexible materials are polymers (plastics), made from repeating molecules linked to each other. Conductive polymers are already a multibillion-dollar market, though use of selective hole-conductors and electron-conductors is limited. An existing commercial plastic, poly(ethylenedioxythiophene) (PEDOT), selectively conducts holes effectively, with about 1% of the conductivity (σ) of a metal (thousands of Siemens per centimeter, S cm⁻¹) after specialized processing. Since metals are incompatible with flexible and printable formats, and those that inject electrons such as lithium are unstable in air, replacing them with polymers is technologically and economically desirable, and for many applications, a lower a would be an acceptable tradeoff for the benefits of printability and flexibility.

The key to the high σ of PEDOT is a second polymer (poly(styrenesulfonate), PSS) with stationary negative charges that balance moving positive charges. This “balancing” polymer is called a “dopant”. Materials made conductive because of an additive that becomes charged are considered “n-doped” or “p-doped” (transporting electrons or holes, respectively). There are numerous suppliers for PEDOT-PSS formulations. Surprisingly, most research on doped flexible materials use small molecules as dopants rather than polymers, despite the commercial success of PEDOT-PSS and the advantages of better-organized hole-transport pathways created by using the polymer dopant. These pathways, in which parts of the polymers are stacked in orderly ways through which charges can easily move, are desirable for more efficient generation and use of energy, to increase stability of the materials in ordinary air environments and elevated temperatures, and to allow more tolerance of variations in the concentrations of the dopants. Furthermore, there are no reported polymers that selectively conduct electrons (n-doped polymers) for which the dopant is a second polymer. Thus, a great commercial opportunity exists for more energy-efficient, thermally stable, mechanically flexible, and easily processable electron conductors using polymer dopants, such as for the compositions, methods, and uses of these materials.

N-doping so far has resulted in orders of magnitude lower σ in polymers than p-doping. Only recently, a new n-doped polymer composition showed a high σ over 120 S cm⁻¹, 10% that of typical PEDOT compositions, but only in a nitrogen-filled glove box, not in ordinary air. The most popular molecular n-dopant, known by the acronym N-DMBI, typically gives σ another ten times lower, but only in a narrow range of dopant concentrations and again, generally in nitrogen atmospheres. Therefore, there remains a need for improved electron conductors using polymer dopants, devices that use these materials and methods of producing the materials and devices.

### SUMMARY OF THE DISCLOSURE

An aspect of the present disclosure is to provide a polymer having the structure

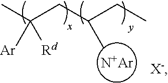

wherein N⁺ Ar is a N-containing monocyclic or bicyclic aromatic ring having 1 or 2 N atoms, at least one of the N atoms is substituted with R^{a} to have a positive charge and the ring is optionally substituted with R^{b}, wherein R^{a} is H, thiophene, furan, pyridine, benzene, thiazole, C₁-C₁₂ alkyl optionally substituted with one or more F atoms, or polyoxyethylene (—(CH₂CH₂O)ₙ—H and R^{b} is H, C₁-C₁₂ alkyl, aralkyl, or C₁-C₁₂ alkoxy, wherein any of the alkyl groups is optionally substituted with one or more F atoms; Ar is a phenyl or naphthalene ring, optionally substituted with R^{c}′ or CO₂Ph, wherein any of the phenyl or naphthalene rings is substituted with R^{c}, wherein R^{c} is H, C₁-C₁₂ alkyl optionally substituted with one or more F atoms, or C₁-C₁₂ alkoxy optionally substituted with one or more F atoms; R^{d} is H or Me; X is halogen, bicarbonate (HCO₃−), carbonate, bisulfate (HSO₄⁻), bisulfite (HSO₃⁻), methane sulfonate (MeSO₃⁻), triethyl borohydride (Et₃BH⁻) or a C₁-C₆ carboxylate; and the ratio of x:y is from about 99:1 to about 1:99.

Another aspect of the present invention is to provide a polymer having the structure

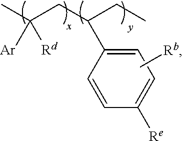

wherein Ar is a phenyl or naphthalene ring, optionally substituted with R^{e}′ or CO₂Ph, wherein any of the phenyl or naphthalene rings is substituted with R^{e}, wherein R is H, C₁-C₁₂ alkyl optionally substituted with one or more F atoms, or C₁-C₁₂ alkoxy optionally substituted with one or more F atoms; R^{b} is H, C₁-C₁₂ alkyl, aralkyl, or C₁-C₁₂ alkoxy, wherein any of the alkyl groups is optionally substituted with one or more F atoms; R^{d} is H or Me; R^{e} is

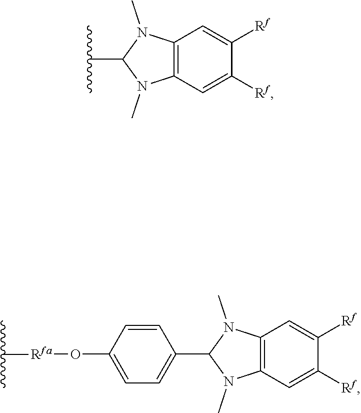

or
—CH₂N⁺R₃ X⁻ or —CH₂P⁺R₃ X⁻,
wherein R^{fa} is a chemical bond, thiophene, furan, pyridine, benzene, thiazole, or C₁-C₆ alkyl optionally having one or more oxygens substituted for carbon and optionally having one or more F atoms on the alkyl chain, R^{f} is H, thiophene, furan, pyridine, benzene, thiazole, or C₁-C₆ alkyl optionally having one or more oxygens substituted for carbon and optionally having one or more F atoms on the alkyl chain, R is C₁-C₆ alkyl and X is halogen, bicarbonate (HCO₃⁻), carbonate, bisulfate (HSO₄⁻), bisulfite (HSO₃⁻), methane sulfonate (MeSO₃⁻), triethyl borohydride (Et₃BH⁻) or a C₁-C₆ carboxylate; and the ratio of x:y is from about 99:1 to about 1:99.

Another aspect of the present invention is to provide a polymer comprising the subunit

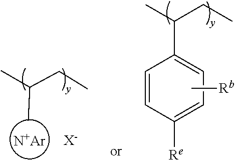

N⁺ Ar is a N-containing monocyclic or bicyclic aromatic ring having 1 or 2 N atoms, at least one of the N atoms is substituted with R^{a} to have a positive charge and the ring is optionally substituted with R^{b}, wherein R^{a} is H, thiophene, furan, pyridine, benzene, thiazole, C₁-C₁₂ alkyl optionally substituted with one or more F atoms, or polyoxyethylene (—(CH₂CH₂O)ₙ—H; R^{b} is H, C₁-C₁₂ alkyl, aralkyl, or C₁-C₁₂ alkoxy, wherein any of the alkyl groups is optionally substituted with one or more F atoms; and R^{e} is

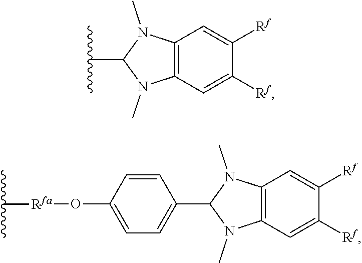

or
CH₂N⁺R₃ X⁻ or —CH₂P⁺R₃ X⁻,
wherein R^{fa} is a chemical bond, thiophene, furan, pyridine, benzene, thiazole, or C₁-C₆ alkyl optionally having one or more oxygens substituted for carbon and optionally having one or more F atoms on the alkyl chain, R^{f} is H, thiophene, furan, pyridine, benzene, thiazole, or C₁-C₆ alkyl optionally having one or more oxygens substituted for carbon and optionally having one or more F atoms on the alkyl chain, R is C₁-C₆ alkyl and X is halogen, bicarbonate (HCO₃⁻), carbonate, bisulfate (HSO₄⁻), bisulfite (HSO₃⁻), methane sulfonate (MeSO₃⁻), triethyl borohydride (Et₃BH⁻) or a C₁-C₆ carboxylate.

A further aspect of the present invention is to provide a polymer having the structure

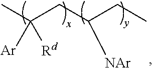

wherein NAr is a N-containing monocyclic or bicyclic aromatic ring having 1 or 2 N atoms and substituted with R^{b}, wherein R^{b} is C₁-C₁₂ alkyl, aralkyl, or C₁-C₁₂ alkoxy, wherein any of the alkyl groups is optionally substituted with one or more F atoms; Ar is a phenyl or naphthalene ring, optionally substituted with R^{c}′ or CO₂Ph, wherein any of the phenyl or naphthalene rings is substituted with R^{c}, wherein R^{c} is H, C₁-C₁₂ alkyl optionally substituted with one or more F atoms, or C₁-C₁₂ alkoxy optionally substituted with one or more F atoms; R^{d} is H or Me; the ratio of x:y is from about 99:1 to about 80:20.

### BRIEF DESCRIPTION OF THE DRAWINGS

The present disclosure, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

FIG. 1A is a plot of the electrical conductivity versus the dopant concentration, according to an embodiment of the present invention;

FIG. 1B is a plot of the Seebeck coefficient versus the dopant concentration, according to an embodiment of the present invention;

FIG. 1C is a plot of the power factor of PFClTVT films doped by various weight fractions of PSpF versus the dopant concentration, according to an embodiment of the present invention;

FIG. 2 is a plot of the electrical conductivity versus temperature showing thermal air stability of electrical conductivity after thermal treatment at 120° C. for 2 cycles of 15 min in the open air, according to an embodiment of the present invention;

FIG. 3A-3C is a structure of a solar cell, photodetector, diode, or light-emitting diode, according to an embodiment of the present invention;

FIG. 3D is a field-effect transistor device, according to an embodiment of the present invention;

FIG. 3E is a thermoelectric device, according to an embodiment of the present invention;

FIG. 4A is a UV-vis-NIR absorption spectrum of polymer dopant PSpF in solution, according to an embodiment of the present invention;

FIG. 4B is a UV-vis-NIR absorption spectrum of polymer dopant PSpF in film, according to an embodiment of the present invention;

FIG. 4C is a plot of heat flow versus temperature showing differential scanning calorimeter (DSC) traces of PSpF measured under N₂, according to an embodiment of the present invention;

FIGS. 5A and 5B show current versus voltage curves of pristine and doped polymer thin films, according to embodiments of the present invention;

FIG. 6A shows the UV-vis-NIR absorption spectra of pristine and doped PFClTVT films, according to an embodiment of the present invention;

FIG. 6B shows the EPR spectra of pristine and doped polymer in solution, according to an embodiment of the present invention;

FIG. 6C shows the ultraviolet photoelectron spectroscopy (UPS) binding energy of pristine and doped polymer films measured under −5 eV, according to an embodiment of the present invention;

FIG. 7A shows the electrical conductivity of PFClTVT films doped by various weight fractions of PSpF, according to an embodiment of the present invention;

FIG. 7B shows the Seebeck coefficient of PFClTVT films doped by various weight fractions of PSpF, according to an embodiment of the present invention;

FIG. 7C shows the power factor of PFClTVT films doped by various weight fractions of PSpF, according to an embodiment of the present invention;

FIG. 7D shows the thermal conductivity of PFClTVT films doped by various weight fractions of PSpF, according to an embodiment of the present invention;

FIGS. 8A and 8B show Seebeck coefficient (α; FIG. 8A) and power factor (α2σ; FIG. 8B) as functions of conductivity (σ) for a range of doped organic thermoelectric (OTE) polymers and composites summarized by Boris Russ et al, according to an embodiment of the present invention;

FIG. 9A shows a thermal air stability of electrical conductivity after thermal treatment at 120° C. for 2-circle 15 min in the open air, according to an embodiment of the present invention;

FIG. 9B shows a temperature-dependent electrical conductivity values of PFClTVT film doped with 30 wt % PSpF, according to an embodiment of the present invention;

FIG. 9C shows time-dependent thermoelectric voltage response under different temperature gradients ΔT, according to an embodiment of the present invention;

FIG. 10A shows the transfer curves of pristine OFET, according to an embodiment of the present invention;

FIG. 10B shows the transfer curves of wt % PSpF doped OFET, according to an embodiment of the present invention;

FIG. 10C shows output curves of pristine OFET, according to an embodiment of the present invention;

FIG. 10D shows output curves of 1 wt % PSpF doped OFET, according to an embodiment of the present invention;

FIG. 11A shows the transfer curve of OFET of 2 wt % PSpF doped polymer thin film, according to an embodiment of the present invention;

FIG. 11B shows the transfer curve of OFET of 10 wt % PSpF doped polymer thin film, according to an embodiment of the present invention;

FIG. 12A shows output curve of OFETs of 2 wt % PSpF doped polymer thin film, according to an embodiment of the present invention;

FIG. 12B shows output curve of OFETs of 10 wt % PSpF doped polymer thin films, according to an embodiment of the present invention;

FIG. 13A is an Out-of-plane GIXRD diagram of pristine and doped polymer films which are prepared similar with the thermoelectric devices, according to an embodiment of the present invention;

FIG. 13B shows Lamellar d-spacing distances of polymers doped with various weight fractions of dopant, according to an embodiment of the present invention;

FIG. 14A shows output curves of OFETs of 2 wt % PSpF doped polymer thin films, according to an embodiment of the present invention;

FIG. 14B shows output curves of OFETs of 10 wt % PSpF doped polymer thin films, according to an embodiment of the present invention;

FIG. 15A shows Atomic Force Microscope (AFM) height images of pristine and PSpF doped polymer thin films, according to an embodiment of the present invention;

FIG. 15B shows phase images of pristine and PSpF doped polymer thin films, according to an embodiment of the present invention;

FIGS. 16A-16D show SEM images of (a) pristine PFClTVT, (b) 5 wt % PSpF, (c) 50 wt % PSpF doped PFClTVT and (d) pristine PSpF films, according to embodiments of the present invention;

FIGS. 16E-16H show an EDS analysis at the even area of (e) pristine PFClTVT (spot 1), (f) 5 wt % PSpF (spot 4), (g) 50 wt % PSpF doped PFClTVT (spot 5) and (h) pristine PSpF films (spot 1), according to embodiments of the present invention;

FIG. 17 shows a conductivity versus temperature of a N-type PSpF doped polymer films, according to an embodiment of the present invention;

FIGS. 18A and 18B are plots showing a chemical shift at 8.24 ppm in PS-P is slightly up field of the known 2,6-protons of 4-methylpyridine, reasonable for the aromatic-ring media, according to an embodiment of the present invention;

FIGS. 19A and 19B show the GPC spectra of PFClTVT, according to an embodiment of the present invention;

FIG. 20 shows a GPC spectra of PS-P, according to an embodiment of the present invention;

FIG. 21 shows differential scanning calorimeter (DSC) traces of PS-P measured under nitrogen (N₂) gas atmosphere, according to an embodiment of the present invention;

FIG. 22A show UPS binding energy of the pristine and doped polymer films measured under −5 eV, according to an embodiment of the present invention;

FIG. 22B shows normalized absorption of pristine and PSpF doped PFClTVT films, according to an embodiment of the present invention;

FIG. 23 shows a plot of diffraction versus percent weight of dopant in polymer, according to an embodiment of the present invention;

FIG. 24A shows chemical structures of polymers and dopants, according to an embodiment of the present invention;

FIG. 24B shows the absorbance spectra of pristine PDPIN, N-DMBI doped PDPIN, and PSpF doped PDPIN in films, according to embodiments of the present invention;

FIG. 24C shows EPR spectra of pristine and N-DMBI and PSpF doped PDPIN in films, according to embodiments of the present invention;

FIG. 24D shows UPS binding energy of pristine and N-DMBI and PSpF doped PDPIN in films, according to embodiments of the present invention;

FIG. 25A shows a doping process of PSpF doped PDPIN, according to an embodiment of the present invention;

FIG. 25B shows a calculated binding energy and electron affinity of adducts of F⁻, TMAF (model molecule of TBAF) and MPSpF (model molecule of PSpF) and repeat unit DPIN of PSPF, according to an embodiment of the present invention;

FIG. 26A shows a plot of the electrical conductivity of PSpF, according to an embodiment of the present invention.

FIG. 26B shows a plot of the Seebeck coefficient of PSpF, according to an embodiment of the present invention;

FIG. 26C shows a plot of the power factor of PSpF, according to an embodiment of the present invention;

FIG. 26D shows a plot of the electrical conductivity of N-DMBI doped PDPIN, according to an embodiment of the present invention;

FIG. 26E shows a plot of the Seebeck coefficient of N-DMBI doped PDPIN, according to an embodiment of the present invention;

FIG. 26F shows a plot of the power factor of N-DMBI doped PDPIN, according to an embodiment of the present invention;

FIG. 27A shows AFM height image and GIWAXS pattern of a pristine PDPIN, according to an embodiment of the present invention;

FIG. 27B shows AFM height image and GIWAXS pattern of a 5 mol % N-DMBI doped PDPIN film, according to an embodiment of the present invention;

FIG. 27C shows AFM height image and GIWAXS pattern of a 30 mol % N-DMBI doped PDPIN film, according to an embodiment of the present invention;

FIG. 27D shows AFM height image and GIWAXS pattern of a 75 mol % N-DMBI doped PDPIN film, according to an embodiment of the present invention;

FIG. 27E shows AFM height image and GIWAXS pattern of 5 wt % PSpF doped PDPIN film, according to an embodiment of the present invention;

FIG. 27F shows AFM height image and GIWAXS pattern of 50 wt % PSpF doped PDPIN film, according to an embodiment of the present invention;

FIG. 27G shows AFM height image and GIWAXS pattern of 100 wt % PSpF doped PDPIN film, according to an embodiment of the present invention;

FIG. 27H shows the π-π stacking distance of N-DMBI film, according to an embodiment of the present invention;

FIG. 27I shows the π-π stacking distance of PSpF doped PDPIN film, according to an embodiment of the present invention;

FIG. 28A shows the Seebeck coefficient of TBAF, N-DMBI and PSpF doped PDPIN at similar electrical conductivity levels, according to an embodiment of the present invention;

FIG. 28B shows the Seebeck coefficient of TBAF and N-DMBI doped PDPIN at similar electrical conductivity levels, according to an embodiment of the present invention;

FIG. 28C shows the thermal conductivity of N-DMBI doped films, according to an embodiment of the present invention;

FIG. 28D shows the ZT of PSpF doped films, according to an embodiment of the present invention;

FIG. 29A is a plot of Air stability of electrical conductivity of 5 mol % N-DMBI doped PDPIN film, according to an embodiment of the present invention;

FIG. 29B is a plot of Seebeck coefficient of 5 mol % N-DMBI doped PDPIN, film according to an embodiment of the present invention;

FIG. 29C is a plot of power factor of 75 wt % PSpF doped PDPIN film, according to an embodiment of the present invention;

FIG. 29D is a plot of Air stability of electrical conductivity of 5 mol % N-DMBI doped PDPIN film, according to an embodiment of the present invention. FIG. 29E is a plot of Seebeck coefficient of 5 mol % N-DMBI doped PDPIN film, according to an embodiment of the present invention;

FIG. 29F is a plot of power factor of 5 mol % N-DMBI doped PDPIN film, according to an embodiment of the present invention;

FIG. 29G is a plot of change of electrical conductivity of PSpF doped PDPIN film, according to an embodiment of the present invention;

FIG. 29H is a plot of power factor of PSpF doped PDPIN film after 75 days relative to initial conductivity, according to an embodiment of the present invention;

FIG. 29I is a plot of the time-dependent thermoelectric potential responses of 75 wt % PSpF doped PDPIN film, according to an embodiment of the present invention;

FIG. 29J is a plot of change of electrical conductivity of N-DMBI doped PDPIN film after 75 days relative to initial conductivity, according to an embodiment of the present invention;

FIG. 29K is a plot of power factor of N-DMBI doped PDPIN film after 75 days relative to initial conductivity, according to an embodiment of the present invention; and

FIG. 29L is a plot of the time-dependent thermoelectric potential responses of 5 mol % N-DMBI doped PDPIN film, according to an embodiment of the present invention.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed, and other methods developed without departing from the broad concepts of the present invention. All references cited anywhere in this specification are incorporated by reference as if each had been individually incorporated.

Accordingly, Tetrabutylammonium fluoride (TBAF) and molecular complexes⁷ of ammonium cations (N⁺) and F anion (F⁻) are shown to be effective n-dopants for conjugated polymers according to some embodiments of the current invention. The chemical structure of PSS inspired us to combine polystyrene (PS) itself and N⁺ and F⁻ ions for design and synthesis of a polymeric n-type dopant. Pyridine has a similar chemical structure to benzene, and can react with halohydrocarbon to achieve N⁺. The copolymer dopant PSpF can enhance n-doping ability while retaining the processing and stability associated with PS. The n-type conjugated polymer PFClTVT, with the following chemical formula, presents excellent n-doping performance with N-DMBI, here we dope it with PSpF, having the following chemical formula, for n-type conductive and thermoelectric polymer compositions.

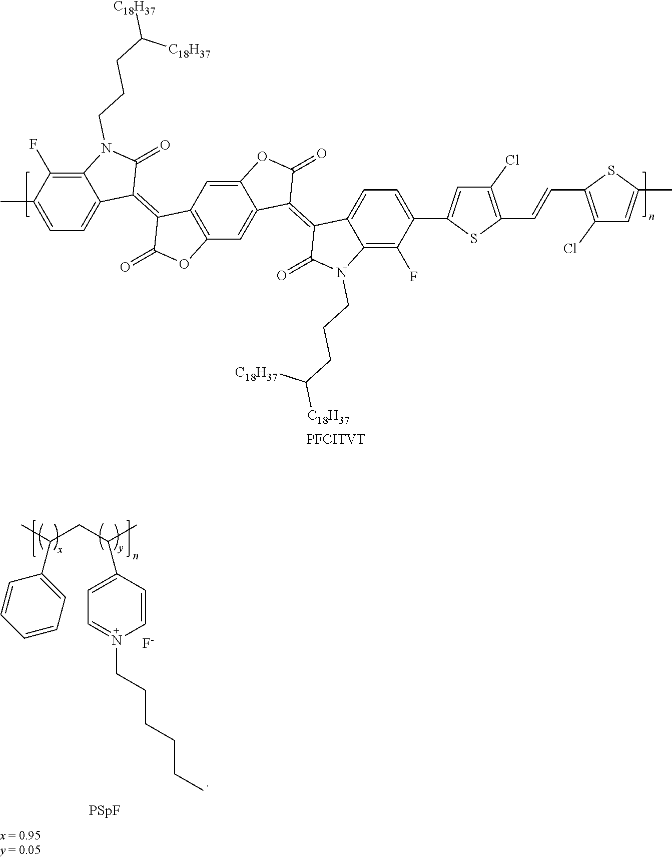

The highest room temperature σ was 4.2 S cm⁻¹, and high g of 58 S cm⁻¹ was detected at 88° C., all in air. Furthermore, an unusually high thermoelectric energy conversion power factor (PF), of 60 μW m⁻¹ K⁻² was achieved, double that of most other flexible n-type materials, and again measured in ordinary air. This is accompanied by low thermal conductivity (0.2 W/m K), which is also desirable for thermoelectric modules.

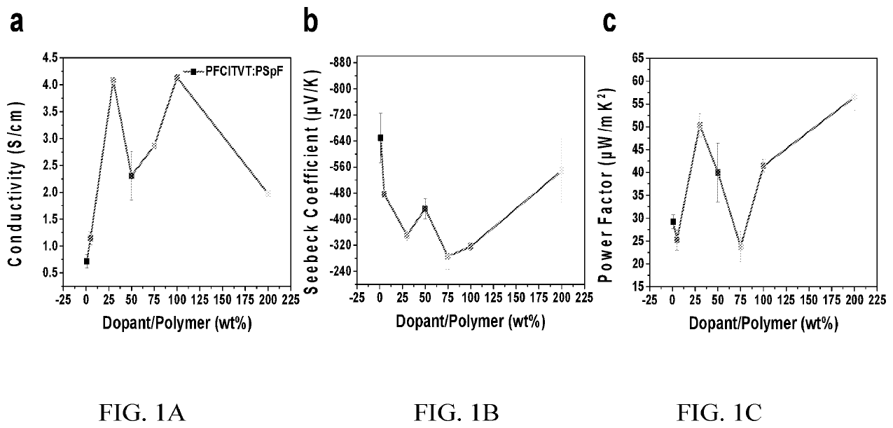

FIG. 1A is a plot of the electrical conductivity versus the dopant concentration, according to an embodiment of the present invention. FIG. 1B is a plot of the Seebeck coefficient versus the dopant concentration, according to an embodiment of the present invention. FIG. 1C is a plot of the power factor of PFClTVT films doped by various weight fractions of PSpF versus the dopant concentration, according to an embodiment of the present invention. The a of doped polymer films was examined by a four-probe method and the Seebeck coefficients were determined by detecting the thermoelectric voltages under different temperature gradients ΔT. All of the measurements were performed in the open air. All the >1% doped films exhibit reasonably high σ over 1 S cm⁻¹ (FIGS. 1A-1C). Polymers with 30 and 100 wt % PSpF doping show σ of 4.1 and 4.2 S cm⁻¹, respectively, indicating PSpF doped polymer films can give effective electron transport over a broad range of dopant concentration, which is very different from N-DMBI doped films, suggesting a broad process window for polymer dopant PSpF. The Seebeck coefficients (S, volts per temperature difference) for 1, 5, 30, 50, 75, 100 and 200 wt % are (negative) 649±75, 476.5±7.5, −351±17, −432±31, −286±40, −316±11 and 550±100 μV K⁻¹, respectively; the S are relatively consistent in the PSpF fraction range between 1-200 wt % compared to N-DMBI-based devices,⁹ suggesting high concentration-tolerance of PSpF doping. The highest PF of 60 (57±3) μW m⁻¹ K⁻² was achieved for 200 wt % PSpF doped films with the contribution of relatively high σ and S (FIG. 1C). PFClTVT doped by 30 wt % PSpF exhibits relatively high σ and PF of 4.1 S cm⁻¹ and 55 μW m⁻¹ K⁻², respectively. The lowest PF is 18.3 (25.2.±6.9) μW m⁻¹ K² with 75 wt % PSpF doping; Even that PF is still much higher than for most n-type organic thermoelectrics.¹¹ The negative Seebeck coefficients indicate electron conductivity, which is the most important criterion for this material to be used in leads for solar cells and LEDs.

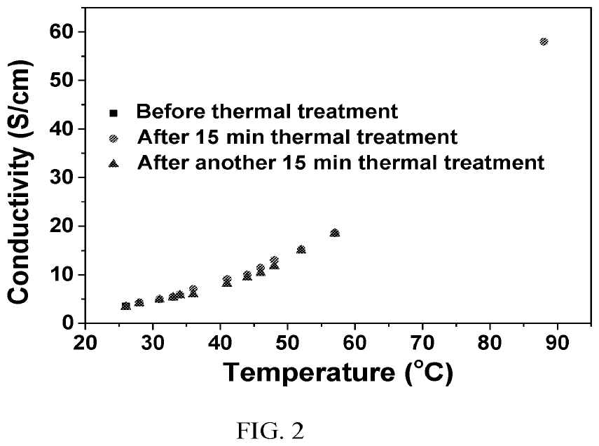

FIG. 2 is a plot of the electrical conductivity versus temperature showing thermal air stability of electrical conductivity after thermal treatment at 120° C. for 2 cycles of 15 min in the open air, according to an embodiment of the present invention. The thermal stability was determined by recording a of films with 75 wt % PSpF doping before and after thermal treatment at 120° C. for 2 cycles of 15 min in the open air. The a at room temperature was 3.45 S cm⁻¹ before thermal treatment; after 2 cycles of 15 min thermal treatment, σ of 3.39 S cm⁻¹ was achieved, an insignificant 2% decrease (FIG. 2). The σ values decreased about 1-10% at 28-57° C., exhibiting excellent thermal stability in the open air. The doped film also shows good ambient stability; the σ was 2.35±0.27 S cm⁻¹ upon 9 days exposure to air, which only decreased 24-40%. Considering that the thickness of the films was only 100-300 nm, meaning much of it was in direct contact with the air, the ambient stability is outstanding. The stability is mainly contributed by the long alkyl chains in PFClTVT and fragments of PS in PSpF. Electron mobility plays a key role in electrical conductivity, according to the formula σ=neμ, where n is carrier density, e is electron charge and μ is the corresponding carrier mobility. To measure the electron mobility of doped polymer films, organic field effect transistors (OFETs) with top-gate/bottom-contact (TGBC) configuration were prepared and studied. PFClTVT with 1 wt % PSpF doping shows a high electron mobility of 0.81±0.05 cm² V⁻¹ s⁻¹, much higher than the mobility of undoped PFClTVT of 0.24±0.04 cm²V⁻¹ s⁻¹. The results are also further supported by a Hall effect measurement. A high electron mobility of 1.70 cm²V⁻¹ s⁻¹ was achieved in 50 wt % PSpF doped PFClTVT films, which is much higher than 0.97 cm²V⁻¹ s⁻¹ in pristine PFClTVT films. The parameters discussed in this section are for just a single polymer-dopant pair. There are many compositional and processing variables that can be optimized to increase these parameters further. For example, using stabilizing monomers larger than styrene will increase the organization of the conductive pathways and decrease sensitivity to air.

Accordingly, some embodiments of the current invention are directed to a polymer having the following structure.

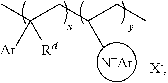

wherein N⁺ Ar represents a N-containing monocyclic or bicyclic aromatic ring having 1 or 2 N atoms. According to this embodiment, at least one of the N atoms is substituted with R^{a} to form a positive charge. R^{a} can be H, a thiophene, a furan, a pyridine, a phenyl ring, a thiazole, a C₁-C₁₂ alkyl group which may be substituted with one or more F atoms in place of H, or a polyoxyethylene (—(CH₂CH₂O)ₙ—H) chain. The N-containing monocyclic or bicyclic aromatic ring may optionally be substituted with one or more groups R^{b}, wherein R^{b} is H, C₁-C₁₂ alkyl, aralkyl, or C₁-C₁₂ alkoxy, wherein the alkyl group or alkyl chain of the alkoxy group is optionally substituted with one or more F atoms.

Ar is —CO₂Ph, or a phenyl or naphthalene ring, which may be formed from, for example a phenyl (meth)acrylate, a styrene or a vinyl naphthalene. Any phenyl or naphthalene ring in Ar may be optionally substituted with one or more groups R^{c} in which is C₁-C₁₂ alkyl optionally substituted with one or more F atoms, or C₁-C₁₂ alkoxy optionally substituted with one or more F atoms. R^{d} can be H or Me. X is one or more counterions associated with the positively charge nitrogen or nitrogens and can be halogen (F, Cl, Br, or I), bicarbonate (HCO₃⁻), carbonate, bisulfate (HSO₄⁻), bisulfite (HSO₃⁻), methane sulfonate (MeSO₃⁻), triethyl borohydride (Et₃BH⁻) or a C₁-C₆ carboxylate. The ratio of x:y is from about 99:1 to about 1:99, for example from about 95:1 to about 80:20, or is from about 95:5 to about 90:10. In some embodiments, N⁺ Ar is as follows.

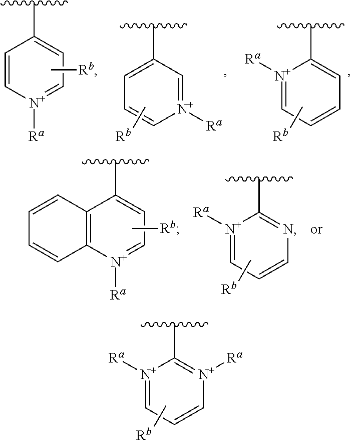

An exemplary polymer has the following structure.

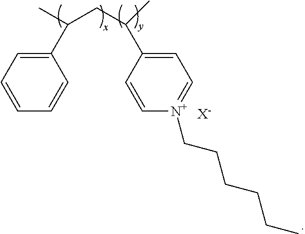

In other embodiments, the invention is a polymer having the following structure.

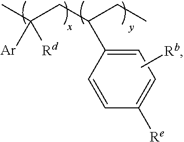

wherein Ar, R^{b} and R^{d} are as described above and R^{e} is

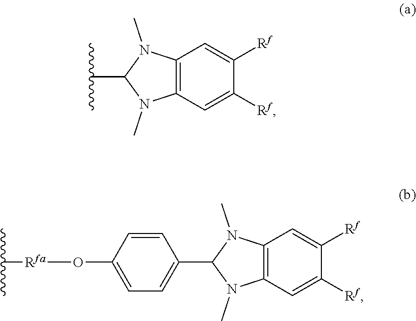

(c) —CH₂N⁺R₃ X⁻ or (d) —CH₂P⁺R₃ X⁻. R^{fa} can be a chemical bond, thiophene, furan, pyridine, benzene, thiazole, or C₁-C₆ alkyl optionally having one or more oxygens substituted for carbon and optionally having one or more F atoms on the alkyl chain, and R^{f} is H, thiophene, furan, pyridine, benzene, thiazole, or C₁-C₆ alkyl optionally having one or more oxygens substituted for carbon and optionally having one or more F atoms on the alkyl chain. In —CH₂N⁺R₃ X⁻ or —CH₂P⁺R₃, X⁻ R is C₁-C₆ alkyl, for example butyl, and X is as defined above. The ratio of x:y is from about 99:1 to about 1:99, for example from about 95:1 to about 80:20, or is from about 95:5 to about 90:10. In an exemplary embodiment, R^{f} is H and R^{fa} is a bond.

In any embodiment of the invention, Ar is a phenyl or naphthalene ring, optionally substituted with R^{c} and R^{d} is H.

In other embodiments, the invention is a polymer that includes either

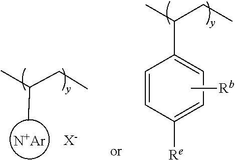

as a subunit, i.e. as a unit derived from a monomer or derivatized from a suitable monomer. N⁺ Ar, R^{b}, R^{c} and X⁻ are as described above. In exemplary embodiments, N⁺ Ar is

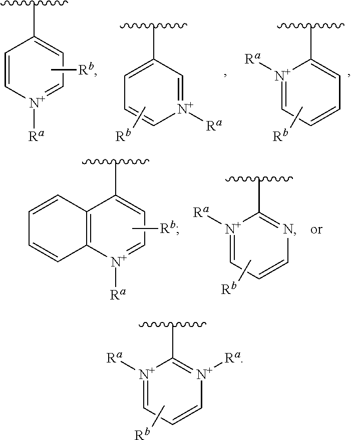

In other exemplary embodiments, R is butyl. Is other exemplary embodiments, R^{f} is H and R^{fa} is a bond.

In any embodiment of the invention, X is preferably Br or F, preferable F.

Polymers of the invention described herein can be a dopant for use with a conducting polymer and thus included in a composition with a conducting polymer, for example a composition containing about 75% dopant and about 25% conducting polymer. Here, the intended meaning is wt % of dopant relative to 100% of conjugated polymer. For example, “100%” doped actually means 50% dopant and 50% conjugated polymer. An exemplary dopant has the following chemical formula.

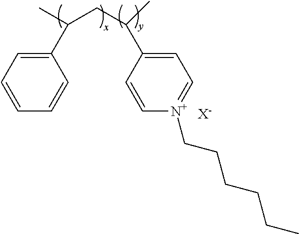

Exemplary conducting polymers for use with dopants polymers of the invention can have the following chemical structure.

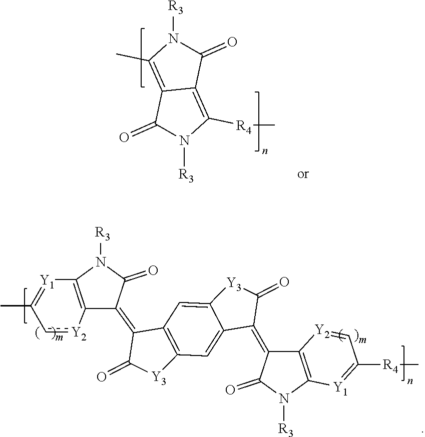

In such structures, Y₁ and Y₂ are independently —CH—, —S—, —O—, —N═, —NR₃—; Y₃ is O or NR₃; R₃ is C₁-C₁₂ alkyl optionally substituted with one or more F atoms; and R₄ is vinyl, acetylene, or a five or six membered aromatic ring optionally having one or two heteroatoms independently selected from N, S, and O. The variable m can be 0 or 1 When m is 0, Y₂ is —S—, —O—, or —NR₃—, and [symbol] is a single bond, thus forming, for example, a thiophene, furan, pyrrole, thiazole and the like. When m is 1, Y₂ is —CH or —N═, and [symbol] is a double bond, thus forming a phenyl or pyridinyl ring. Accordingly, exemplary embodiments of conducting polymers include:

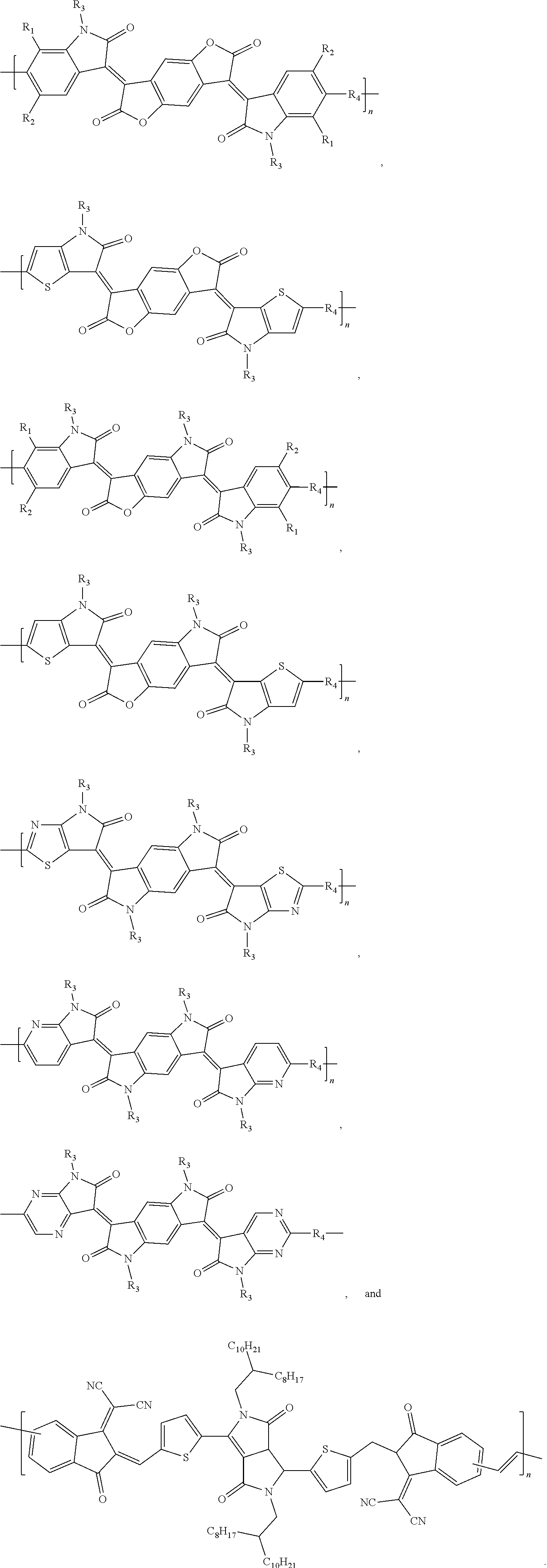

According to embodiments, R₁ and R₂ are independently H, a halogen, —CN, C₁-C₁₂ alkyl or C₁-C₁₂ alkoxy, R₃ is C₁-C₁₂ alkyl optionally substituted with one or more F atoms, and R₄ is a five or six membered aromatic ring optionally having one or two heteroatoms independently selected from N, S, and O, vinyl or acetylene. In exemplary embodiments, R₄ is thiophene, furan, pyridine, benzene, thiazole, phenyl, or a derivative thereof. In another exemplary composition according to the invention, the conducting polymer is as follows

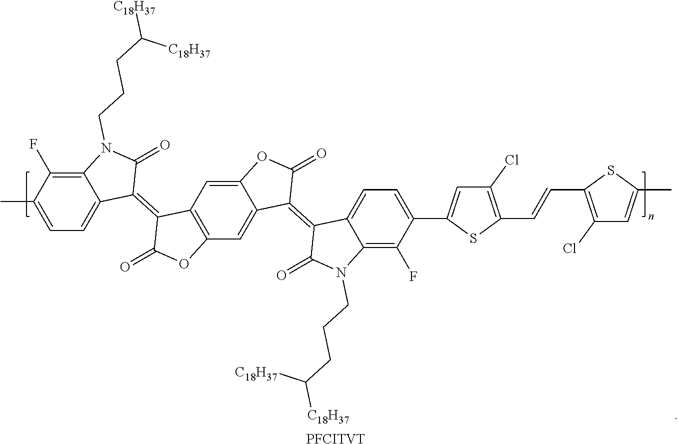

In other embodiments, the invention is a polymer having the following structure.

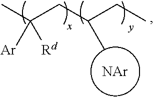

wherein NAr is a N-containing monocyclic or bicyclic aromatic ring having 1 or 2 N atoms and substituted with R^{b}, wherein R^{b} is C₁-C₁₂ alkyl, aralkyl, or C₁-C₁₂ alkoxy, wherein any of the alkyl groups is optionally substituted with one or more F atoms. Ar, R^{d} and the ratio of x:y, including exemplary and preferred values, are as described above.

Some electronic devices require separate transport of electrons and holes, and/or maintaining voltages on two sides of a semiconductor.

These include diodes, solar cells, light-emitting diodes, and thermoelectric devices. Some embodiments of polymers as described above can be used to provide organic, printable, and flexible versions of these devices, for example. Further embodiments can include fuel cells and optoelectronic stimulation of biological cells and tissues, for example.

Accordingly, some embodiments of the current invention are directed to electronic and/or electro-optic devices that use any one or more of the above-noted polymers.

Some embodiments of the current invention are directed to an electronic and/or electro-optic device comprising at least one polymer as described above.

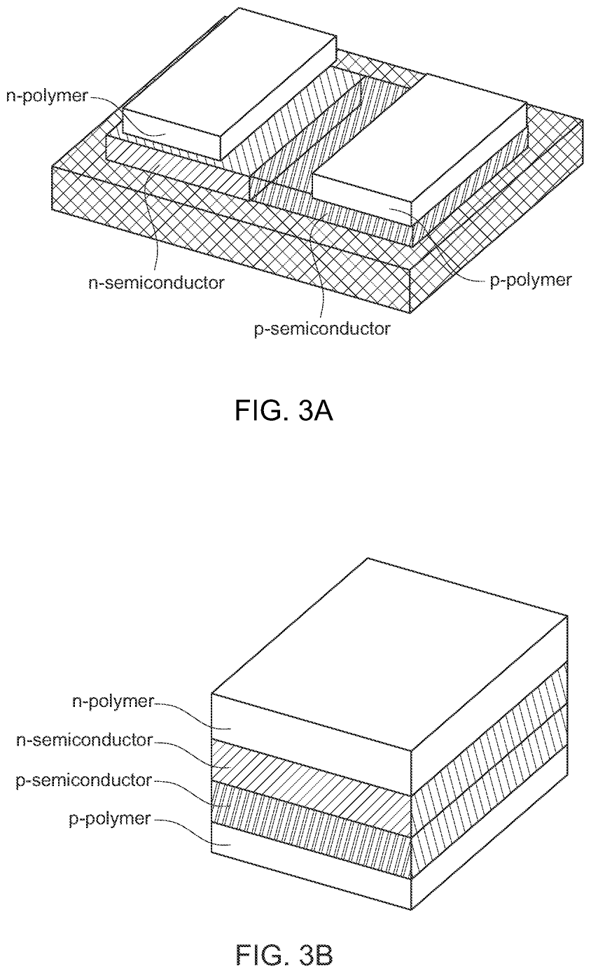

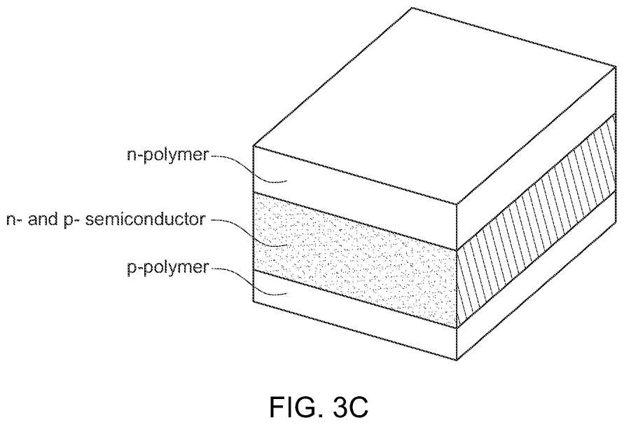

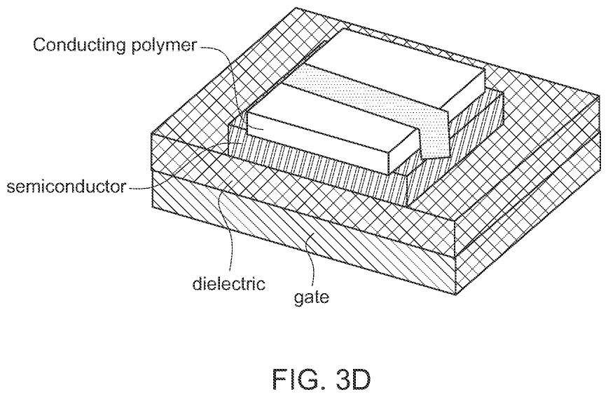

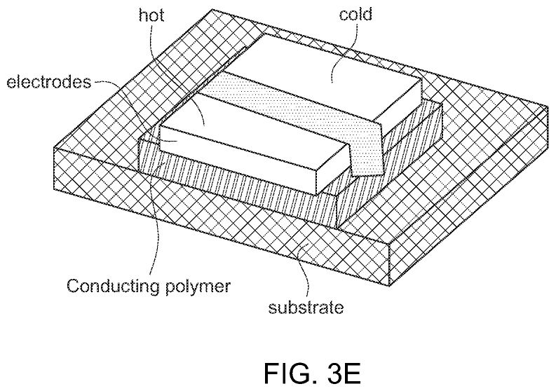

Some embodiments of the current invention are directed to a device that includes a first electrode; a second electrode spaced apart from the first electrode; and at least one of an electrically conducting or semiconductor material arranged between the first and second electrodes. At least one of the first and second electrodes comprises at least one polymer as described above. FIGS. 3A-3E show few examples of a device that includes a first electrode and a second electrode, and at least one of an electrically conducting or semiconductor material arranged between the first and second electrodes, according to an embodiment of the present invention. However, the general concepts of devices according to embodiments of the current invention are not limited to only these examples. FIG. 3A-3C is a structure of a solar cell, photodetector, diode, or light-emitting diode, according to an embodiment of the present invention. In FIGS. 3A-3C, the n-polymer electrodes can include at least one polymer according to an embodiment of the current invention. FIG. 3D is a field-effect transistor device, according to an embodiment of the present invention. FIG. 3E is a thermoelectric device, according to an embodiment of the present invention. In FIGS. 3D and 3E, one of the top electrodes can include at least one polymer according to an embodiment of the current invention, for example, as described above. In FIG. 3D, the gate electrode can optionally include at least one polymer according to an embodiment of the current invention, for example, as described above. In FIG. 3E, the “conducting polymer” can optionally include at least one polymer according to an embodiment of the current invention. The schematic illustrations of FIGS. 3A-3E can include devices with multilayered structures for any of the layers shown in alternative embodiments. For example, various buffer layers may be included between or as part of other layers.

EXAMPLES: Further examples are described in detail in a section at the end of this specification. The broad concepts of the current invention are not intended to be limited to the particular examples.

A novel n-type copolymer dopant polystyrene-polyvinyl hexylpyridinium fluoride PSpF with fluoride anion is designed and synthesized by reversible addition-fragmentation chain transfer (RAFT) polymerization. To our knowledge, it is the first polymeric n-type dopant, and certainly the first polymeric fluoride dopant. It thus serves as a counterpart to the widely used polystyrenesulfonate p-type dopant for n-type organic thermoelectrics. Electrical conductivity of 4.2 S cm⁻¹ and high power factor of 60 μW m⁻¹ K⁻² are achieved for PSpF doped polymer films, with a corresponding decrease in thermal conductivity as the PSpF concentration is increased, giving the highest ZT of 0.1. An especially high electrical conductivity of 58 S cm⁻¹ at 88° C. and outstanding thermal stability were recorded. Further, organic transistors of PSpF doped thin films exhibit high electron mobility and Hall mobility of 0.86 and 1.70 cm²V⁻¹ s⁻¹, respectively. The results suggest that polystyrene-polyvinyl pyridinium salt copolymers with fluoride anion are promising for high performance n-type all-polymer thermoelectrics. This work provides a new way to realize organic thermoelectrics with high conductivity relative to Seebeck coefficient, high power factor, thermal stability and broad processing window.

N-doping has been employed as a crucial process for organic transistors, solar cells, organic light-emitting diodes and photocatalysts. Recently n-doping for use in organic thermoelectrics was studied extensively to control carrier density and electrical conductivity. Organic thermoelectrics (OTEs) can enable emergent applications in large area and flexible/wearable green energy-harvesting devices, which can convert the heat from the human body into electricity. Power factor (PF, see below) is commonly used for evaluating the performance of organic thermoelectrics. For example dilute sulfuric acid-treated poly(3,4-ethylenedioxythiophene):poly(4-styrenesulfonate) (PEDOT:PSS) exhibit high electrical conductivity ≥3000 S cm⁻¹, that can equal to or exceed that of indium tin oxide (ITO) or metal electrodes. PSS is an ideal p-type dopant for PEDOT and helps make PEDOT:PSS a promising organic thermoelectric material. Benefitting from high electrical conductivity, PEDOT:PSS has also been used as a hole-transporting interface material and as electrodes for organic solar cells. N-type doping results in much lower σ than p-doping with most σ less than 1 S cm⁻¹, and usually uses small molecule n-dopants, such as 4-(1,3-dimethyl-2,3-dihydro-1H-benzoimidazol-2-yl)phenyl)dimethylamine (N-DMBI), tetrakis(dimethylamino)ethylene (TDAE), tetra-n-butylammonium fluoride (TBAF) and a polycyclic triaminomethane (TAM) donor.

Recently, the design and synthesis of novel n-type conjugated polymers themselves has been the primary focus. The Lei group reported a new polymer P(PzDPP-2FT) with a zigzag backbone doped with CoCp₂ showing a high electrical conductivity over 120 S cm⁻¹. The acceptor-acceptor polymer with electron-deficient double B←N bridged bipyridine unit was proved to be an excellent organic thermoelectric material. N-DMBI is usually used as n-dopant for organic thermoelectrics. However, the relatively low value of conductivity relative to Seebeck coefficient of N-DMBI-based devices results in relatively low power factor. In addition, high electrical conductivity of organic thermoelectrics based on N-DMBI and similar dopants can only be achieved from narrow and limited dopant concentrations. For example, FBDPPV doped by N-DMBI exhibits a high electrical conductivity of 12 S cm⁻¹, however, conductivity over 1 S cm⁻¹ was only achieved between N-DMBI concentration of 3 and 15 wt %. The thermoelectric performance of polymers is usually evaluated by ZT and power factor (PF) are as follows.

$$ZT = \frac{{S}^{2} σ T}{K} \qquad ( 1 )$$

$$PF = {S}^{2} σ \qquad ( 2 )$$

In which, S is Seebeck coefficient, σ is electrical conductivity, T is absolute temperature, K is thermal conductivity. Currently the common way to enhance the thermoelectric efficiency of polymers is increasing the S and σ, because conjugated polymers usually show similar K. Though the K of conjugated polymers is much lower than those of electrically conductive inorganic materials, it's still can be decreased to enhance the ZT. Polystyrene (PS) usually presents much lower thermal conductivity (0.03-0.18 W m⁻¹ K⁻¹) than the conjugated polymers (0.3-0.5 W m⁻¹ K⁻¹), so it can be useful to decrease thermal conductivity while increasing electrical conductivity by introducing polystyrene into dopants.

To our knowledge, polymeric n-type dopants for n-type conjugated polymers, analogous to PSS for PEDOT have not yet reported. One approach to increasing conductivity and maintaining high mobility while doping is to keep the dopant counterions from interfering with the transporting polymer structure. Dopant polymers that might segregate from conjugated polymers offer this opportunity. PSS is a PS derivative with a sulfonic acid group, which making it an ionic polymer. Previously, TBAF and the Meisenheimer complexes NDI-TBAF containing ammonium cation (N⁺) and F anion (F⁻) were proved to be effective n-type dopants for conjugated polymers. The chemical structure of PSS inspired us to combine PS and the ions of N⁺ and F⁻ for design and synthesis of a polymeric n-type dopant. Pyridine has a similar chemical structure to benzene, and can react with halohydrocarbon to achieve N⁺. The copolymer dopant PSpF can enhance n-doping ability and maintain the ambient stability of PS. The n-type conjugated polymer PFClTVT, having the following chemical structure, presents excellent n-doping performance with N-DMBI; here we use it to dope with PSpF, having the following chemical structure, for n-type organic thermoelectrics. The highest σ of 4.2 S cm⁻¹ and PF of 60 μW m⁻¹ K⁻² are achieved at room temperature, and high σ of 58 S cm⁻¹ was detected at 88° C. Following are chemical structures of n-type conjugated polymer PFClTVT and dopant polymer PSpF, according to an embodiment of the present invention.

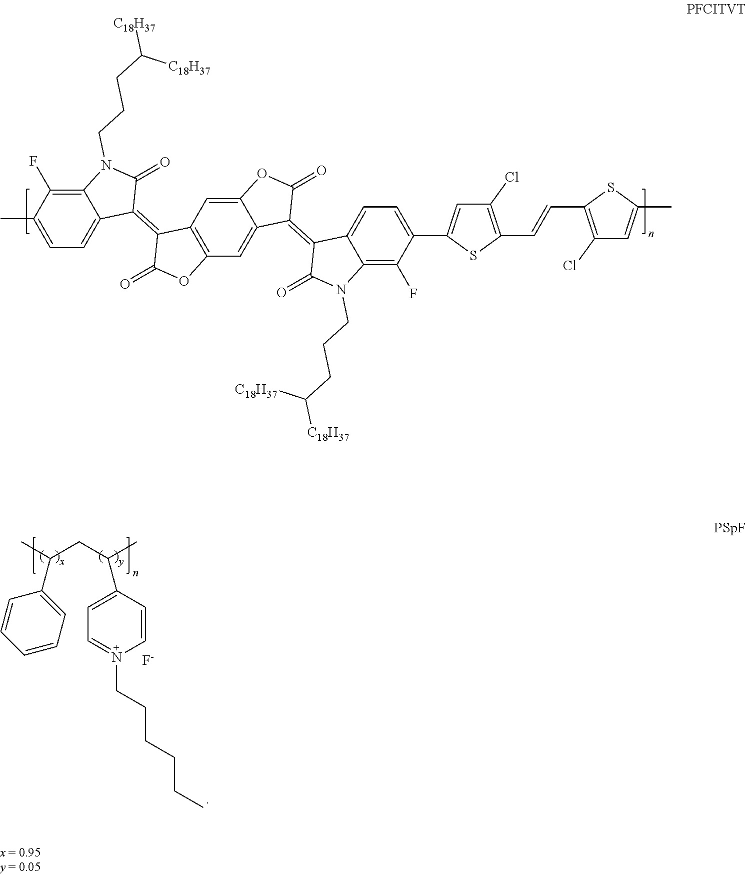

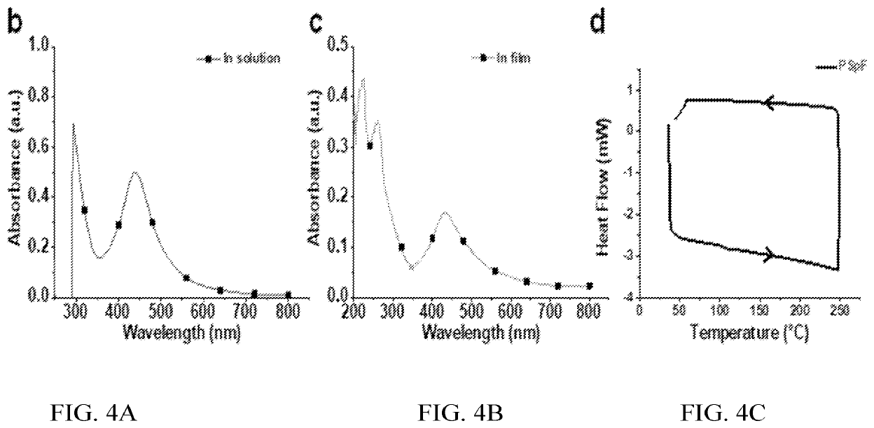

FIG. 4A is a UV-vis-NIR absorption spectrum of polymer dopant PSpF in solution, according to an embodiment of the present invention. FIG. 4B is a UV-vis-NIR absorption spectrum of polymer dopant PSpF in film, according to an embodiment of the present invention. FIG. 4C is a plot of heat flow versus temperature showing differential scanning calorimeter (DSC) traces of PSpF measured under N₂, according to an embodiment of the present invention. The polystyrene-polyvinyl pyridine (PS-P) copolymer with 5 mol % pyridine rings was synthesized by RAFT living radical polymerization with molecular weight of 334.1 kDa. The copolymer PSpBr containing Br⁺ was achieved by nucleophilic substitution with bromohexane (supporting information). A PS-P-based polymer dopant PSpF was obtained from PSpBr by ion exchange reaction. The absorption spectra of PSpF in solution are shown in FIG. 4A where two absorption peaks were detected at 294 and 440 nm, respectively. The peaks can be attributed to the absorption of polystyrene and fluoride polypyridine salt, respectively. As shown in FIG. 4B, the PSpF film had three absorption peaks at 224, 260 and 431 nm, respectively; the blue shifts of 34 and 9 nm were observed in the absorption of polystyrene and polypyridine salt, respectively. In FIG. 4C, the differential scanning calorimeter (DSC) traces of polymer PS-P and PSpF were measured under N₂ between 40 and 250° C. The glass transition temperatures (T_{g}) of PS-P and PSpF are 114 and 109° C., respectively. The relatively lower T_{g} of PSpF is related to the hexyl sidechains on pyridine.

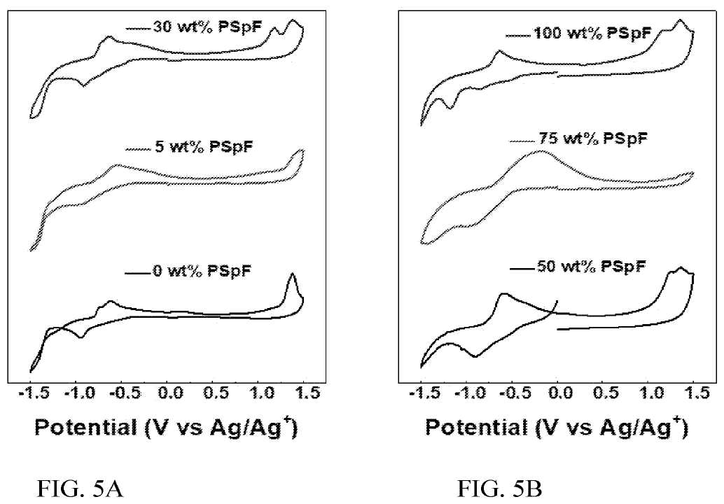

Cyclic voltammetry (CV) measurement with Ag/Ag⁺ as reference electrode was performed to determine the energy levels of the doped polymer thin films. The lowest unoccupied molecular orbital (LUMO)/highest occupied molecular orbital (HOMO) energy levels are −4.18/−5.45, −4.10/−5.77, −4.24/−5.57, −4.20/−5.29, −4.15/−5.26 and −4.27/−5.45 eV for 0, 5, 30, 50, 75, 100 wt % PSpF doped films, respectively (FIGS. 5A and 5B), fairly independent of doping level, although it happens that the films with 30 and 100 wt % PSpF show the highest σ and the lowest LUMO energy levels. FIGS. 5A and 5B show current versus voltage curves of pristine and doped polymer thin films, according to embodiments of the present invention.

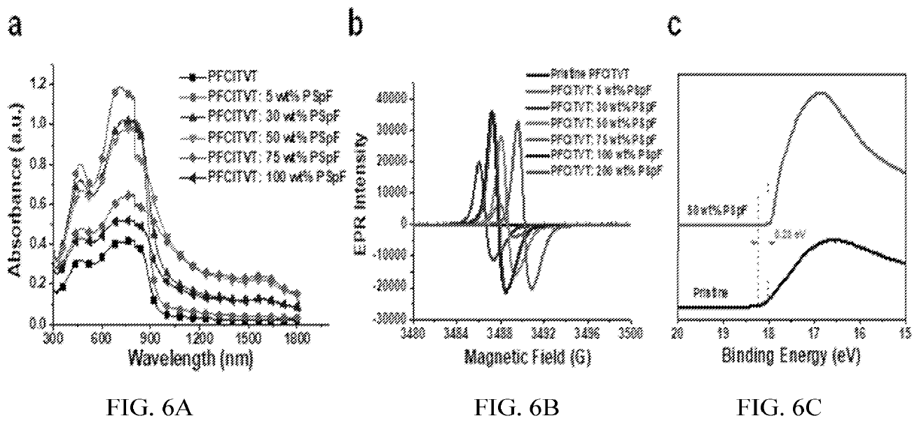

FIG. 6A shows the UV-vis-NIR absorption spectra of pristine and doped PFClTVT films, according to an embodiment of the present invention. FIG. 6B shows the EPR spectra of pristine and doped polymer in solution, according to an embodiment of the present invention. FIG. 6C shows the ultraviolet photoelectron spectroscopy (UPS) binding energy of pristine and doped polymer films measured under −5 eV, according to an embodiment of the present invention. The pristine film displays two absorptions peaks at 465 and 777 nm, which can be attributed to π-π* transition and intramolecular charge transfer. With 5 wt % PSpF doping, stronger absorption was detected in the low energy region of 1000-1800 nm, contributed by polaron/bipolaron transitions and similar to N-DMBI doped films. However, the absorption of neutral N-DMBI doped films is usually bleached, here the absorption intensity increases with PSpF doping, different from N-DMBI-doped films. When the weight fraction of PSpF increases to 30 wt %, absorption in the low energy region is much stronger and two new weak absorption peaks at 1350 and 1596 nm appear. With the weight fraction of PSpF increasing from 30 to 75 wt %, the two peaks become stronger and the neutral absorption in the high energy region becomes weaker but is still stronger than for pristine PFClTVT. The absorption result demonstrates that effective doping occurs in films of PFClTVT:PSpF.

FIG. 6B shows the electron paramagnetic resonance (EPR) spectra of pristine and doped PFClTVT solution. There is no radical peak for pristine PFClTVT solution, while an obvious radical peak was detected in 5 wt % PSpF doped solution that is at the similar magnetic field with N-DMBI doped polymers. When PSpF fraction increases to 50 and 100 wt %, the EPR intensity is much stronger than 5 wt % PSpF doped solution, and further proves the effective doping by PSpF.

FIG. 6C shows the ultraviolet photoelectron spectroscopy (UPS) spectra. The secondary electron cutoff of PFClTVT doped by 50 wt % PSpF shifts by −0.23 eV, suggesting a downward movement of its Fermi level by 0.23 eV which is similar to the TBAF doped polymer films and could be from associations of the doped polymer with multiple cations of the dopant or a surface voltage induced by the dopant.

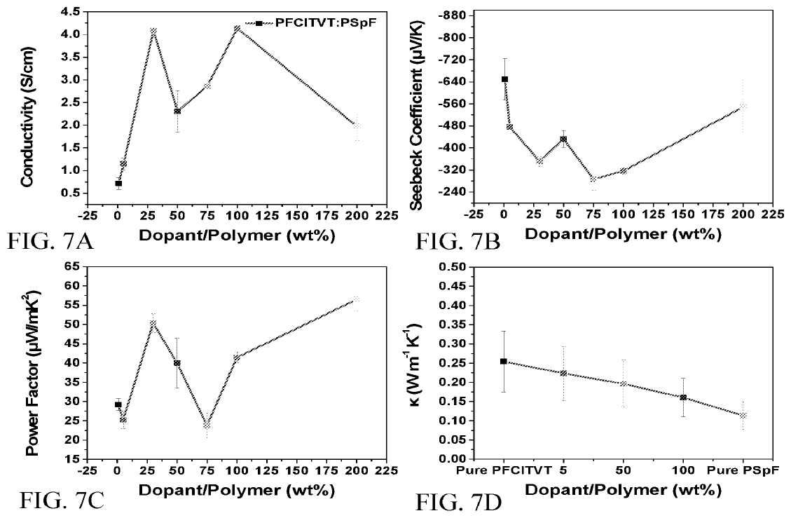

FIG. 7A shows the electrical conductivity of PFClTVT films doped by various weight fractions of PSpF, according to an embodiment of the present invention. FIG. 7B shows the Seebeck coefficient of PFClTVT films doped by various weight fractions of PSpF, according to an embodiment of the present invention. FIG. 7C shows the power factor of PFClTVT films doped by various weight fractions of PSpF, according to an embodiment of the present invention. FIG. 7D shows the thermal conductivity of PFClTVT films doped by various weight fractions of PSpF, according to an embodiment of the present invention. The left most black point in FIG. 7A is 1 wt % PSpF doped, not undoped.

The electrical conductivity of doped polymer films was examined by a four-probe method and the Seebeck coefficients were determined by detecting the thermoelectric voltages under open air. All the doped films exhibit reasonably high σ over 1 S cm⁻¹ except polymer films doped by 1 wt % PSpF. Polymers with 30 and 100 wt % PSpF doping show the σ of 4.1 and 4.2 S cm⁻¹, respectively, indicating PSpF doped polymer films can give effective electron transport over a broad range of dopant concentration, which is very different from N-DMBI doped films, suggesting a broad process window for polymer dopant PSpF. The Seebeck coefficients for 1, 5, 30, 50, 75, 100 and 200 wt % are 649±75, 476±7, −351±17, −432±31, −286±40, −316±11 and 550±100 μV K⁻¹, respectively (FIG. 7B). The S are relatively consistent in the PSpF fraction range between 1-200 wt % compared to N-DMBI-based devices, suggesting high concentration-tolerance of PSpF doping. The highest power factor of 60 (57±3) μW m⁻¹ K⁻² was achieved for 200 wt % PSpF doped films with the contribution of relatively high σ relative to S (FIG. 7C). PFClTVT doped by 30 wt % PSpF exhibits relatively high electrical conductivity and power factor of 4.1 S cm⁻¹ and 55 μW m⁻¹ K⁻², respectively. The lowest PF is 18.3 (25.2.±6.9) μW m⁻¹K⁻² with 75 wt % PSpF doping; even that PF is still much higher than for most n-type organic thermoelectrics. Thermal conductivity measurement on the thin film samples were performed via time-domain thermoreflectance (TDTR) to study the effect of polystyrene-based dopant PSpF on that property. The thermal conductivities of pristine PFClTVT and PSpF are about 0.25±0.07 and 0.11±0.04 W m⁻¹ K⁻¹ (FIG. 7D), respectively. The thermal conductivity of PSpF-doped PFClTVT films decreased from 0.22±0.07 W m⁻¹ K⁻¹ to 0.16±0.04 W m⁻¹ K⁻¹ when the dopant concentration increased from 5 to 100 wt %, suggesting PSpF can decrease the thermal conductivity of doped polymer films in proportion to its compositional fraction. The sources uncertainty in our reported values for thermal conductivity measurements on these thin films polymer samples are reported in our prior works. The highest ZT, assuming isotropic orientation of drop-cast films, is calculated to be about 0.1.

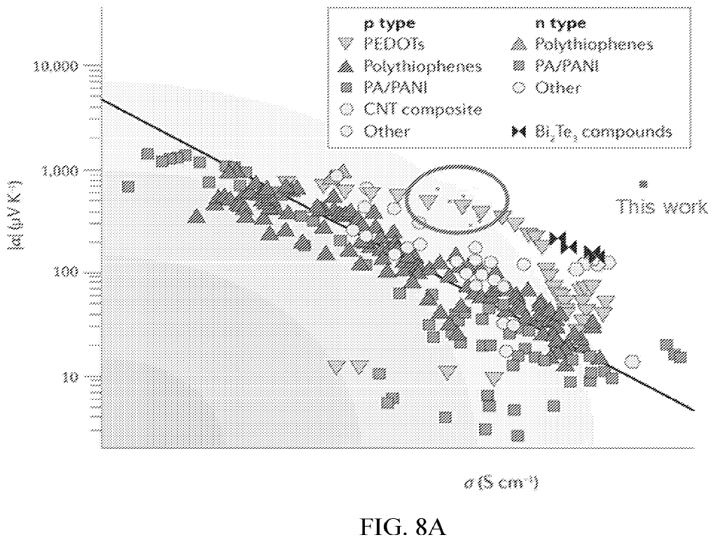

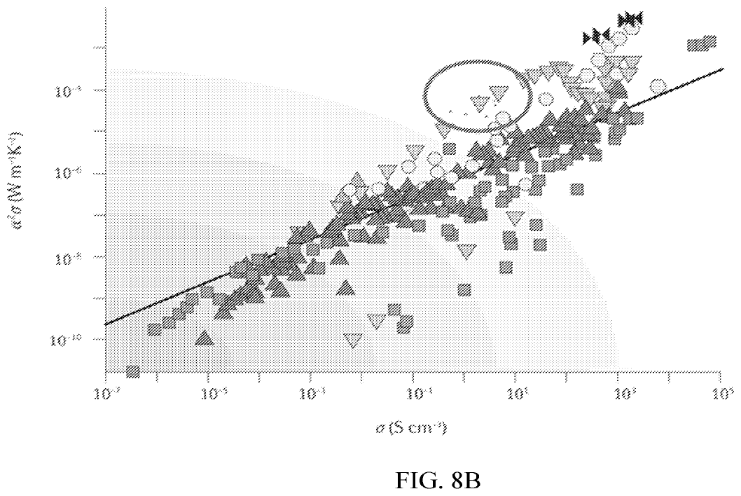

To explore the relationship of S, PF and a, the Seebeck coefficient and power factor as functions of electrical conductivity in this work were compared with reported works which have been summarized by Russ et al (FIGS. 8A and 8B). Though the S and PF (FIGS. 8A and 8B) in this work are relatively high, they are still reasonable and very similar to the trend of p-type thermoelectrics based on PEDOT:PSS. FIGS. 8A and 8B show Seebeck coefficient (α; FIG. 8A) and power factor (α2σ; FIG. 8B) as functions of conductivity (σ) for a range of doped organic thermoelectric (OTE) polymers and composites summarized by Boris Russ et al, according to an embodiment of the present invention.

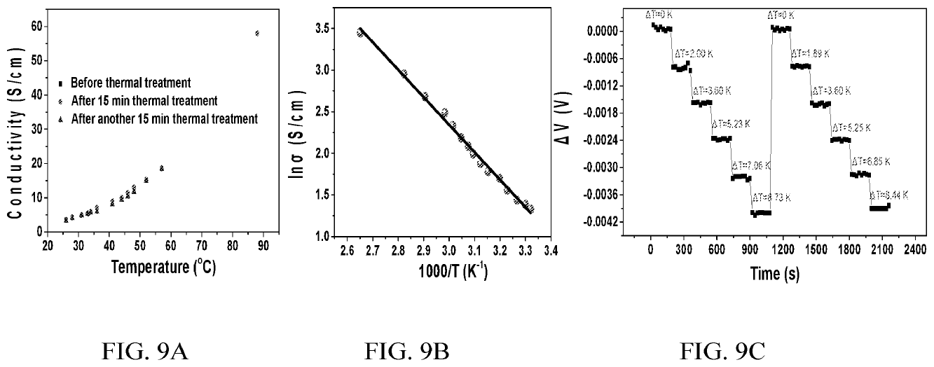

FIG. 9A shows a thermal air stability of electrical conductivity after thermal treatment at 120° C. for 2-circle 15 min in the open air, according to an embodiment of the present invention. FIG. 9B shows a temperature-dependent electrical conductivity values of PFClTVT film doped with 30 wt % PSpF, according to an embodiment of the present invention. FIG. 9C shows time-dependent thermoelectric voltage response under different temperature gradients ΔT, according to an embodiment of the present invention.

The thermal stability in ambient is very important for thermoelectric devices. It was explored by recording the electrical conductivity of films with 75 wt % PSpF doping before and after thermal treatment at 120° C. for 2 cycles of 15 min in the open air. The r at room temperature was 3.45 S cm⁻¹ before thermal treatment; after 2 cycles of 15 min thermal treatment, the value of 3.39 S cm⁻¹ was achieved, an insignificant 2% decrease (FIG. 9A). The σ values decreased about 1-10% at 28-57° C., exhibiting excellent thermal stability in the open air. Moreover, the apparent Eₐ hardly changed in the process. The doped film also shows good ambient stability; the σ was 2.35±0.27 S cm⁻¹ upon 9 days exposure to air, only a 24-40% decrease. Considering that the thickness of the films was only 100-300 nm, the ambient stability is outstanding. The stability is probably promoted by the long alkyl chains in PFClTVT and fragments of PS in PSpF.

To estimate the activation energy (Eₐ) of doped polymer films, temperature-dependent electrical conductivity values of PFClTVT with 30 wt % PSpF doping were recorded in FIG. 9B. The PSpF doped film shows increasing σ values over the range of 25-90° C. The apparent Eₐ was calculated according to the Arrhenius equation, being 282 meV. The value of the activation energy divided by the average temperature of the measurement is 852 μV K⁻¹. The value is somewhat higher than the measured Seebeck coefficient due to the barrier to site-to-site hopping, but is of the same order of magnitude as S. The time-dependent thermoelectric voltage responses under different temperature gradients were recorded for 36 minutes (FIG. 9C). These were unusually stable, suggesting the relatively high Seebeck coefficient can most likely originate from an electron contribution, not from ion contributions.

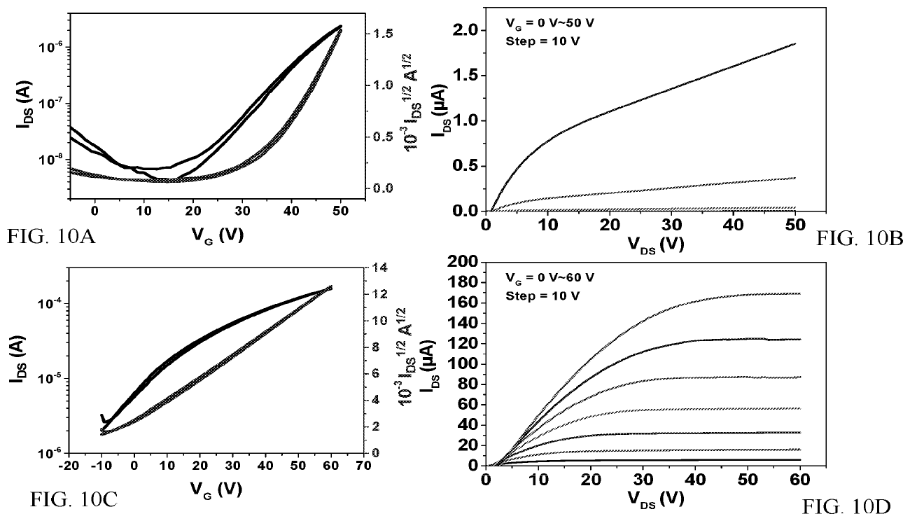

FIG. 10A shows the transfer curves of pristine OFET, according to an embodiment of the present invention. FIG. 10B shows the transfer curves of wt % PSpF doped OFET, according to an embodiment of the present invention. FIG. 10C shows output curves of pristine OFET, according to an embodiment of the present invention. FIG. 10D shows output curves of 1 wt % PSpF doped OFET, according to an embodiment of the present invention.

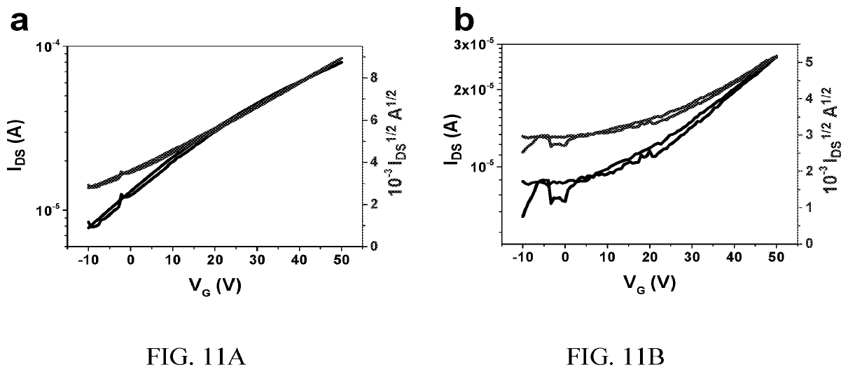

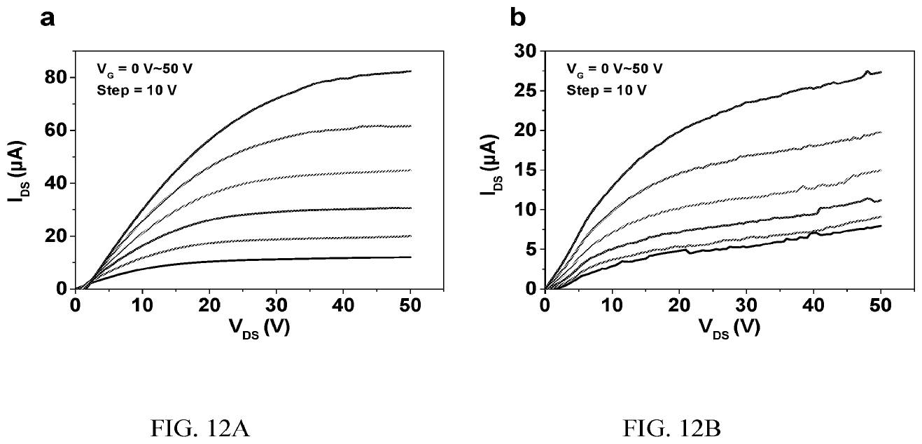

Electron mobility plays a key role in electrical conductivity, according to the formulation σ=neμ, where n is carrier density, e electron charge and μ is the corresponding carrier mobility. The σ is positively related to μ and n of polymer films.^{[35]} To measure the electrical mobility of doped polymer films, organic field effect transistors (OFETs) with top-gate/bottom-contact (TGBC) configuration were prepared and studied. The dopant PSpF fractions in the OFETs are 1, 2 and 10 wt %. The transfer and output curves are shown in FIGS. 10A-10D. The transfer and output curves are also shown in FIGS. 11A and 11B and FIGS. 12A and 12B in the supporting information.

FIG. 11A shows the transfer curve of OFET of 2 wt % PSpF doped polymer thin film, according to an embodiment of the present invention. FIG. 11B shows the transfer curve of OFET of 10 wt % PSpF doped polymer thin film, according to an embodiment of the present invention. FIG. 12A shows output curve of OFETs of 2 wt % PSpF doped polymer thin film, according to an embodiment of the present invention. FIG. 12B shows output curve of OFETs of 10 wt % PSpF doped polymer thin films, according to an embodiment of the present invention.

TABLE 1 provides Characteristics of polymers. The molecular weight of PFClTVT was determined by GPC at 150° C. in 1,2,4-trichlorobenzene with polystyrene standards. The molecular weight of PS-P was determined by GPC at 30° C. in THF with polystyrene standards.

TABLE 1

| Polymer | Mₙ (kDa) | M_{w} (kDa) | PDI |
|---|---|---|---|
| PFClTVT | 39.4 | 140.6 | 3.6 |
| PS-P | 118.4 | 334.1 | 2.8 |

The performance of OFETs is summarized in Table 2. Table 2 provides OFET device performance of the pristine and doped polymers.

TABLE 2

| | μₑ | | |
|---|---|---|---|
| Polymer films | (cm² V⁻¹ s⁻¹) | V_{T} (V) | Iₒₙ/I_{off} |
| PFClTVT | 0.24 ± 0.04 | 35-40 | 500-1000 |
| 1 wt % PSpF | 0.81 ± 0.05 | −7--21 | 80-100 |
| 2 wt % PSpF | 0.37 ± 0.01 | −25 | 10-15 |
| 10 wt % PSpF | 0.13 ± 0.05 | −3--22 | 3-400 |

In the transfer curves, PFClTVT with 1 wt % PSpF doping shows much higher I_{d} than pristine films, while, in the output curves, 1 wt % PSpF doped films show better linear behavior than undoped films in the low V_{d} region, owing to the reduction of contact resistance.

PFClTVT with 1 wt % PSpF doping shows a high electron mobility of 0.81±0.05 cm²V⁻¹ s⁻¹, much higher than the mobility of undoped PFClTVT of 0.24±0.04 cm²V⁻¹ s⁻¹. This could be from the filling of traps and/or the dopant inducing locally improved order. When the dopant fraction increases to 2 and 10 wt %, the electron mobility decreases to 0.37±0.01 and 0.13±0.05 cm²V⁻¹ s⁻¹, respectively, presumably because the unconjugated polymer dopant can disorder the conjugated polymer arrangement. The results are also further supported by a Hall effect measurement. A high electron mobility of 1.70 cm² V⁻¹ s⁻¹ was achieved in 50 wt % PSpF doped PFClTVT films, which is much higher than 0.97 cm²V⁻¹ s⁻¹ in pristine PFClTVT films.

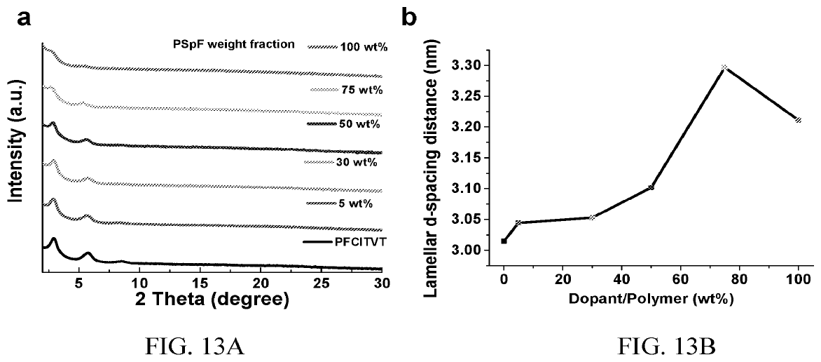

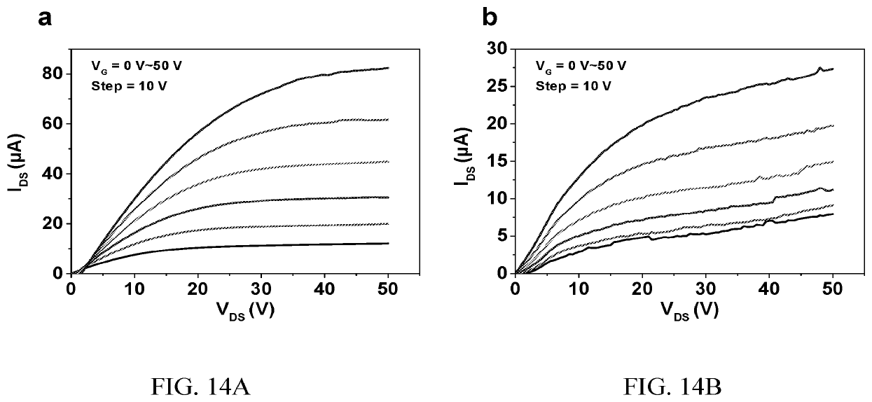

FIG. 13A is an Out-of-plane GIXRD diagram of pristine and doped polymer films which are prepared similar with the thermoelectric devices, according to an embodiment of the present invention. FIG. 13B shows Lamellar d-spacing distances of polymers doped with various weight fractions of dopant, according to an embodiment of the present invention. Polymer film microstructures were determined by grazing incidence X-ray scattering (GIXRS). The strong diffraction peaks of (100) and (200) were detected for pristine and 5-75 wt % PSpF doped polymer films, suggesting polymer molecules are in an ordered arrangement when the fraction of PFClTVT is higher than PSpF (FIG. 13A). There is no (010) peak detected in the out-of-plane diffractions, indicating the polymer films have an edge-on orientation packing. With the fractions of PSpF increasing from 0 to 75 wt %, the lamellar d-spacing distance increases from 30.15 to 32.97 Å (FIG. 13B), owing to the PSpF polymer molecules occupying space in the alkyl side-chain region. PFClTVT with 100 wt % PSpF doping presents a smaller d-spacing distance than that of 75 wt % PSpF doping and weak (100) peak, suggest that a different molecule arrangement formed. The (200) peak width decreases linearly as the PSpF fraction increases from 0 to 100 wt % (FIGS. 14A and 14B), suggesting PSpF likely can make alkyl side chains more compact. FIG. 14A shows output curves of OFETs of 2 wt % PSpF doped polymer thin films, according to an embodiment of the present invention. FIG. 14B shows output curves of OFETs of 10 wt % PSpF doped polymer thin films, according to an embodiment of the present invention.

FIG. 15A shows Atomic Force Microscope (AFM) height images of pristine and PSpF doped polymer thin films, according to an embodiment of the present invention. FIG. 15B shows phase images of pristine and PSpF doped polymer thin films, according to an embodiment of the present invention. The surface morphology of polymer films was investigated by atomic force microscope (AFM). All the films present similar small size fiber-like aggregates with no preferred direction, suggesting good miscibility of PSpF with conjugated polymers (FIGS. 15A and 15B). The smaller root-mean-square roughness of polymer film with 100 wt % PSpF doping is attributed to the low crystallinity (implying little or no preferred orientation) consistent with the GIXRS result.

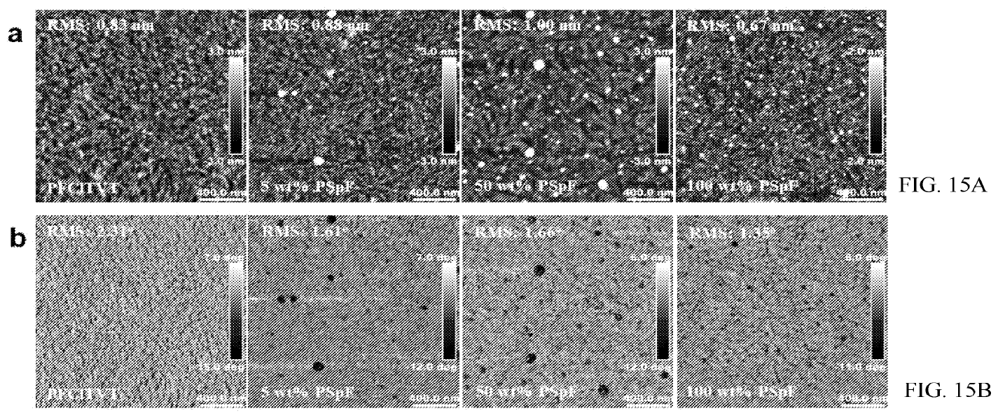

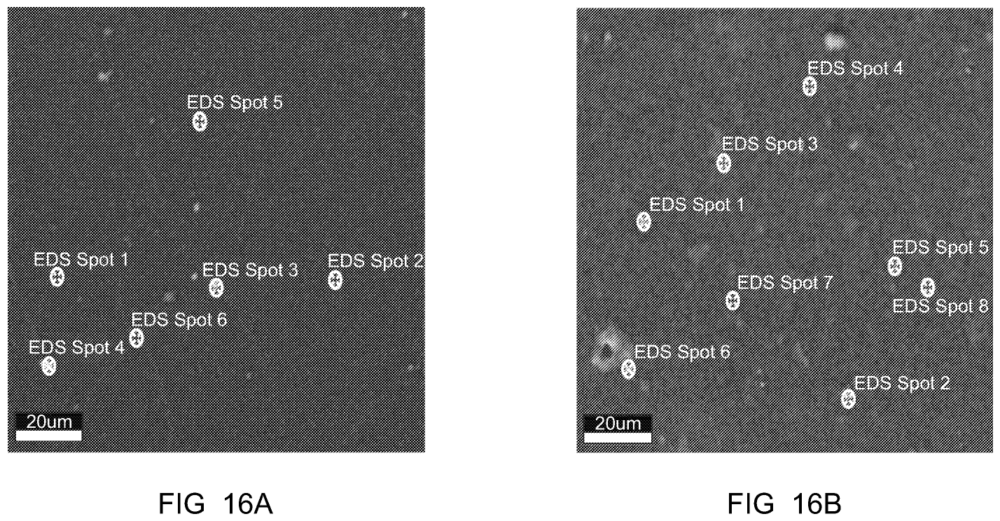

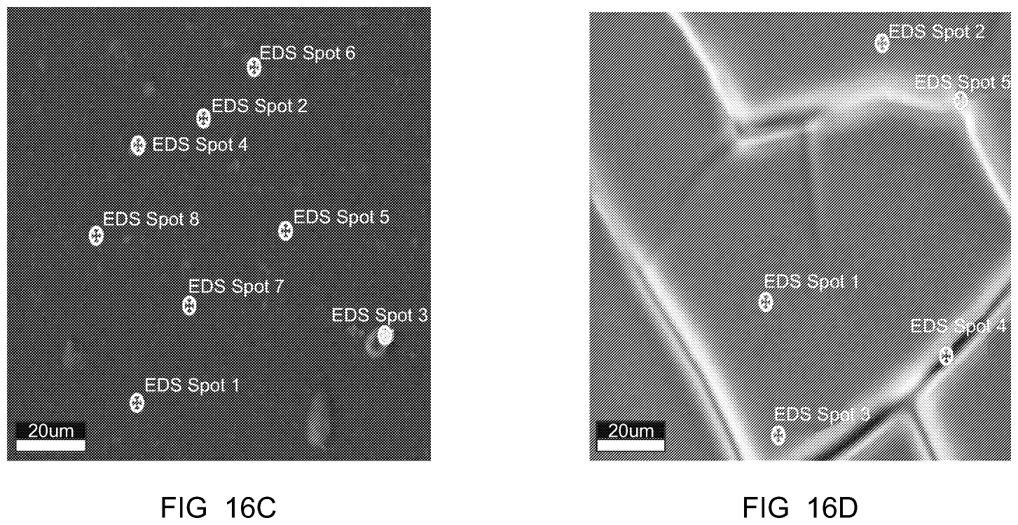

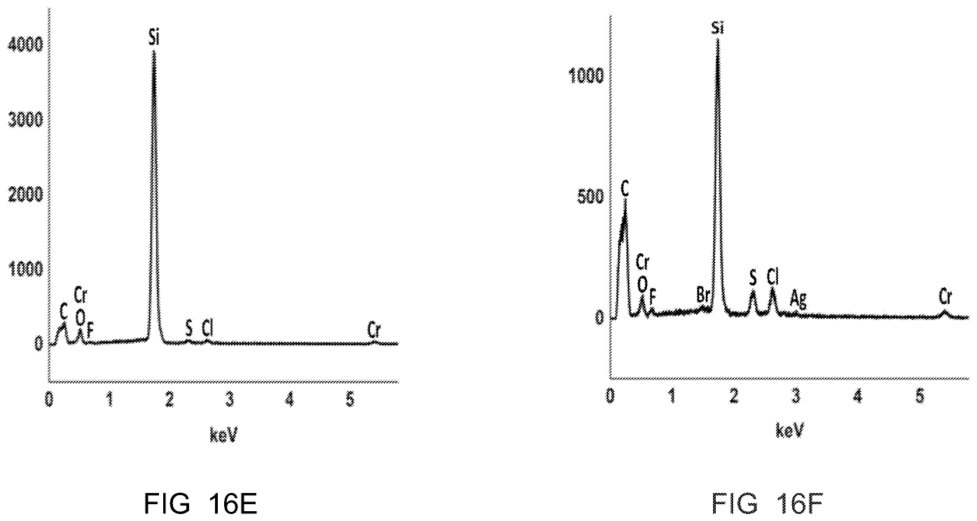

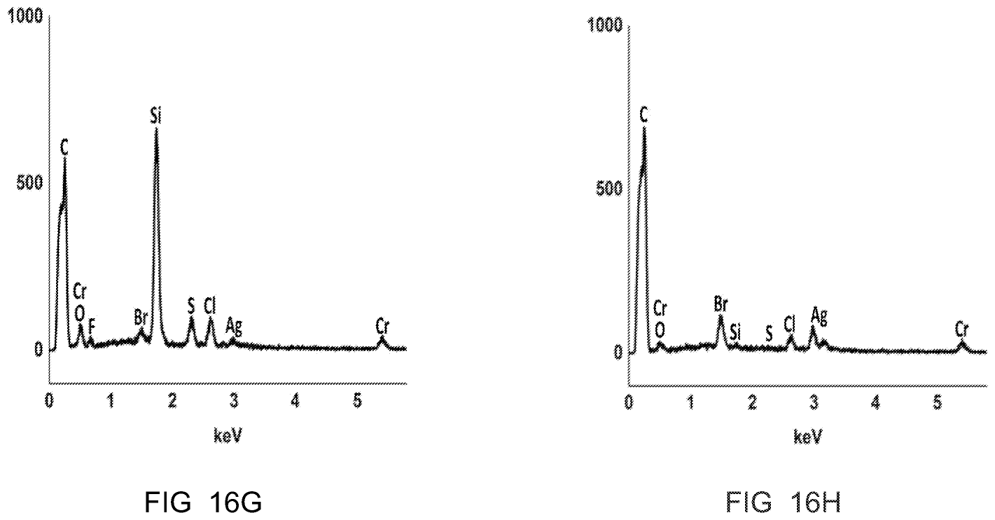

To further study the morphology and doping reaction of PFClTVT and PSpF, scanning electron microscope (SEM) and energy dispersive spectroscopy (EDS) measurements were done to examine the films prepared by drop-casting on Si/SiO₂ substrates. To measure SEM, polymer films were prepared by drop-casting, as was done with the all-polymer thermoelectrics. The micron-sized aggregates can be observed in 5 and 50 wt % PSpF doped PFClTVT films (FIGS. 16A-16H).

FIGS. 16A-16D show SEM images of (a) pristine PFClTVT, (b) 5 wt % PSpF, (c) 50 wt % PSpF doped PFClTVT and (d) pristine PSpF films, according to embodiments of the present invention. FIGS. 16E-16H show an EDS analysis at the even area of (e) pristine PFClTVT (spot 1), (f) 5 wt % PSpF (spot 4), (g) 50 wt % PSpF doped PFClTVT (spot 5) and (h) pristine PSpF films (spot 1), according to embodiments of the present invention. The percentage composition of F in b (FIG. 16B) and c (FIG. 16C) is higher than a (FIG. 16A), suggesting the existence and adduct reaction with PFClTVT of F⁻ in PSpF, indicating the phase separation between the ionic polymer PSpF and conjugated polymer PFClTVT. There is no F detected in pure PSpF film because F⁻ can escape as HF in high vacuum. The content of F atoms increased from 0.14% in pristine PFClTVT to 0.96% in 5 wt % PSpF doped PFClTVT (Tables 3, 4 and 5), due to the reaction of F⁻ with BDOPV rings in PFClTVT. The results indicate that the F atoms are covalently bonded to the polymer after doping.

Table 3 provides EDS element analysis of pristine PFClTVT film in different spots.

TABLE 3

| | Spot 1 | Spot 2 | Spot 3 | Spot 4 | Spot 5 | Spot 6 |
|---|---|---|---|---|---|---|
| | Atomic | Atomic | Atomic | Atomic | Atomic | Atomic |
| Element | % | % | % | % | % | % |
| C K | 52.54 | 52.46 | 61.49 | 70.23 | 53.08 | 53.06 |
| O K | 9.58 | 9.51 | 12.22 | 11.05 | 9.54 | 9.15 |
| F K | 0.14 | 0.18 | 0.5 | 0.32 | 0.17 | 0.17 |
| Si K | 35.77 | 35.68 | 23.26 | 13.59 | 35.26 | 35.37 |
| S K | 0.56 | 0.59 | 0.58 | 1.57 | 0.55 | 0.63 |
| Cl K | 0.56 | 0.66 | 0.83 | 1.59 | 0.53 | 0.63 |
| Cr K | 0.85 | 0.92 | 61.49 | 1.65 | 0.86 | 0.99 |

Table 4 provides EDS element analysis of 5 wt % PSpF doped PFClTVT film in different spots (Spot 6 is dust).

TABLE 4

| | Spot 1 | Spot 2 | Spot 3 | Spot 4 | Spot 5 | Spot 7 | Spot 8 |
|---|---|---|---|---|---|---|---|
| Ele- | Atomic | Atomic | Atomic | Atomic | Atomic | Atomic | Atomic |
| ment | % | % | % | % | % | % | % |
| C K | 74.53 | 77.61 | 75.04 | 73.45 | 74.61 | 73.64 | 72.96 |
| O K | 10.61 | 7.89 | 7.27 | 6.08 | 8.27 | 5.9 | 6.22 |
| F K | 2 | 1.25 | 0.63 | 0.96 | 1.61 | 0.89 | 1.03 |
| Br L | 0.2 | 0.27 | 0.27 | 0.22 | 0.21 | 0.22 | 0.24 |
| Si K | 2.75 | 7.66 | 11.72 | 14.46 | 7.64 | 14.29 | 14.89 |
| S K | 2.37 | 2.01 | 1.92 | 1.79 | 2.34 | 1.88 | 1.73 |
| Cl K | 2.54 | 1.59 | 1.7 | 1.92 | 2.47 | 1.86 | 1.79 |
| Ag L | 3.53 | 0.19 | 0.24 | 0.11 | 1.3 | 0.13 | 0.1 |
| Cr K | 1.47 | 1.53 | 1.22 | 1.01 | 1.55 | 1.19 | 1.04 |

Table 5 provides EDS element analysis of 50 wt % PSpF doped PFClTVT film in different spots (Spot 3 is dust).

TABLE 5

| | Spot 1 | Spot 2 | Spot 4 | Spot 5 | Spot 6 | Spot 7 | Spot 8 |
|---|---|---|---|---|---|---|---|
| Ele- | Atomic | Atomic | Atomic | Atomic | Atomic | Atomic | Atomic |
| ment | % | % | % | % | % | % | % |
| C K | 76.32 | 78.87 | 74.09 | 77.8 | 78.01 | 76.7 | 77.96 |
| O K | 10.5 | 5.27 | 13.48 | 6.39 | 7.95 | 9.3 | 5.48 |
| F K | 0.56 | 0.92 | 0.97 | 1 | 1.03 | 0.82 | 0.78 |
| Br L | 0.24 | 0.32 | 0.32 | 0.33 | 0.36 | 0.35 | 0.37 |
| Si K | 7.94 | 9.64 | 6.03 | 9.46 | 6.98 | 7.87 | 10.47 |
| S K | 1.21 | 1.55 | 1.24 | 1.62 | 1.61 | 1.36 | 1.62 |
| Cl K | 1.57 | 1.74 | 1.83 | 1.67 | 2.13 | 1.7 | 1.73 |
| Ag L | 0.18 | 0.3 | 0.26 | 0.32 | 0.39 | 0.24 | 0.31 |
| Cr K | 1.47 | 1.39 | 1.8 | 1.4 | 1.55 | 1.65 | 1.28 |

Table 6 provides EDS element analysis of pristine PSpF film in different spots (Spot 3 is dust).

TABLE 6

| | | Spot 2 | | Spot 4 | Spot 5 |
|---|---|---|---|---|---|
| | Spot 1 | Atomic | Spot 3 | Atomic | Atomic |
| Element | Atomic % | % | Atomic % | % | % |
| C K | 90.19 | 89.23 | 90.51 | 37.65 | 86.53 |
| O K | 3.03 | 2.6 | 2.8 | 0 | 5.56 |
| Br L | 1.24 | 1.02 | 1.16 | 0.04 | 0.93 |
| Si K | 0.2 | 2.08 | 0.38 | 56.77 | 2.04 |
| S K | 0.21 | 0.24 | 0.28 | 0.05 | 0.19 |
| Cl K | 1.18 | 1.12 | 1.2 | 0.39 | 1 |
| Ag L | 1.68 | 1.36 | 1.37 | 0.52 | 1.24 |
| Cr K | 2.26 | 2.34 | 2.31 | 4.57 | 2.5 |

The results demonstrate that the copolymer PSpF can be an effective n-dopant for high-performance n-type organic thermoelectrics. High electrical conductivity of 4.2 S cm⁻¹ and power factor of 60 μW m⁻¹ K⁻² were achieved for PSpF doped polymer films. The OFETs of PSpF doped thin films exhibit high electron mobility of 0.86 cm²V⁻¹ s⁻¹. Moreover, excellent thermal stability and ambient stability were observed for the electrical conductivity of PSpF doped films. Very stable time-dependent thermoelectric voltage responses under different temperature gradients were recorded. This work opens the way for designing polymer n-type dopants for organic conductors and thermoelectrics with low thermal conductivity, high conductivity relative to-Seebeck coefficient and high power factor.

A novel polystyrene-polyvinyl pyridinium-based n-type polymer dopant is firstly designed and synthesized. It can dope n-type conjugated polymers to make n-type all-polymer conducting materials and thermoelectrics, analogous to poly(3,4-ethylenedioxythiophene) poly(4-styrenesulfonate). High electrical conductivity of 4.2 S cm⁻¹, electron mobility of 0.86 cm²V⁻¹ s⁻¹ and power factor of 60 W m⁻¹ K⁻² are achieved for PSpF doped polymer films.

FIG. 17 shows a conductivity versus temperature of a N-type PSpF doped polymer films, according to an embodiment of the present invention. The following paragraphs describe methods of fabrication and synthesis along with other experimental evaluation details.

Chemical reagents (Including solvent and PMMA) were purchased and used as received. All the synthesis procedures were performed under N₂. ¹H and ¹³C NMR spectra were recorded on Bruker Advance (400 MHz) spectrometers. ¹H NMR chemical shifts were referenced to tetramethylsilane TMS (0 ppm). Gel permeation chromatography (GPC) was performed on a PL gel MIXED-B LS 300×7.5 mm×3 at 150° C. using trichlorobenzene (TCB) stabilized with 0.0125% BHT as eluent. Cyclic voltammetry (CV) was performed on a BASI Epsilon workstation. Thin films of polymers and doped polymers (wt % of dopant relative to 100% of conjugated polymer) were tested in acetonitrile solutions under N₂ with 0.1 M tetrabutylammonium hexafluorophosphate (NBu₄PF₆) as the supporting electrolyte at room temperature. The cyclic voltammograms were obtained at a scan rate of 50 mV/s. Glassy carbon was used as a working electrode material, a platinum wire was used as a counter electrode, and all potentials were recorded versus Ag/Ag⁺ as a reference electrode. To measure CV, polymer PFClTVT in o-DCB (1 mg/mL) was doped with different concentration of PSpF (10 mg/mL) and then 10 uL was dropped on the Glassy carbon electrode and dried in the drying oven at 100° C. The EPR measurements were performed on a Bruker-EMX EPR spectrometer at room temperature. Solutions of doped polymers were prepared by stirring at 120° C. for 3 min and then 50 μL solution was injected into EPR tubes. AFM images were taken in tapping mode using a Dimensional 3100 AFM (Bruker Nano, Santa Barbara, CA). The images were visualized using the Nanoscope software (Bruker). SEM samples were observed under a Tescan MIRA 3 GMU at 10-20 keV with working distances between 10 and 30 mm. All EDS data were acquired via the AMATEK EDAX Octane Plus. The absorption spectra were acquired on an Agilent Cary 5000 UV-Vis-NIR spectrophotometer. GIXRD was performed on a Bruker D8 Advance A25 instrument.

OFET Film Fabrication and Characterization: Organic field electric transistors (OFETs) with top-gate/bottom-contact (TGBC) configuration were fabricated using n⁺⁺-Si/SiO2 (300 nm) substrates. The substrates were cleaned using ultrasonication in cleaning agent (Decon, labs, Inc), deionized water, acetone, and isopropanol. The cleaned substrates were dried under vacuum at 60° C. for 6 h and then transferred into a glovebox. The source and drain electrodes comprising a layer of Au (50 nm) were deposited through a shadow mask onto the silicon substrates by thermal evaporation. Thin films of polymers (2.5 mg/mL in orthodichlorobenzene (o-DCB)) and doped polymers were prepared by spin coating the solution on the substrates at 2000 rpm for 60 s and annealed at 150° C. for 30 min. Then, the solution of PMMA was spin-coated on the polymer films at 2000 rpm for 60 s and annealed at 110° C. for 30 min, resulting in a dielectric layer about 1050 nm thick. Gate electrodes comprising a layer of Au (50 nm) were then deposited through a shadow mask onto the dielectric layer by thermal evaporation. The OFET devices had a channel length (L) of 200 μm and a channel width (W) of 8000 μm. The evaluations of the OFETs were carried out in atmosphere on a probe stage using Agilent B1500A as parameter analyzers. The mobility was calculated in the saturation regime according to the equation: I_{DS}=(W/2L)μCᵢ(V_{G}−V_{T})², where I_{DS} is the drain current, μ is the mobility, and V_{G} and V_{T} are the gate voltage and threshold voltage, respectively.

Thermoelectric devices and properties measurements: ITO electrodes with a channel length of 3 mm and a channel width of 7 mm patterned glass substrates were cleaned by sonication in cleaning agent, deionized water, acetone, and isopropanol. Polymers and dopants were dissolved in o-DCB separately with the concentration of 2.5 mg mL⁻¹. The polymers and the dopants solution were heated at 100° C. for 24 h. Then the polymer was blended with dopant in the desired weight ratio. The mixed solution was heated at 120° C. and stirred for 2 min. The final solution was dropped on the glass substrates on which 2D wells are fabricated by laying a pattern of Novec polymer. After natural evaporation of solvent in a glove box over 24 h, square films form. The devices were annealed on a hot plate at 120° C. for 12 h in nitrogen. All the measurements were performed in ambient. Resistance was measured by using a four-probe method with an Agilent B1500A Semiconductor Parameter Analyzer. 3-8 measurements of resistance were performed on each sample surface in different positions. Seebeck coefficient can be calculated by S=ΔV/ΔT, where ΔV is the thermal voltage obtained between the two electrodes of the device subjected to a temperature gradient ΔT. Six ΔT were imposed on the sample, so the slopes of ΔV versus ΔT give values of the Seebeck coefficient.

Synthesis of polymers: PFClTVT was synthesized according to the previous work.

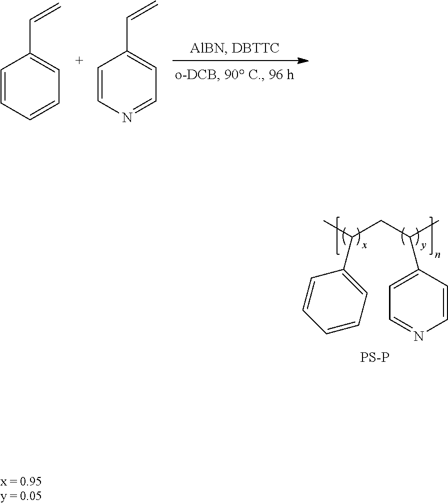

PS-P: Styrene (20 g, 22.08 mL, 192 mmol) and vinylpyridine (1 g, 1.04 mL, 9.6 mmol) was added to a dry Schlenk tube under N₂, then 2,2-azobisisobutyronitrile (AIBN) (12 mg) and S, S-Dibenzyl trithiocarbonate (DBTTC) (6 mg) was added to the Schlenk tube under N₂. Then 16 mL o-DCB was added to the tube, and evacuation and refilling with N₂ was repeated 8 times under stirring. Then the solution was heated to 90° C. and stirred for 96 h. The polymer solution was dropped into 350 mL methanol and stirred for 1 h, then it was filtered and washed in a Soxhlet extractor with methanol for 2 days. White solid was obtained in the yield of 85%. GPC: Mₙ=118.4 kDa, M_{w}=334.1 kDa, PDI=2.8.

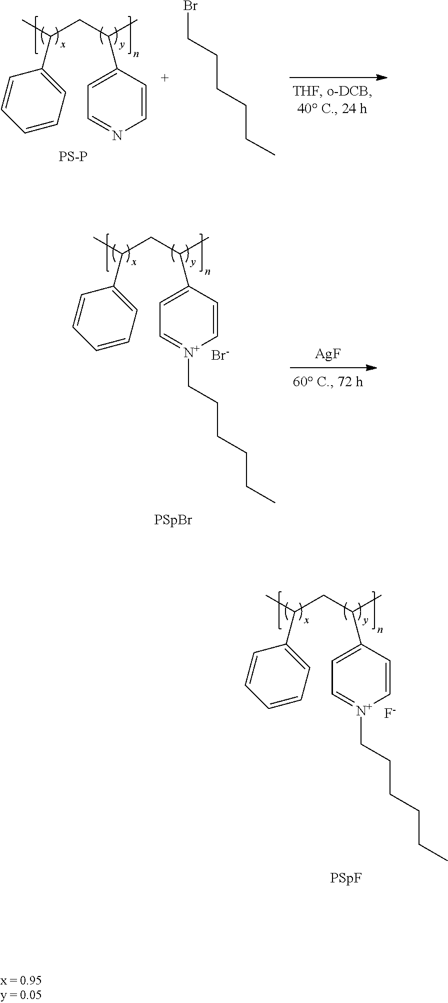

PSpBr: The polymer PS-P (3 g) and bromohexane (0.5 g) was added to a dry Schlenk bottle. Then 30 mL o-DCB and 10 mL THF was added and stirred for 0.5 h under N₂. Then the mixture was heated to 40° C. and reacted for 24 h. After reaction, the solution was cooled to room temperature and used in the next step without purification.

PSpF: Excess AgF (0.55 g) was added to the solution under N₂, and the mixture was heated to 60° C. and stirred for 72 h. After reaction, the solvent was removed with reduced pressure distillation. Then the solid was dissolved in chloroform and filtered. The filtrate was concentrated with rotary evaporation and dried in vacuum under 55° C. for 3 days. The faint yellow solid was obtained in the yield of 59%.

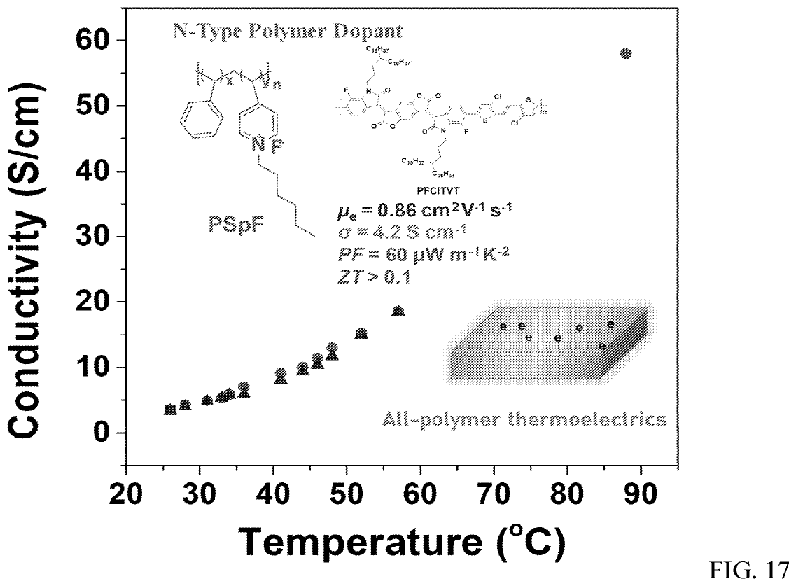

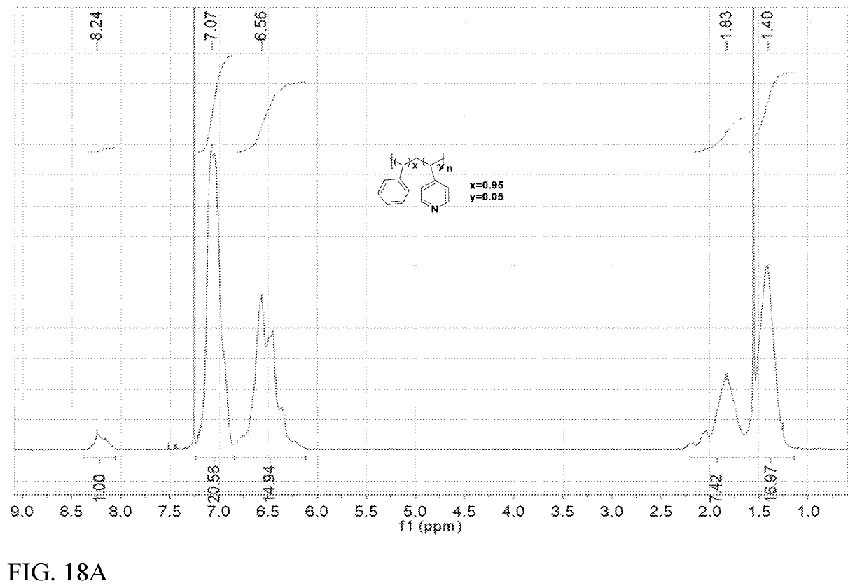

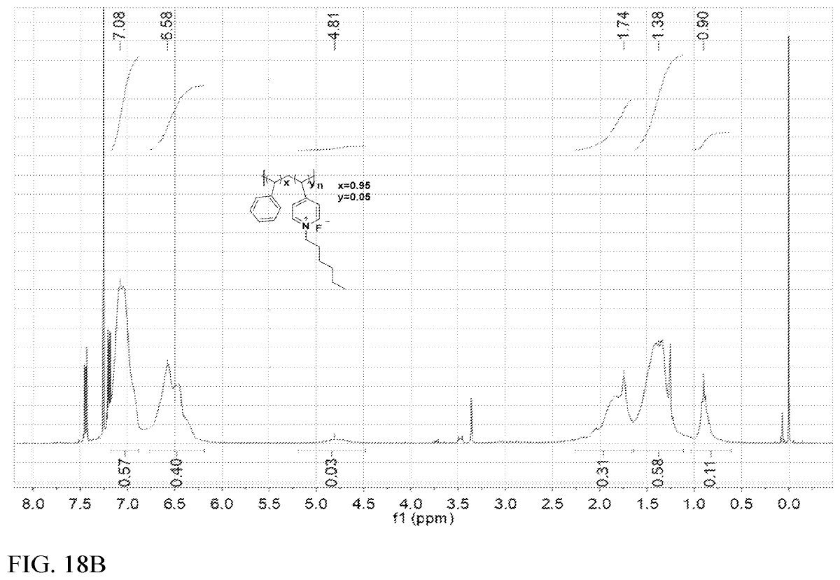

FIGS. 18 A and 18B are plots showing a chemical shift at 8.24 ppm in PS-P is slightly up field of the known 2,6-protons of 4-methylpyridine, reasonable for the aromatic-ring media, according to an embodiment of the present invention. The broad peak with chemical shift at 4.81 ppm belongs to 1-H atoms of the hexyl groups. The extra 7.4 ppm peak in PSpF belongs to solvent O-DCB which does not affect the doping results.

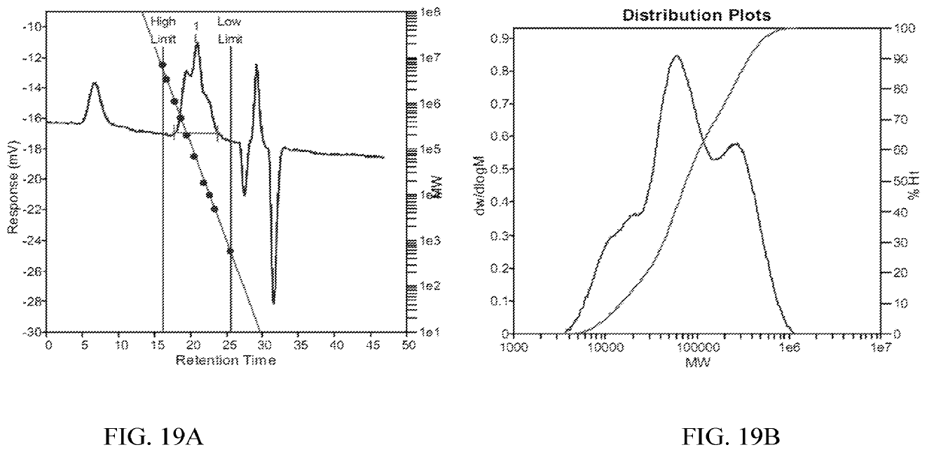

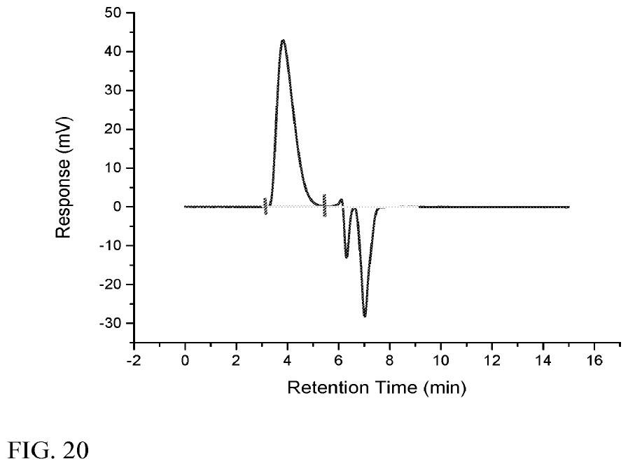

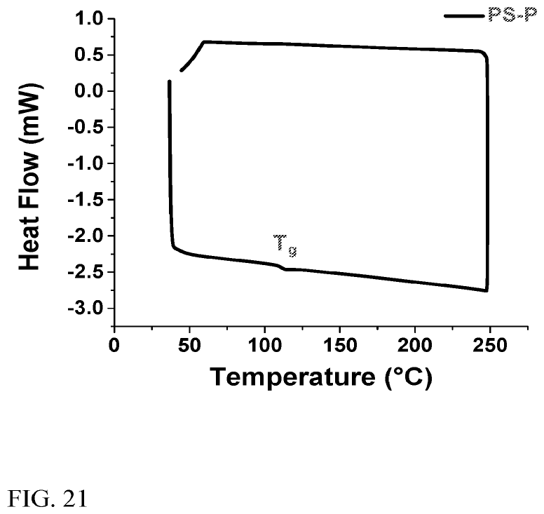

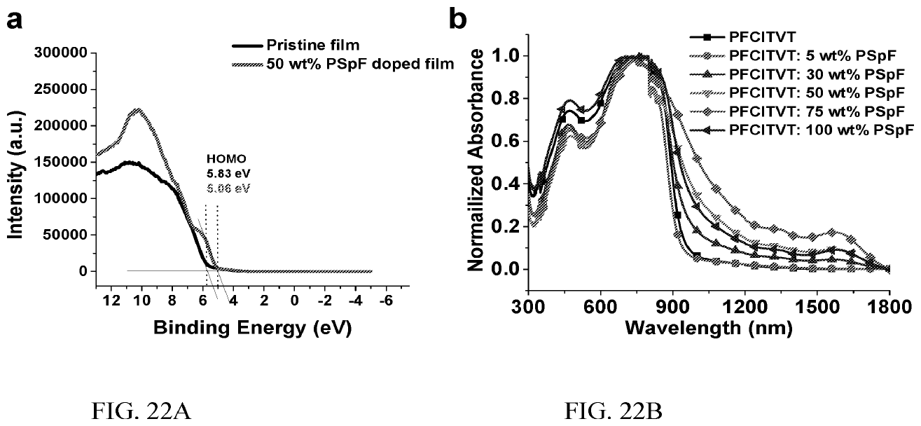

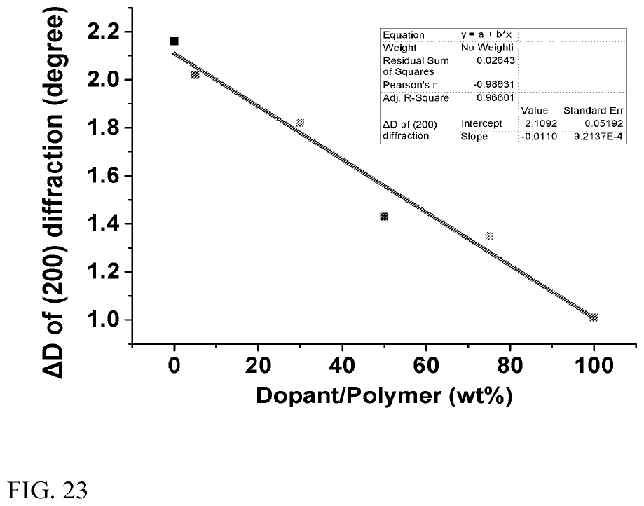

Characteristics of polymers and doped polymer films: FIGS. 19A and 19B show the GPC spectra of PFClTVT, according to an embodiment of the present invention. FIG. 20 shows a GPC spectra of PS-P, according to an embodiment of the present invention. FIG. 21 shows differential scanning calorimeter (DSC) traces of PS-P measured under nitrogen (N₂) gas atmosphere. FIG. 22A show UPS binding energy of the pristine and doped polymer films measured under −5 eV, according to an embodiment of the present invention. FIG. 22B shows normalized absorption of pristine and PSpF doped PFClTVT films, according to an embodiment of the present invention. FIG. 23 shows a plot of diffraction versus percent weight of dopant in polymer, according to an embodiment of the present invention. FIG. 23 shows the linewidth of the (200) peak of pristine and doped thin films.

Designing n-type polymers with high electrical conductivity (σ) and thermoelectric figure of merit (ZT) is still a major challenge. N-type thermoelectrics typically consist of a small molecule dopant+polymer host. Only a few polymer dopant+polymer host systems have been reported, and these have lower thermoelectric parameters. N-type organic thermoelectrics generally show the highest σ and power factor (PF) values at different dopant/host ratios, due to the inverse correlations of σ values and Seebeck coefficient (S) absolute values. N-type polymers with high crystallinity and order are generally used for high-σ organic conductors. Few n-type polymers with only short-range lamellar stacking for high-conductivity materials have been reported. Here, we report an n-type short-range lamellar-stacked all-polymer thermoelectric system with highest σ of 78 S⁻¹, PF of 163 μW m⁻¹K⁻², and maximum ZT of 0.53 at room temperature with a dopant/host ratio of 75 wt %. The polymer has a unique electron-demanding dicyanomethyleneindanone conjugated subunit. The relatively minor effect of polymer dopant on the molecular arrangement of conjugated polymer PDPIN at high ratios, high doping capability, high S absolute values relative to a, high electron mobility, and thermal conductivity that shows a rare decrease with electronic doping contribute to the excellent performance. The results have promising applications in flexible conductors and thermoelectrics.

Semiconducting polymers have been used for many kinds of devices, such as organic solar cells (OSCs), polymer photodetectors (PPDs), thin film field effect transistors (TFTs), polymer light emitting diodes (LEDs), organic thermoelectric devices, wearable devices, photoacoustic-imaging, photothermal therapy and neural applications. Organic thermoelectrics have attracted increasing attention because of the potential value in transforming heat energy into electricity. More than 50% of available natural and waste heat energy is low-temperature (<250° C.) which could conceivably be recovered by organic thermoelectrics. The low σ and ZT of n-type polymers are still challenges for organic thermoelectrics. The low σ is because the electron mobility and doping efficiency of n-type organic thermoelectrics are limited. Matching and engineering of n-dopants and n-polymers to enhance the doping efficiency have led to some progress. The values of σ and Seebeck coefficient are usually in an inverse relationship, leading to the relatively low ZT (<0.2) at room temperature (r.t.) which is much lower than that (ZT=0.5-1 at r.t.) of inorganic n-type materials. Seebeck coefficient for a given conductivity can be increased by reducing the Coulombic interaction between host and dopant but is decreased by higher carrier concentrations that contribute to σ.

To decrease the Coulombic interaction and increase σ, the host-dopant distance and electron mobility (μ) of doped polymers should be increased. The engineering of tailored dopants and conjugated polymers is an effective method to achieve this goal. The triaminomethane and trimethoxy-substituted N-DMBI (TP-DMBI) dopants have larger than typical sizes and higher singly occupied molecular orbital (SOMO) energy levels, and led to higher c, Seebeck coefficient and power factors, associated with good dopant-host miscibility. Introducing polarizable triethylene glycol type side chains to n-polymers can promote dispersion of the dopant in the host polymers, thus increasing the doping efficiency and σ.

Other efforts have been devoted to the engineering of n-polymer backbones. Some effective ways to achieve high σ include increasing lactone backbone density, introducing electron-withdrawing groups to donor units and optimizing the acceptor units³⁰ within donor-acceptor (D-A) polymers. These optimized acceptor units play a key role in σ and ZT of doped films. Until now, the n-type D-A or acceptor-acceptor (A-A) linear polymers used for doped films with σ≥10 S cm⁻¹ are mostly based on BDOPV, CNDTI, TzTI, PzDPP and TBDOPV. Developing new n-type polymers is still an urgent task and helpful to achieve high σ for n-type organic thermoelectrics. Our recent report suggests that a polymer dopant is effective in improving the Seebeck coefficient and ZT of n-type thermoelectrics. Polymer dopants can also enhance the mechanical properties, thermal stability and organic solvent stability of thermoelectric films. The σ of n-type all-polymer thermoelectrics are ≤10 S cm⁻¹, which is much lower than films doped with small molecule dopants. New polymers are needed to achieve high-σ and high-ZT n-type all-polymer thermoelectrics.

In the following paragraphs, we further describe embodiments of a semiconducting polymer PDPIN doped with copolymer ionic dopant PSpF and molecular dopant N-DMBI, providing a new system for n-type all-polymer thermoelectrics with high-σ and ZT.

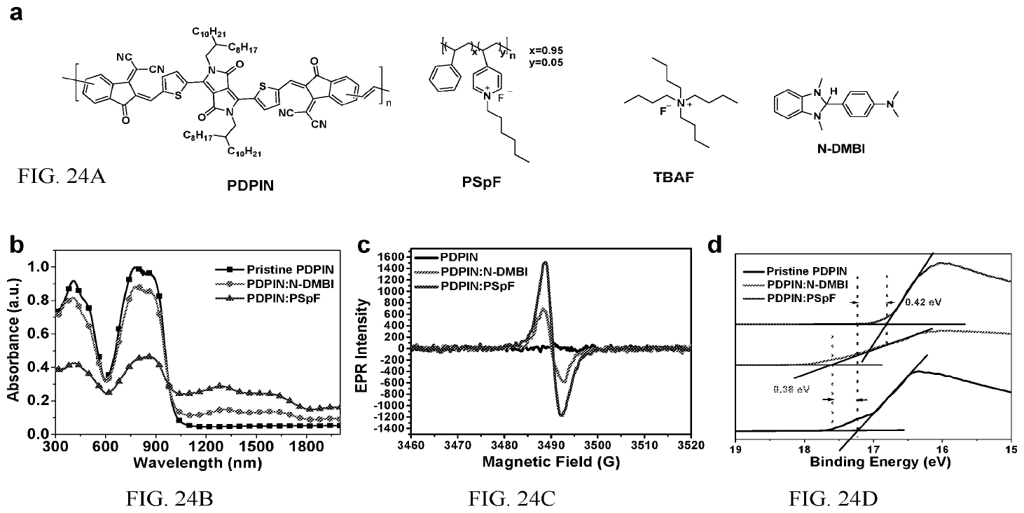

FIG. 24A shows chemical structures of polymers and dopants, according to an embodiment of the present invention. FIG. 24B shows the absorbance spectra of pristine PDPIN, N-DMBI doped PDPIN, and PSpF doped PDPIN in films, according to embodiments of the present invention. FIG. 24C shows EPR spectra of pristine and N-DMBI and PSpF doped PDPIN in films, according to embodiments of the present invention. FIG. 24D shows UPS binding energy of pristine and N-DMBI and PSpF doped PDPIN in films, according to embodiments of the present invention. Note that spin density would be double the density of generated mobile anions, since the neutral radicals following charge transfer would also contribute to ESR peaks.

The involvement of F⁻ in the doping of PDPIN:PSpF was supported by energy-dispersive X-ray spectroscopy (EDS) observation and ab initio computational calculations. We observe a record-breaking σ of 78 S cm⁻¹ for an n-type all-polymer thermoelectric. The impressive maximum power factor of 163 μW m⁻¹K⁻² and ZT of 0.53 at room temperature are achieved with relatively high S and low thermal conductivity (K). Ultraviolet-visible-near infrared (UV-vis-NIR) absorbance measurements indicate that all-polymer films have stronger polar/bipolar absorbance than molecular N-DMBI-doped films. A larger vacuum level shift and higher spin density in all-polymer doped films are calculated using ultraviolet photoelectron spectroscopy (UPS) and electron paramagnetic resonance (EPR) measurements. The discovery illustrates a new polymer blend architecture for high-σ conductors for plastic electronics.

PDPIN was synthesized by Stille coupling polymerization. It had low lowest unoccupied molecular orbital (LUMO) energy levels of −4.26 eV, much lower than the singly occupied molecular orbital (SOMO) energy levels (−2.36 eV) of N-DMBI, suggesting it can be doped by N-DMBI. The corresponding highest occupied molecular orbital (HOMO) energy levels calculated from the onset oxidation in the cyclic voltammetry curves is −5.55 eV, and the electrochemical band gap is 1.29 eV. The optical band gap of PDPIN estimated from the film absorbance onset is 1.23 eV (FIG. 24B), which is very close to the electrochemical band gap. The calculated HOMO and LUMO frontier orbitals of the DPIN repeat unit within PDPIN; the calculated LUMO and HOMO energy levels are −4.2 and −5.0 eV, respectively. The electrophilicity of PDPIN increased the driving force for forming the adduct of PDPIN with F⁻. The weight-average molecular weight of PDPIN, 122 kDa, was measured using gel permeation chromatography (GPC) at 150° C. There are three absorbance peaks observed in pristine PDPIN films at 406, 776 and 866 nm, the first from the π-π* transition and the latter two from intramolecular charge transfer. There is no absorbance peak between 300-400 nm in the spectra of PSpF, so the f π-π* absorbance is from PDPIN. The absorbance peak of N-DMBI was detected between 300-350 nm, the π-π* absorbance peak of pristine PDPIN is 406 nm, and with the increase of N-DMBI ratio, the π-π* transitions absorbance peak moved to 340 nm, so the π-π* bands of N-DMBI doped PDPIN arise from both of N-DMBI and PDPIN. A new peak at 575 nm was detected in 75 mol % N-DMBI-doped PDPIN, suggesting bipolaron formation because of over-doping. The absorbance spectra at 300-1000 nm of both of N-DMBI and PSpF doped films are bleached, which is as expected and similar to other doped films. After doping with 1 mol % N-DMBI, two more absorbance peaks at 1325 and 1585 nm were detected, which can be assigned to polaron/bipolaron transitions. The peak at 869 nm decreases with an increasing N-DMBI/PDPIN molar ratio. PSpF-doped PDPIN films exhibit very different absorbance spectra from N-DMBI-doped films. The peak at 792 nm decreases when the PSpF/PDPIN weight ratio increases, and the peak at 869 nm presents no shift, suggesting PSpF-doped PDPIN films have stronger intramolecular charge transfer than N-DMBI-doped films. To estimate the doping efficiency of the doped films, we calculated the ratio of absorbance peaks at 600-1000 nm (Abs₆₀₀₋₉₀₀) and 1250-1850 nm (Abs₁₂₅₀₋₁₈₅₀). The absorbance spectra of 5 mol % N-DMBI and 75 wt % PSpF-doped PDPIN were examined because the highest 6 values occurred at these dopant/PDPIN ratios. The ratios of Abs₆₀₀₋₉₀₀ and Abs₁₂₅₀₋₁₈₅₀ of N-DMBI and PSpF-doped PDPIN are 5.9 and 1.6, respectively. The lower ratio of PSpF-doped PDPIN suggests a higher doping efficiency.

To confirm the formation of polarons and bipolarons, and to estimate the spin density, EPR spectra of pristine and doped PDPIN were collected. The EPR intensity is initially increased when the dopant ratios increase as more single electrons are transferred to conjugated subunits. However, when the dopant ratio reaches 75 mol % and 100 wt % for N-DMBI and PSpF, respectively, the EPR intensity decreases somewhat. The spin density of 5 mol % N-DMBI and 50 wt % PSpF-doped PDPIN was calculated to be about 1.2×10²⁰ and 2.4×10²⁰ cm⁻³. If we assume the PDPIN radical anion is the only single electron structure, the corresponding doping efficiency of PSpF is about 50%. Considering that the σ of 5 mol % N-DMBI-doped (19.1±2.4 S cm⁻¹) and 50 wt % PSpF-doped PDPIN (22.2±1.5 S cm⁻¹) are close, it can be concluded that inter-polaron distance and electron mobility could both play roles in the electron transport.

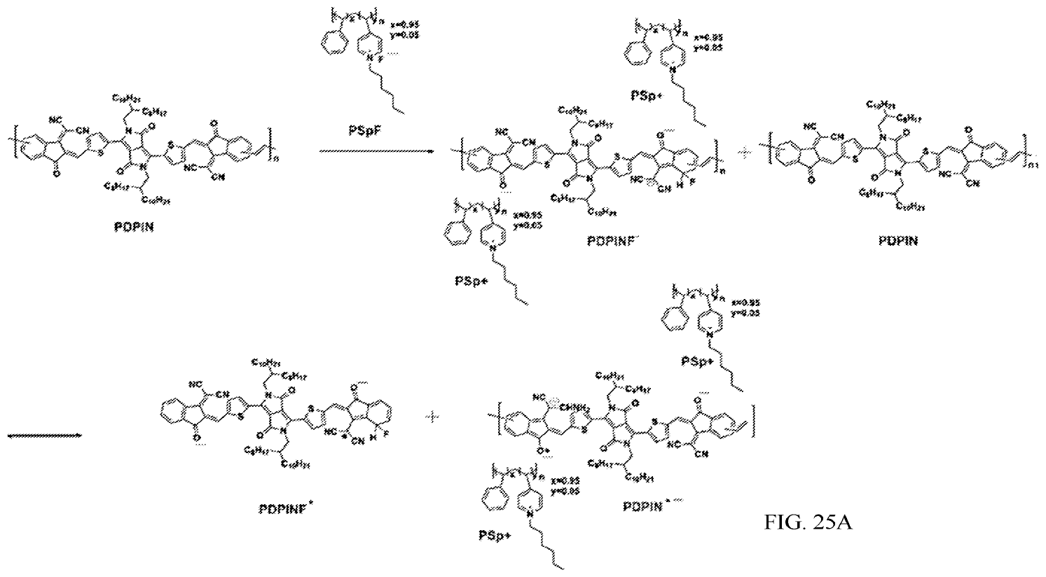

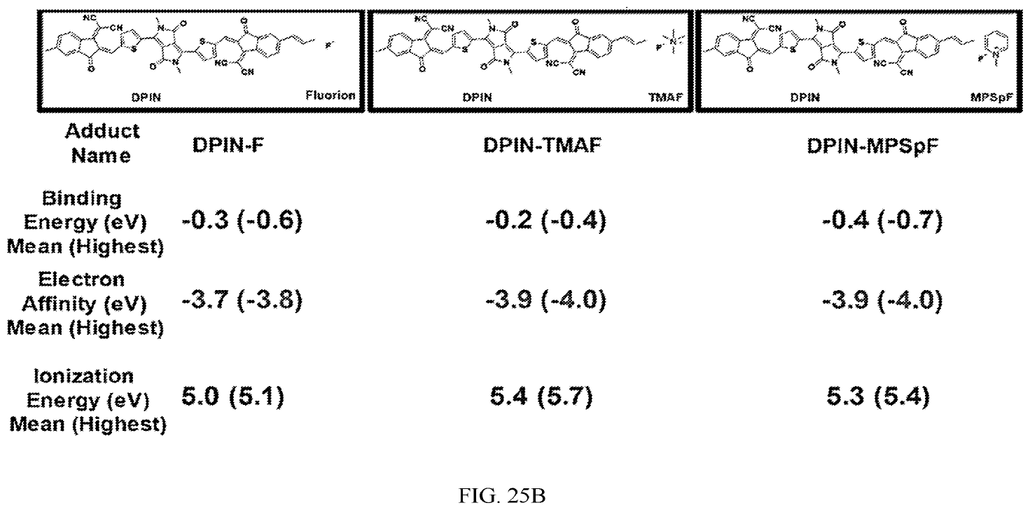

UPS measurements reveal that after doping with 5 mol % N-DMBI, the work function of PDPIN shifts from 3.98 eV to 3.60 eV. The −0.38 eV offset suggests that the Fermi level moves toward the LUMO level which is similar to other N-DMBI-doped polymers and molecules (FIG. 24D). Alternatively, the work function after doping with 75 wt % PSpF shifts to 4.40 eV; a +0.42 eV shift was recorded (FIG. 24D). The Fermi level shift is in the same direction as other F⁻ doped polymer films. This may be caused by the introduction of the electron-withdrawing F atom to segments of the backbone of PDPIN (FIG. 25A).

FIG. 25A shows a doping process of PSpF doped PDPIN, according to an embodiment of the present invention. Other F⁻ addition sites and radical/anion resonance structures are possible. FIG. 25B shows a calculated binding energy and electron affinity of adducts of F⁻, TMAF (model molecule of TBAF) and MPSpF (model molecule of PSpF) and repeat unit DPIN of PSPF, according to an embodiment of the present invention.

The larger shift of work function of DPIN-MPSpF compared to N-DMBI-doped PDPIN is beneficial for more effective doping of PDPIN. The valence bands of N-DMBI- and PSpF-doped PDPIN are 4.33 and 4.16 eV, respectively. The corresponding shifts from pristine PDPIN are 0.89 and 0.72 eV. The higher energy valence bands can lower the energy needed for electrons to reach the conduction bands.

The proposed doping mechanism shown in FIGS. 25A and 25B was evaluated. We hypothesized that F− ions can interact with PDPIN through a stabilizing interaction (FIG. 25A) IR spectra were obtained to support this step in the doping mechanism. For example, the IR signal at 2925 cm⁻¹ (the stretching vibration band of C—H on benzene ring) and at 2222 cm⁻¹ (absorbance peak of the cyano group) was shifted to lower energy, broadened, and decreased in intensity when PDPIN was doped with PSpF, so F⁻ prefers to attack the dicyanomethylene group, either directly or vinylogously.

To further study the doping reaction, density functional theory (DFT) calculations were performed using the ORCA software package. A uniform dielectric constant was applied to the simulation medium (i.e. an “implicit solvent”), via the conductor-like polarizable continuum model (CPCM), to emulate the presence of orthodichlorobenzene, the solvent used in experiments. The DPIN repeat unit of PDPIN was used as a model compound to react with F⁻. TMAF and MPSpF were used as model compounds of TBAF and PSpF, respectively. All adducts of DPIN-F, DPIN-TMAF and DPIN-MPSpF present similar ionization energy of 5.0-5.7 eV. The average binding (interaction stabilization) energy and electron affinity of the adduct of DPIN and F⁻ are −0.3 and −3.7 eV (FIG. 25B). The average binding energy and electron affinity properties of DPIN-TMAF were calculated to be −0.2 and −3.9 eV (FIG. 25B). Here, the lower absolute value of the binding energy suggests a decreased enthalpic favorability of formation, and that the counter-cation of TMA⁺ contributes little to the formation stability of DPIN-TMAF. Compared with DPIN-TMAF, the electron affinity of DPIN-MPSpF does not change, the average binding energy of DPIN-MPSpF is increased to −0.4 eV (FIG. 25B) and the highest binding energy absolute values increases from 0.4 eV to 0.7 eV. The larger absolute value of the binding energy of DPIN-MPSpF suggests MPSpF⁺ has a better capability to stabilize the adduct, which can give higher doping efficiency and σ values. The ionization potential of DPIN-MPSpF is slightly higher than that of DPIN-TMAF, decreasing the difference between the ionization potential of the actual n-dopant and the electron affinity energy levels of PDPIN (FIG. 25B). The geometry optimizations of DPIN-MPSpF with a binding energy of −0.7 eV show that the counter ion of piperidine is mainly located between the backbones of PDPIN, which is consistent with the results of 2D GIWAXS.

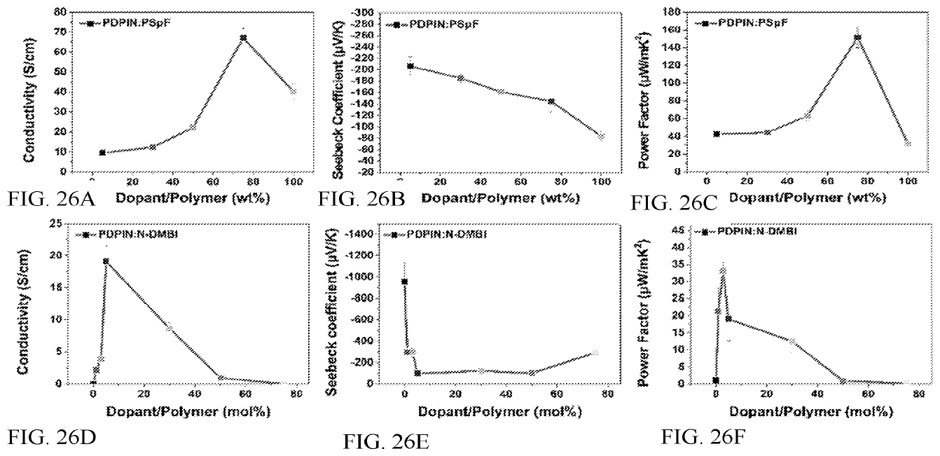

FIG. 26A shows a plot of the electrical conductivity of PSpF, according to an embodiment of the present invention. FIG. 26D shows a plot of the electrical conductivity of N-DMBI doped PDPIN, according to an embodiment of the present invention. FIG. 26B shows a plot of the Seebeck coefficient of PSpF, according to an embodiment of the present invention. FIG. 26E shows a plot of the Seebeck coefficient of N-DMBI doped PDPIN, according to an embodiment of the present invention. FIG. 26C shows a plot of the power factor of PSpF, according to an embodiment of the present invention. FIG. 26F shows a plot of the power factor of N-DMBI doped PDPIN, according to an embodiment of the present invention.

The thermoelectric performance of PDPIN films doped by N-DMBI and PSpF was explored by measuring dropcast films in open air. As shown in FIG. 26A, the σ increases when the PSpF/PDPIN ratios increase from 5 wt % to 75 wt %. The σ (maximum followed by mean and standard deviation in parentheses) of 10.5 (9.5±1), 15.5 (12.3±3.2), 26.3 (23.4±2.9), and 78.1 (67.1±11.1) S cm⁻¹ were recorded at ratios of 5, 30, 50 and 75 wt % (Table 7), respectively.

TABLE 7

| Polymer | κ | σ | S | PF | |
|---|---|---|---|---|---|
| films | W m⁻¹K⁻¹ | S cm⁻¹ | μV K⁻¹ | μW m⁻¹K⁻² | ZT (r. t.) |
| PDPIN: 5 | 0.12 ± 0.02 | 19.1 ± 5.3 | −100 ± 14 | 19.0 ± 6.3 | 0.047 ± 0.016 |
| mol% N- | | | | | |
| DMBI | | | | | |
| PDPIN: 50 | 0.15 ± 0.02 | 1 ± 0.1 | −102 ± 12 | 1.0 ± 0.2 | 0.002 ± 0.0004 |
| mol % N- | | | | | |
| DMBI | | | | | |
| PDPIN: 5 | 0.20 ± 0.03 | 9.5 ± 1 | −206 ± 16 | 42.5 ± 2.0 | 0.06 ± 0.003 |
| wt % PSpF | | | | | |
| PDPIN: 30 | 0.17 ± 0.02 | 12.3 ± 3.2 | −185 ± 10 | 44.2 ± 2.1 | 0.08 ± 0.004 |
| wt % PSpF | | | | | |
| PDPIN: 50 | 0.12 ± 0.02 | 23.4 ± 2.9 | −161 ± 4 | 62.9 ± 5.4 | 0.16 ± 0.01 |
| wt % PSpF | | | | | |
| PDPIN: 75 | 0.093 ± 0.01 | 67.1 ± 11.1 | −145 ± 19 | 151.5 ± 11.5 | 0.49 ± 0.04 |
| wt % PSpF | | | | | |
| PDPIN: 100 | 0.16 ± 0.02 | 40.1 ± 10.4 | −84 ± 10 | 31.6 ± 3.6 | 0.06 ± 0.007 |
| wt % PSpF | | | | | |

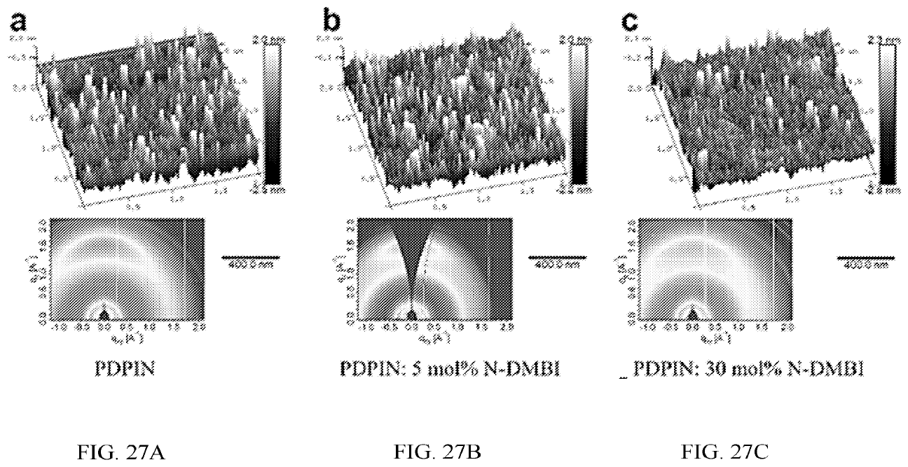

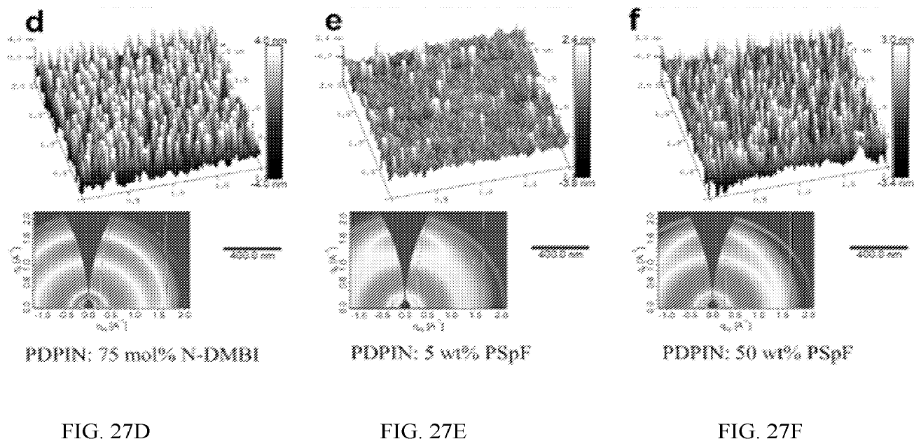

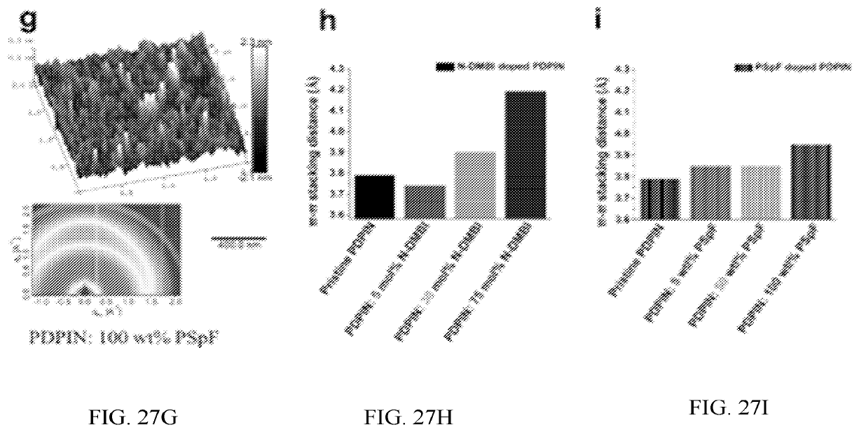

It is worth noting that 75 wt % PSpF doped PDPIN presented the highest c of 78 S cm⁻¹, a breakthrough for n-type all-polymer conductors and thermoelectrics. The relatively high conductivity can be attributed to high doping efficiency, high mobility, enhanced conjugation and little disordering caused by PSpF (FIGS. 27A-27I).

FIG. 27A shows AFM height image and GIWAXS pattern of a pristine PDPIN, according to an embodiment of the present invention. FIG. 27B shows AFM height image and GIWAXS pattern of a 5 mol % N-DMBI doped PDPIN film, according to an embodiment of the present invention. FIG. 27C shows AFM height image and GIWAXS pattern of a 30 mol % N-DMBI doped PDPIN film, according to an embodiment of the present invention. FIG. 27D shows AFM height image and GIWAXS pattern of a 75 mol % N-DMBI doped PDPIN film, according to an embodiment of the present invention. FIG. 27E shows AFM height image and GIWAXS pattern of 5 wt % PSpF doped PDPIN film, according to an embodiment of the present invention. FIG. 27F shows AFM height image and GIWAXS pattern of 50 wt % PSpF doped PDPIN film, according to an embodiment of the present invention. FIG. 27G shows AFM height image and GIWAXS pattern of 100 wt % PSpF doped PDPIN film. FIG. 27H shows the t-t stacking distance of N-DMBI film, according to an embodiment of the present invention. FIG. 27I shows the t-t stacking distance of PSpF doped PDPIN film, according to an embodiment of the present invention.

The conductivity is much higher than for PSpF-doped PFClTVT, perhaps because the conjugation of adduct PFClTVT-PSpF is weakened and the conjugation of adduct PDPIN-PSpF is enhanced. Moreover, the diradicals of PDPIN can enable a more efficient doping process and higher conductivity. When the PSpF/PDPIN ratio increases to 100 wt %, σ decreases to 50 (40±10) S cm⁻¹ (FIG. 26A), due to the lower ordering and larger π-π stacking distance caused by a higher proportion of dopant PSpF. N-DMBI-doped polymers have generally shown higher σ compared to other dopants. From FIGS. 26A-26F and FIGS. 27A-27I, we suggest that N-DMBI-doped PDPIN films have lower σ, because the polymer molecular stacking was disordered by N-DMBI when the N-DMBI ratio was over 5 mol % (FIGS. 26A-26F, FIGS. 27A-27I). The highest σ value of 19.1±5.3 S cm⁻¹ was achieved in a N-DMBI ratio of 5 mol %; the σ decreased to 10.6 and 1.1 S cm⁻¹ for 30 and 50 mol % N-DMBI-doped PDPIN, respectively (FIG. 26D). The average absolute negative S values of PSpF-doped PDPIN decrease gradually from 206±16 to 84±10 μV K⁻¹ as the PSpF ratio increases from 5 to 100 wt % (FIG. 26B). Though the absolute value of S of PSpF-doped PDPIN is relatively high, it remains very reasonable and very close to the trend of other p-type and n-type organic thermoelectric materials. It is very difficult to achieve the highest σ and power factor simultaneously because the absolute values of S usually decrease when σ increases.^{26,54} Here, the absolute S values of PSpF-doped PDPIN decrease relatively slowly when σ increases; 75 wt % PSpF-doped PDPIN presents the highest σ and power factor simultaneously, which is very rare and useful for thermoelectrics. The highest power factors are 163 (145±19) μW m⁻¹K⁻² at room temperature, among the best results reported for organic thermoelectrics (FIG. 26C). Moreover, high power factors of 44 (42.5±2), 46 (44.2±2.1), 68 (62.9±5.4) and 35 (31.6±3.6) μW m⁻¹K⁻² were achieved at PSpF ratios of 5, 30, 50, and 100 wt % (Table 7), respectively. All these values are also very high for organic thermoelectrics, showing that PDPIN appears particularly well-suited for use with the polymer dopant PSpF. For N-DMBI-doped films, 3 mol % N-DMBI-doped PDPIN shows the highest power factor of 36 (33.1±2.9) μW m⁻¹K⁻² (FIG. 26F), with a corresponding σ of 4 (3.8±0.3) S cm⁻¹ (FIG. 26D). The power factor of doped films with 5 and 30 mol % N-DMBI ratios are 25 (19±6.3) and 16 (12.4±3.3) μW m⁻¹K⁻² (FIG. 26F), respectively. The power factor values are, again, among the best results of N-DMBI-doped polymers, suggesting PDPIN is a promising polymer for n-type organic thermoelectrics.

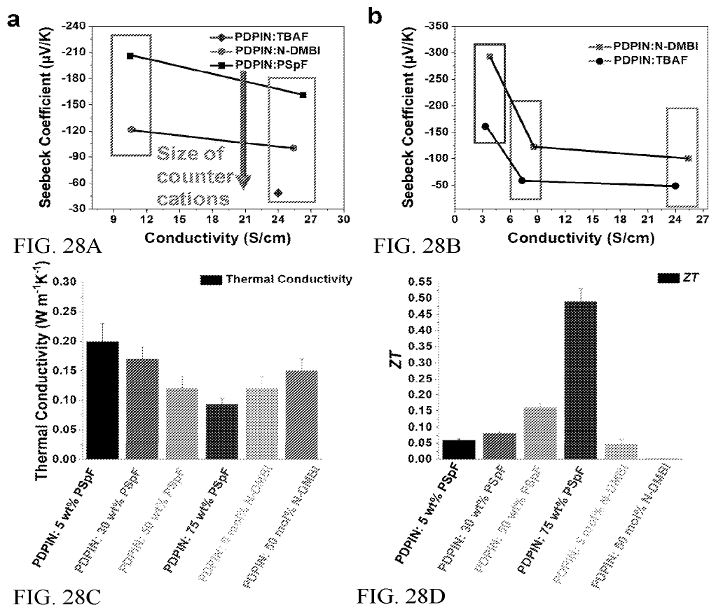

FIG. 28A shows the Seebeck coefficient of TBAF, N-DMBI and PSpF doped PDPIN at similar electrical conductivity levels, according to an embodiment of the present invention. FIG. 28B shows the Seebeck coefficient of TBAF and N-DMBI doped PDPIN at similar electrical conductivity levels, according to an embodiment of the present invention. FIG. 28C shows the thermal conductivity of N-DMBI doped films, according to an embodiment of the present invention. FIG. 28D shows the ZT of PSpF doped films, according to an embodiment of the present invention.

The higher S values of PSpF-doped PDPIN relative to its a can be attributed to the larger distance between counter-cation and -anion, which is caused by the large polymer molecule size of PSpF. To further confirm this hypothesis, we measured PDPIN films doped with TBAF, which has a much smaller volume per dopant molecule. Although 30 mol % TBAF-doped PDPIN presents the highest σ of 24 S cm⁻¹, the corresponding power factor is only 5.6 μW m⁻¹K⁻², which is much lower than that of N-DMBI and PSpF doped films with similar a values. The S values at similar a levels are summarized in FIGS. 28A and 28B. When a is about 10 S cm⁻¹, S for PSpF and N-DMBI-doped PDPIN are −206 and −122 μV K⁻¹, respectively; When σ is about 25 S cm⁻¹, S values of PSpF-, N-DMBI- and TBAF-doped PDPIN are −161, −100 and −49 μV K⁻¹, respectively. These absolute values decrease when the size of the counter-cations decrease, probably due to the fact that the sizes of counter-cations play a key role in determining host-dopant distances and further affect the Coulombic interaction. S of N-DMBI- and TBAF-doped PDPIN at σ levels of about 3 and 7 S cm⁻¹ also follows the same trend (FIG. 28B). To further confirm that the major contribution to S is due to electron, rather than ion, redistribution, time-dependent thermal voltage responses of N-DMBI and PSpF-doped PDPIN were recorded. The thermal voltages of PSpF-doped PDPIN at different temperature gradients are stable; this result is similar to that of N-DMBI-doped PDPIN films. Though 5 mol % N-DMBI and 75 wt % PSpF-doped PDPIN have different σ values, the activation energy is similar, being 181 and 186 meV, respectively.

As a final check whether the high σ and S values for PSpF-doped PDPIN arises from electron transport, we recorded the time (1 h)-dependent current through 75 wt % PSpF-doped PDPIN with an application of −50 V. The current is fairly stable over one hour, suggesting electron transport contributes to the high σ. The mean current is 1.65 milliamps: 3600 seconds×1.65 milliamps which equates to 5.94 coulombs, or 3.7×10¹⁹ electrons; this would be 6.2×10⁻⁵ moles. A typical polymer density is generally about 1-1.1 g cm⁻³; with polystyrene specifically about 1 g cm⁻³. Thus, the volume of a mole of PDPIN repeat units plus the dopant PSpF is about 1430 cm³. The 6.2×10⁻⁵ moles should have a volume of 0.09 cm³. However, the real volume of doped films is below 10⁻⁴ cm³, so there are many more moving charges than ions in the PSpF-doped PDPIN film, further revealing the all-electronic transport in the film.

Thermal conductivity measurements were undertaken to determine the figure of merit of doped films. The thermal conductivity decreases when the ratio of PSpF increases from 5 wt % to 75 wt % (FIG. 28C). The average thermal conductivity values are 0.21, 0.16, 0.13 and 0.099 W m⁻¹K⁻¹ for 5, 30, 50 and 75 wt % PSpF doped films (Table 7). When the ratio of PSpF/PDPIN is 100 wt %, the thermal conductivity increases to 0.16 W m⁻¹K⁻¹. It is interesting to note that the films of 75 wt % PSpF-doped PDPIN present the highest σ, power factor and lowest thermal conductivity among PSpF-doped films, giving a record-breaking maximum ZT (0.53 at room temperature) among n-type all-polymer thermoelectrics (FIG. 28D), which is comparable with that of n-type inorganic thermoelectrics at room temperature. The calculated highest ZT (means and standard deviations follow) of 5, 30 and 50 wt % PSpF-doped PDPIN are 0.063 (0.06±0.003), 0.087 (0.08±0.004) and 0.17 (0.16±0.01) (Table 7), respectively. The values are also substantial compared to recently reported n-type organic thermoelectrics. The highest figures of merit of 5 and 50 mol % N-DMBI-doped PSpF are 0.063 (0.047±0.016) and 0.0024 (0.002=0.0004) (Table 7), respectively, which are much lower than those of PSpF doped films, further demonstrating the potential and advantage of PSpF.

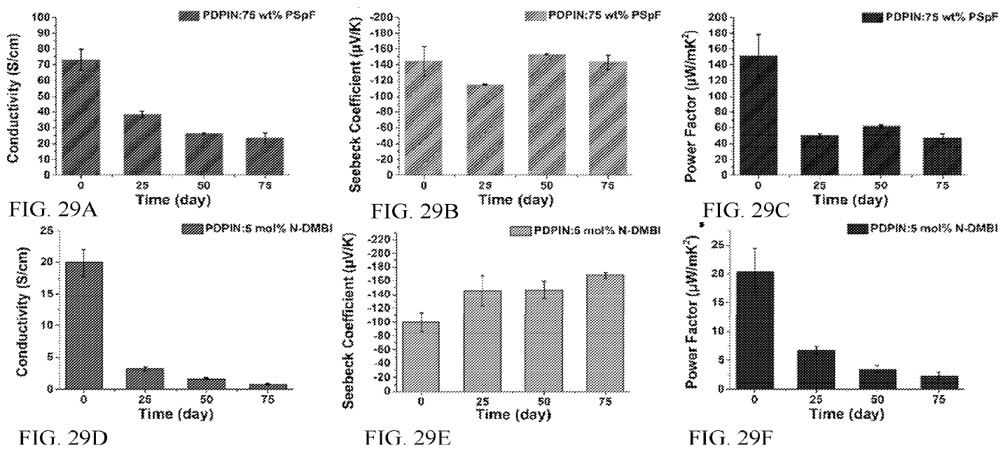

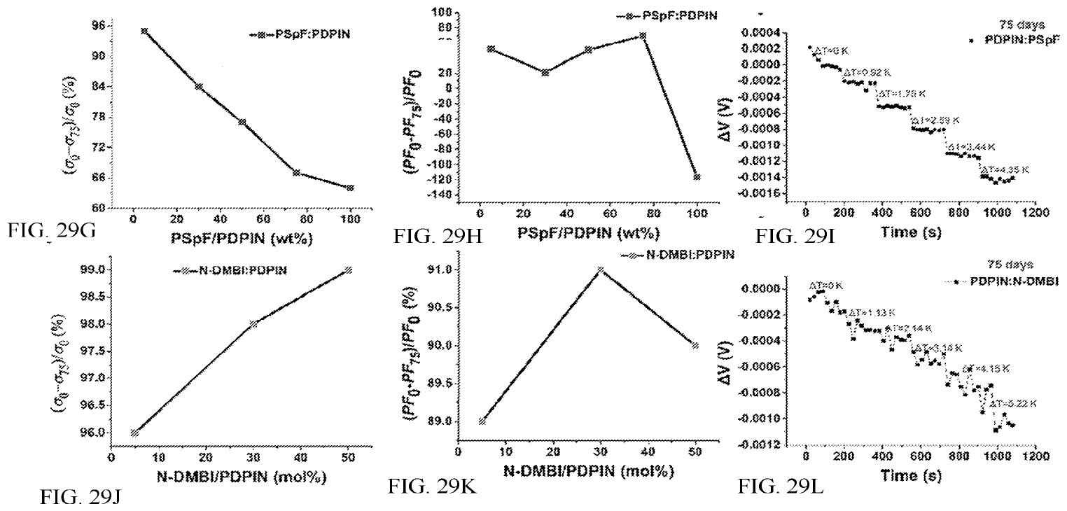

FIG. 29A is a plot of Air stability of electrical conductivity of 5 mol % N-DMBI doped PDPIN film, according to an embodiment of the present invention. FIG. 29B is a plot of Seebeck coefficient of 5 mol % N-DMBI doped PDPIN, film according to an embodiment of the present invention. FIG. 29C is a plot of power factor of 75 wt % PSpF doped PDPIN film, according to an embodiment of the present invention. FIG. 29D is a plot of Air stability of electrical conductivity of 5 mol % N-DMBI doped PDPIN film, according to an embodiment of the present invention. FIG. 29E is a plot of Seebeck coefficient of 5 mol % N-DMBI doped PDPIN film, according to an embodiment of the present invention. FIG. 29F is a plot of power factor of 5 mol % N-DMBI doped PDPIN film, according to an embodiment of the present invention. FIG. 29G is a plot of change of electrical conductivity of PSpF doped PDPIN film, according to an embodiment of the present invention. FIG. 29H is a plot of power factor of PSpF doped PDPIN film after 75 days relative to initial conductivity, according to an embodiment of the present invention. FIG. 29I is a plot of the time-dependent thermoelectric potential responses of 75 wt % PSpF doped PDPIN film, according to an embodiment of the present invention. FIG. 29J is a plot of change of electrical conductivity of N-DMBI doped PDPIN film after 75 days relative to initial conductivity, according to an embodiment of the present invention. FIG. 29K is a plot of power factor of N-DMBI doped PDPIN film after 75 days relative to initial conductivity, according to an embodiment of the present invention. FIG. 29L is a plot of the time-dependent thermoelectric potential responses of 5 mol % N-DMBI doped PDPIN film, according to an embodiment of the present invention.

The air stability of doped PDPIN films is studied by recording σ at 0, 25, 50 and 75 days after storing in ambient conditions. PSpF-doped PDPIN presents much higher air stability of σ than that of N-DMBI-doped PDPIN (FIGS. 29A-29L). Usually n-type organic thermoelectric materials are only stable when the films are microns thick, and few works report air stability beyond 10 days. Here, we observed the stability of doped films with nanometer thickness after exposure to air over two months. The initial σ can be defined as σ₀, and σ after 75 days can be defined as 175. In the first 25 days, σ of 75 wt % PSpF- and 5 mol % N-DMBI-doped PDPIN decreased by 43% and 84% (FIG. 29A and FIG. 29D), respectively. PSpF-doped films not only exhibit higher σ, but also have much better performance than that of N-DMBI-doped films, suggesting the PSpF is very suitable dopant for polymer PDPIN. The reduction of the mean values of σ for 75 wt % PSpF-doped PDPIN at 50 and 75 days (σ₇₅) are 31% and 9%, respectively. Even then, both of the highest σ at 50 and 75 days are 27.4 S cm⁻¹, suggesting an excellent long-term air stability. The corresponding decreases of 5 mol % N-DMBI-doped PDPIN are 47% and 53%, suggesting thin films of N-DMBI-doped films cannot form effective self-encapsulated structures as previously hypothesized for thick films. The S absolute values of 75 wt % PSpF-doped PDPIN change little; and the values for 5 mol % N-DMBI-doped PDPIN increase with time delay (FIGS. 29B and 29E). It is very interesting that the decrease of σ decreases with an increase in PSpF weight ratio (FIG. 29G). The decreases of 5, 30, 50, 75 and 100 wt % PSpF-doped PDPIN after 75 days are 95%, 84%, 77%, 67% and 64%, respectively. These results further confirm that PSpF plays a key role in the stability of doped PDPIN: the abundant polystyrene fragments can prevent water and oxygen from diffusing into the doped films. The decreases of 5, 30, and 50 mol % N-DMBI-doped PDPIN are 96%, 98% and 99% (FIG. 29J); they are much higher than that of PSpF doped films and increase along with the molar ratio of N-DMBI, suggesting that N-DMBI may play a destructive role in stability of doped films. The initial power factor can be defined as PF₀, and the power factor after 75 days can be defined as PF₇₅. The S absolute values of 5, 30, 50, and 100 wt % PSpF-doped PDPIN increase with time delay. On the other hand, σ decreases over time. The corresponding percent decreases of power factors after 75 days are 52%, 21%, 51%, and −117% (an increase!) (FIG. 29H), respectively. It is surprising that the power factors of 100 wt % PSpF-doped PDPIN did not decrease, but instead increased to a value of 90 W m⁻¹ K⁻² because of the relatively low decrease of σ and higher increase of S values. Although S absolute values of N-DMBI-doped PDPIN also increased with time delay, the decreases of σ values are so high that the power factors dropped drastically. The decrease of 5, 30 and 50 mol % N-DMBI-doped PDPIN are about 90% (FIG. 29K) which is much higher than that of PSpF-doped PDPIN. To further check the stability of doped films, we explored time-dependent voltage response measurements. Both the N-DMBI- and PSpF-doped PDPIN films present stable voltage responses after 50 days, even more stable than the initial devices because of increased S absolute values. After 75 days, the time-dependent voltage response of N-DMBI-doped films became unstable, perhaps because of the lower σ. The stability of PSpF-doped PDPIN hardly changes after 75 days compared with that of the initial devices.

The morphology and molecular packing of films can help us further understand the underlying doping mechanism and characteristics. AFM, GIWAXS and SEM measurements were performed on the doped films. As shown in FIGS. 27A-27I, the polymer PDPIN presents low crystallinity and low-intensity lamellar stacking. The low order of lamellar stacking of PDPIN did not affect the high 6 values of doped films, suggesting highly ordered lamellar stacking is not necessary for n-type organic conductors. After doping with N-DMBI or PSpF, all of the lamellar stacking peaks are detected at q_{xy}=0.233 Å⁻¹, resulting in a distance of 26.97 Å, suggesting that the dopant molecules have no effect on the lamellar stacking of PDPIN and indicating that some intercalation of dopant segments occurs within the backbone parts of the conjugated polymers. There was no (010) peak detected in the in-plane diffractions of pristine and doped PDPIN films, which reveals that PDPIN films tend to have a face-on orientation packing with a π-π stacking distance of 3.79 Å. FIGS. 27B, 27C and 27D show a significant effect of N-DMBI on the molecular arrangement of PDPIN molecules: the diffraction intensity of π-π stacking was reduced when the N-DMBI molar ratio increased. After doping with 5 mol % N-DMBI, the π-π stacking distance slightly decreased to 3.74 Å, indicating that N-DMBI has good miscibility at low molar ratio. When the N-DMBI molar ratio increased further, the π-π stacking distance increased significantly, 30 and 75 mol % N-DMBI-doped PDPIN have π-π stacking distances of 3.90 and 4.19 Å (FIG. 27H), respectively. It is interesting that PSpF has a much smaller effect on the π-π stacking, and the diffraction intensity hardly changes after doping with PSpF. The π-π stacking distances are 3.85, 3.85 and 3.95 Å for 5, 50 and 100 wt % PSpF-doped PDPIN films (FIG. 27I), suggesting that PSpF may have better miscibility with PDPIN at high weight or molar ratios. 5 mol % N-DMBI-doped PDPIN presents a root-mean-square (RMS) roughness of 0.74 nm which is much lower than that of pristine PDPIN films (2.16 nm), again suggesting N-DMBI has a good miscibility with PDPIN at this ratio, which is consistent with the result of the GIWAXS measurement. However, when the N-DMBI molar ratio increases to 30 and 75 mol %, the RMS roughness increases to 1.28 and 2.35 nm, respectively. The results reveal that N-DMBI can self-aggregate at high concentrations, which can be confirmed by the AFM phase images and EDS measurement. Also, numerous discontinuous columnar structures in 75 mol % N-DMBI-doped PDPIN films may be another reason for the much lower σ. The RMS roughness are 1.25, 1.33, and 0.65 nm for 5, 50, and 100 wt % PSpF-doped PDPIN films. All the roughness values are much lower than for pristine PDPIN, especially for 100 wt % PSpF-doped PDPIN, suggesting that PSpF has good miscibility with PDPIN, which can be confirmed by AFM phase images. Our previous report suggests that F cannot be detected in EDS measurement for pristine PSpF films because F⁻ can escape as HF and other compounds in high vacuum. In contrast, after doping with conjugated polymers, F can now be detected because of the high bond energy of covalent bonds. Here, we detected the F element in the 5, 30, 50, 75, and 100 wt % doped PDPIN films, and the content of F is enhanced when the PSpF ratio increases. These results further confirm our speculation regarding the doping reactions. We also found that the distribution of element F is not uniform in EDS measurement because some PDPIN have no F according to the doping mechanism (FIG. 25A), indicating that self-aggregations of PDPIN molecules with F or without F form. This phenomenon has no effect on the electron transport because all the doped PDPIN molecules are potentially conductive.

To further explore the effect of doping on the electron transport of films, thin film transistors with a top-gate bottom-contact (TGBC) configuration were prepared and studied. The pristine PDPIN thin films present an electron mobility of 0.01 cm² V⁻¹ s⁻¹, lower than other n-type polymers with higher crystallinity because of the slightly disordered molecular arrangement. The lower/higher mobility of pristine films does not mean that the polymer cannot achieve higher/lower σ at high doping concentrations, because the ordered arrangement of molecules will be changed by dopants. The electron mobility is enhanced to 0.11 cm² V⁻¹ s⁻¹ after doping with 0.2 mol % N-DMBI. On the other hand, the electron mobility of 2 mol % N-DMBI-doped PDPIN decreased to 0.0035 cm² V⁻¹ s⁻¹ may be because of disordering caused by N-DMBI. The electron mobility of 0.5 wt % PSpF-doped PDPIN increases to 0.071 cm² V⁻¹ s⁻¹, and 5 wt % PSpF-doped PDPIN presents a much higher electron mobility of 0.42 cm² V⁻¹ s⁻¹. These results further suggest that PSpF has a strong doping ability with PDPIN and hardly affects the polymer molecular arrangement.

N-type all-polymer organic conductors and thermoelectrics with high electrical conductivity have been demonstrated. Higher electrical conductivity, power factor, ZT, and lowest thermal conductivity were achieved at the same dopant/host ratio for PSpF doped PDPIN films. The excellent doping performance of all-polymer films was confirmed by UV-vis-NIR absorbance spectra, EPR spectra, UPS spectra, and EDS measurement, associated with DFT calculations. The remarkable dopant-host miscibility of PSpF doped PDPIN at high dopant ratio were proved by 2D GIWAXS, AFM, and SEM measurements. Embodiments of the present invention described in the above paragraphs can promote the development of flexible energy devices and conductors.

### REFERENCES

Yan, X.; Xiong, M.; Deng, X.-Y.; Liu, K.-K.; Li, J.-T.; Wang, X.-Q.; Zhang, S.; Prine, N.; Zhang, Z.; Huang, W.; Wang, Y.; Wang, J.-Y.; Gu, X.; So, S. K.; Zhu, J.; Lei, T., Approaching disorder-tolerant semiconducting polymers. Nat. Commun. 2021, 12 (1), 5723, 10.1038/s41467-021-26043-y.
Wang, Y.; Takimiya, K., Naphthodithiophenediimide-Bithiopheneimide Copolymers for High-Performance n-Type Organic Thermoelectrics: Significant Impact of Backbone Orientation on Conductivity and Thermoelectric Performance. Adv. Mater. 2020, 32 (30), 2002060, https://doi.org/10.1002/adma.202002060.
Ma, W.; Shi, K.; Wu, Y.; Lu, Z. Y.; Liu, H. Y.; Wang, J. Y.; Pei, J., Enhanced Molecular Packing of a Conjugated Polymer with High Organic Thermoelectric Power Factor. ACS Appl. Mater. Inter. 2016, 8 (37), 24737-43, 10.1021/acsami.6b06899.
Zhao, X.; Madan, D.; Cheng, Y.; Zhou, J.; Li, H.; Thon, S. M.; Bragg, A. E.; DeCoster, M. E.; Hopkins, P. E.; Katz, H. E., High Conductivity and Electron-Transfer Validation in an n-Type Fluoride-Anion-Doped Polymer for Thermoelectrics in Air. Adv. Mater. 2017, 29 (34), 1606921, 10.1002/adma.201606928.
Kim, J.; Khim, D.; Baeg, K.-J.; Park, W.-T.; Lee, S.-H.; Kang, M.; Noh, Y.-Y.; Kim, D.-Y., Systematic Study of Widely Applicable N-Doping Strategy for High-Performance Solution-Processed Field-Effect Transistors. Adv. Funct. Mater. 2016, 26 (43), 7886-7894, https://doi.org/10.1002/adfm.201602610.
Paterson, A. F.; Savva, A.; Wustoni, S.; Tsetseris, L.; Paulsen, B. D.; Faber, H.; Emwas, A. H.; Chen, X.; Nikiforidis, G.; Hidalgo, T. C.; Moser, M.; Maria, I. P.; Rivnay, J.; McCulloch, I.; Anthopoulos, T. D.; Inal, S., Water stable molecular n-doping produces organic electrochemical transistors with high transconductance and record stability. Nat. Commun. 2020, 11 (1), 3004, 10.1038/s41467-020-16648-0.
Han, J.; Ganley, C.; Hu, Q.; Zhao, X.; Clancy, P.; Russell, T. P.; Katz, H. E., Using Preformed Meisenheimer Complexes as Dopants for n-Type Organic Thermoelectrics with High Seebeck Coefficients and Power Factors. Adv. Funct. Mater. 2021, 31 (18), 2010567, https://doi.org/10.1002/adfm.202010567.
Cui, K.; Lu, X.; Cui, W.; Wu, J.; Chen, X.; Lu, Q., Fluorescent nanoparticles assembled from a poly(ionic liquid) for selective sensing of copper ions. Commun. Chem. 2011, 47 (3), 920-922, 10.1039/C₀CC03900D.
Han, J.; Fan, H.; Zhang, Q.; Hu, Q.; Russell, T. P.; Katz, H. E., Dichlorinated Dithienylethene-Based Copolymers for Air-Stable n-Type Conductivity and Thermoelectricity. Adv. Funct. Mater. 2021, 31 (5), 2005901, https://doi.org/10.1002/adfm.202005901.
Shi, K.; Zhang, F.; Di, C. A.; Yan, T. W.; Zou, Y.; Zhou, X.; Zhu, D.; Wang, J. Y.; Pei, J., Toward High Performance n-Type Thermoelectric Materials by Rational Modification of BDPPV Backbones. J. Am. Chem. Soc. 2015, 137 (22), 6979-82, 10.1021/jacs.5b00945.
Lu, Y.; Wang, J.-Y.; Pei, J., Strategies To Enhance the Conductivity of n-Type Polymer Thermoelectric Materials. Chem. Mater. 2019, 31 (17), 6412-6423, 10.1021/acs.chemmater.9b01422.
Novoselov, K. S.; Geim, A. K.; Morozov, S. V.; Jiang, D.; Zhang, Y.; Dubonos, S. V.; Grigorieva, I. V.; Firsov, A. A., Electric Field Effect in Atomically Thin Carbon Films. Science 2004, 306 (5696), 666, 10.1126/science.1102896.
A. F. Paterson, A. Savva, S. Wustoni, L. Tsetseris, B. D. Paulsen, H. Faber, A. H. Emwas, X. Chen, G. Nikiforidis, T. C. Hidalgo, M. Moser, I. P. Maria, J. Rivnay, I. McCulloch, T. D. Anthopoulos, S. Inal, Nat. Commun. 2020, 11, 3004.
Y. Han, H. Zhao, C. Duan, S. Yang, Z. Yang, Z. Liu, S. Liu, Adv. Funct. Mater. 2020, 30, 1909972.
H. L. Smith, J. T. Dull, E. Longhi, S. Barlow, B. P. Rand, S. R. Marder, A. Kahn, Adv. Funct. Mater. 2020, 30, 2000328.
J. Graciani, A. Nambu, J. Evans, J. A. Rodriguez, J. F. Sanz, J. Am. Chem. Soc. 2008, 130, 12056-12063.
H. Chen, M. Moser, S. Wang, C. Jellett, K. Thorley, G. T. Harrison, X. Jiao, M. Xiao, B. Purushothaman, M. Alsufyani, H. Bristow, S. De Wolf, N. Gasparini, A. Wadsworth, C. R. McNeill, H. Sirringhaus, S. Fabiano, I. McCulloch, J. Am. Chem. Soc. 2021, 143, 260-268; b) Y. Lu, J.-Y. Wang, J. Pei, Acc. Chem. Res. 2021, 54, 2871-2883;
M. Xiong, X. Yan, J.-T. Li, S. Zhang, Z. Cao, N. Prine, Y. Lu, J.-Y. Wang, X. Gu, T. Lei, Angew. Chem. Int. Ed. 2021, 60, 8189-8197.
S. Yang, P. Qiu, L. Chen, X. Shi, Small Science 2021, 1, 2100005; b) Y. Zhang, S.-J. Park, Polymers 2019, 11, 909; c) Y. Zhao, L. Liu, F. Zhang, C.-a. Di, D. Zhu, SmartMat 2021, DOI:10.1002/smm2.1034.
Y. Xia, K. Sun, J. Ouyang, Adv. Mater. 2012, 24, 2436-2440.
J. G. Tait, B. J. Worfolk, S. A. Maloney, T. C. Hauger, A. L. Elias, J. M. Buriak, K. D. Harris, Sol. Energy Mater. Sol. Cells 2013, 110, 98-106.
Y. Lu, J.-Y. Wang, J. Pei, Chem. Mater. 2019, 31, 6412-6423.
Y. Sun, C.-A. Di, W. Xu, D. Zhu, Adv. Electron. Mater. 2019, 5, 1800825.
X. Yan, M. Xiong, X.-Y. Deng, K.-K. Liu, J.-T. Li, X.-Q. Wang, S. Zhang, N. Prine, Z. Zhang, W. Huang, Y. Wang, J.-Y. Wang, X. Gu, S. K. So, J. Zhu, T. Lei, Nat. Commun. 2021, 12, 5723.
C. Dong, S. Deng, B. Meng, J. Liu, L. Wang, Angew. Chem. Int. Ed. 2021, 60, 16184-16190.
J. Han, H. Fan, Q. Zhang, Q. Hu, T. P. Russell, H. E. Katz, Adv. Funct. Mater. 2021, 31, 2005901.
Y. Wang, K. Takimiya, Adv. Mater. 2020, 32, 2002060.
W. Ma, K. Shi, Y. Wu, Z. Y. Lu, H. Y. Liu, J. Y. Wang, J. Pei, ACS Appl. Mater. Inter. 2016, 8, 24737-24743.
C. Y. Yang, W. L. Jin, J. Wang, Y. F. Ding, S. Nong, K. Shi, Y. Lu, Y. Z. Dai, F. D. Zhuang, T. Lei, C. A. Di, D. Zhu, J. Y. Wang, J. Pei, Adv. Mater. 2018, 30, e1802850.
B. Russ, A. Glaudell, J. J. Urban, M. L. Chabinyc, R. A. Segalman, Nat. Rev. Mater. 2016, 1, 16050.
Q. Zhang, Y. Sun, W. Xu, D. Zhu, Adv. Mater. 2014, 26, 6829-6851; b) Y. Chen, Y. Zhao, Z. Liang, Energy Environ. Sci. 2015, 8, 401-422.
W. Park, J. Hu, L. A. Jauregui, X. Ruan, Y. P. Chen, Applied Physics Letters 2014, 104, 113101; b) M. B. Jakubinek, M. A. White, M. Mu, K. I. Winey, Applied Physics Letters 2010, 96, 083105; c) S. A. Al-Ajlan, Appl. Therm. Eng. 2006, 26, 2184-2191.
H. Li, M. E. DeCoster, R. M. Ireland, J. Song, P. E. Hopkins, H. E. Katz, Journal of the American Chemical Society 2017, 139, 11149-11157.
K. Naoi, M. Lien, W. H. Smyrl, J. Electrochem. Soc. 1991, 138, 440-445.
X. Zhao, D. Madan, Y. Cheng, J. Zhou, H. Li, S. M. Thon, A. E. Bragg, M. E. DeCoster, P. E. Hopkins, H. E. Katz, Adv. Mater. 2017, 29, 1606921; b) J. Kim, D. Khim, K.-J. Baeg, W.-T. Park, S.-H. Lee, M. Kang, Y.-Y. Noh, D.-Y. Kim, Adv. Funct. Mater. 2016, 26, 7886-7894.
J. Han, C. Ganley, Q. Hu, X. Zhao, P. Clancy, T. P. Russell, H. E. Katz, Adv. Funct. Mater. 2021, 31, 2010567.
K. Cui, X. Lu, W. Cui, J. Wu, X. Chen, Q. Lu, Commun. Chem. 2011, 47, 920-922.
G. Moad, E. Rizzardo, S. H. Thang, Chem-Asian J. 2013, 8, 1634-1644.
T. Li, C. Zhou, M. Jiang, Polym. Bull. 1991, 25, 211-216.
C. S. Abeywickrama, Y. Pang, New J. Chem. 2021, 45, 9102-9108; b) X. Liu, X. Liu, Y. Shen, B. Gu, ACS Omega 2020, 5, 21684-21688.
B. D. Naab, X. Gu, T. Kurosawa, J. W. F. To, A. Salleo, Z. Bao, Adv. Electron. Mater. 2016, 2, 1600004.
J. L. Bredas, G. B. Street, Acc. Chem. Res. 1985, 18, 309-315.
X. Yan, M. Xiong, J. T. Li, S. Zhang, Z. Ahmad, Y. Lu, Z. Y. Wang, Z. F. Yao, J. Y. Wang, X. Gu, T. Lei, J. Am. Chem. Soc. 2019, 141, 20215-20221.
K. Shi, F. Zhang, C. A. Di, T. W. Yan, Y. Zou, X. Zhou, D. Zhu, J. Y. Wang, J. Pei, J. Am. Chem. Soc. 2015, 137, 6979-6982; b) J. Liu, B. van der Zee, R. Alessandri, S. Sami, J. Dong, M. I. Nugraha, A. J. Barker, S. Rousseva, L. Qiu, X. Qiu, N. Klasen, R. C. Chiechi, D. Baran, M. Caironi, T. D. Anthopoulos, G. Portale, R. W. A. Havenith, S. J. Marrink, J. C. Hummelen, L. J. A. Koster, Nature Communications 2020, 11, 5694; c) C.-Y. Yang, Y.-F. Ding, D. Huang, J. Wang, Z.-F. Yao, C.-X. Huang, Y. Lu, H.-I. Un, F.-D. Zhuang, J.-H. Dou, C.-a. Di, D. Zhu, J.-Y. Wang, T. Lei, J. Pei, Nature Communications 2020, 11, 3292; d) J. Han, A. Chiu, C. Ganley, P. McGuiggan, S. M. Thon, P. Clancy, H. E. Katz, Angew. Chem. Int. Ed. 2021, 60, 27212-27219.
D. G. Cahill, Review of Scientific Instruments 2004, 75, 5119-5122; b) J. L. Braun, S. W. King, A. Giri, J. T. Gaskins, M. Sato, T. Fujiseki, H. Fujiwara, P. E. Hopkins, Applied Physics Letters 2016, 109, 191905.
G. H. Kim, L. Shao, K. Zhang, K. P. Pipe, Nat. Mater. 2013, 12, 719-723.
Y. Lu, Z.-D. Yu, Y. Liu, Y.-F. Ding, C.-Y. Yang, Z.-F. Yao, Z.-Y. Wang, H.-Y. You, X.-F. Cheng, B. Tang, J.-Y. Wang, J. Pei, J. Am. Chem. Soc. 2020, 142, 15340-15348.
W. B. Chang, H. Fang, J. Liu, C. M. Evans, B. Russ, B. C. Popere, S. N. Patel, M. L. Chabinyc, R. A. Segalman, ACS Macro Lett. 2016, 5, 455-459.
K. S. Novoselov, A. K. Geim, S. V. Morozov, D. Jiang, Y. Zhang, S. V. Dubonos, I. V. Grigorieva, A. A. Firsov, Science 2004, 306, 666.
K. Kang, S. Watanabe, K. Broch, A. Sepe, A. Brown, I. Nasrallah, M. Nikolka, Z. Fei, M. Heeney, D. Matsumoto, K. Marumoto, H. Tanaka, S.-i. Kuroda, H. Sirringhaus, Nat. Mater. 2016, 15, 896-902.
J. Han, H. Fan, Q. Zhang, Q. Hu, T. P. Russell, H. E. Katz, Adv. Funct. Mater. 2021, 31, 2005901.
B. Russ, A. Glaudell, J. J. Urban, M. L. Chabinyc, R. A. Segalman, Nat. Rev. Mater. 2016, 1, 16050.
Liu, C., Wang, K., Gong, X. & Heeger, A. J. Low bandgap semiconducting polymers for polymeric photovoltaics. Chemical Society Reviews 45, 4825-4846, doi:10.1039/C5CS00650C (2016).
Garcia de Arquer, F. P., Armin, A., Meredith, P. & Sargent, E. H. Solution-processed semiconductors for next-generation photodetectors. Nature Reviews Materials 2, 16100, doi:10.1038/natrevmats.2016.100 (2017).
Li, M. et al. Noncovalent semiconducting polymer monolayers for high-performance field-effect transistors. Prog. Polym. Sci. 117, 101394, doi:https://doi.org/10.1016/j.progpolymsci.2021.101394 (2021).
Ren, A. et al. Emerging light-emitting diodes for next-generation data communications. Nature Electronics 4, 559-572, doi:10.1038/s41928-021-00624-7 (2021).
Russ, B., Glaudell, A., Urban, J. J., Chabinyc, M. L. & Segalman, R. A. Organic thermoelectric materials for energy harvesting and temperature control. Nat. Rev. Mater. 1, 16050, doi:10.1038/natrevmats.2016.50 (2016).
Ray, T. R. et al. Bio-Integrated Wearable Systems: A Comprehensive Review. Chem. Rev. 119, 5461-5533, doi:10.1021/acs.chemrev.8b00573 (2019).
Ong, S. Y., Zhang, C., Dong, X. & Yao, S. Q. Recent Advances in Polymeric Nanoparticles for Enhanced Fluorescence and Photoacoustic Imaging. Angew. Chem. Int. Ed. 60, 17797-17809, doi:https://doi.org/10.1002/anie.202101964 (2021).
Pierini, F. et al. Polymer-Based Nanomaterials for Photothermal Therapy: From Light-Responsive to Multifunctional Nanoplatforms for Synergistically Combined Technologies. Biomacromolecules 19, 4147-4167, doi:10.1021/acs.biomac.8b01138 (2018).
Dimov, I. B., Moser, M., Malliaras, G. G. & McCulloch, I. Semiconducting Polymers for Neural Applications. Chem. Rev. 122, 4356-4396, doi:10.1021/acs.chemrev.1c00685 (2022).
Massetti, M. et al. Unconventional Thermoelectric Materials for Energy Harvesting and Sensing Applications. Chem. Rev. 121, 12465-12547, doi:10.1021/acs.chemrev.1c00218 (2021).
Lu, Y., Wang, J.-Y. & Pei, J. Strategies To Enhance the Conductivity of n-Type Polymer Thermoelectric Materials. Chem. Mater. 31, 6412-6423, doi:10.1021/acs.chemmater.9b01422 (2019).
Guo, H. et al. Transition metal-catalysed molecular n-doping of organic semiconductors. Nature 599, 67-73, doi:10.1038/s41586-021-03942-0 (2021).
Yan, X. et al. Approaching disorder-tolerant semiconducting polymers. Nature Communications 12, 5723, doi:10.1038/s41467-021-26043-y (2021).
Gainza, J. et al. Evidence of nanostructuring and reduced thermal conductivity in n-type Sb-alloyed SnSe thermoelectric polycrystals. Journal of Applied Physics 126, 045105, doi:10.1063/1.5108569 (2019).
Liu, J. et al. N-type organic thermoelectrics: demonstration of ZT>0.3. Nature Communications 11, 5694, doi:10.1038/s41467-020-19537-8 (2020).
Sun, Y., Di, C.-A., Xu, W. & Zhu, D. Advances in n-Type Organic Thermoelectric Materials and Devices. Advanced Electronic Materials 5, 1800825, doi:https://doi.org/10.1002/aelm.201800825 (2019).
Wei, J. et al. Review of current high-ZT thermoelectric materials. JMatS 55, 12642-12704, doi:10.1007/s10853-020-04949-0 (2020).
Liu, J. et al. Amphipathic Side Chain of a Conjugated Polymer Optimizes Dopant Location toward Efficient N-Type Organic Thermoelectrics. Adv. Mater. 33, 2006694, doi:https://doi.org/10.1002/adma.202006694 (2021).
Aubry, T. J. et al. Tunable Dopants with Intrinsic Counterion Separation Reveal the Effects of Electron Affinity on Dopant Intercalation and Free Carrier Production in Sequentially Doped Conjugated Polymer Films. Adv. Funct. Mater. 30, 2001800, doi:https://doi.org/10.1002/adfm.202001800 (2020).
Aubry, T. J. et al. Dodecaborane-Based Dopants Designed to Shield Anion Electrostatics Lead to Increased Carrier Mobility in a Doped Conjugated Polymer. Adv. Mater. 31, 1805647, doi:https://doi.org/10.1002/adma.201805647 (2019).
Dun, C. et al. Flexible n-type thermoelectric films based on Cu-doped Bi2Se3 nanoplate and Polyvinylidene Fluoride composite with decoupled Seebeck coefficient and electrical conductivity. Nano Energy 18, 306-314, doi:https://doi.org/10.1016/j.nanoen.2015.10.012 (2015).
Yang, C.-Y. et al. A thermally activated and highly miscible dopant for n-type organic thermoelectrics. Nat. Commun. 11, 3292, doi:10.1038/s41467-020-17063-1 (2020).
Han, J. et al. 3,4,5-Trimethoxy Substitution on an N-DMBI Dopant with New N-Type Polymers: Polymer-Dopant Matching for Improved Conductivity-Seebeck Coefficient Relationship. Angew. Chem. Int. Ed. 60, 27212-27219, doi:https://doi.org/10.1002/anie.202110505 (2021).
Liu, J. et al. Enhancing Molecular n-Type Doping of Donor-Acceptor Copolymers by Tailoring Side Chains. Adv. Mater. 30, 1704630, doi:https://doi.org/10.1002/adma.201704630 (2018).
Marks, A. et al. Synthetic Nuances to Maximize n-Type Organic Electrochemical Transistor and Thermoelectric Performance in Fused Lactam Polymers. Journal of the American Chemical Society 144, 4642-4656, doi:10.1021/jacs.2c00735 (2022).
Alsufyani, M. et al. Lactone Backbone Density in Rigid Electron-Deficient Semiconducting Polymers Enabling High n-type Organic Thermoelectric Performance. Angew. Chem. Int. Ed. 61, e202113078, doi:https://doi.org/10.1002/anie.202113078 (2022).
Han, J. et al. Dichlorinated Dithienylethene-Based Copolymers for Air-Stable n-Type Conductivity and Thermoelectricity. Adv. Funct. Mater. 31, 2005901, doi:https://doi.org/10.1002/adfm.202005901 (2021).
Yang, C. Y. et al. Enhancing the n-Type Conductivity and Thermoelectric Performance of Donor-Acceptor Copolymers through Donor Engineering. Adv. Mater. 30, e1802850, doi:10.1002/adma.201802850 (2018).
Feng, K. et al. Cyano-Functionalized n-Type Polymer with High Electron Mobility for High-Performance Organic Electrochemical Transistors. Adv. Mater. n/a, 2201340, doi:https://doi.org/10.1002/adma.202201340 (2022).
Yan, X. et al. Pyrazine-Flanked Diketopyrrolopyrrole (DPP): A New Polymer Building Block for High-Performance n-Type Organic Thermoelectrics. J. Am. Chem. Soc. 141, 20215-20221, doi:10.1021/jacs.9b10107 (2019).
Shi, K. et al. Toward High Performance n-Type Thermoelectric Materials by Rational Modification of BDPPV Backbones. J. Am. Chem. Soc. 137, 6979-6982, doi:10.1021/jacs.5b00945 (2015).
Feng, K. et al. Cyano-Functionalized Bithiophene Imide-Based n-Type Polymer Semiconductors: Synthesis, Structure-Property Correlations, and Thermoelectric Performance. Journal of the American Chemical Society 143, 1539-1552, doi:10.1021/jacs.0c11608 (2021).
Yan, X. et al. Approaching disorder-tolerant semiconducting polymers. Nat. Commun. 12, 5723, doi:10.1038/s41467-021-26043-y (2021).
Lu, Y. et al. Persistent Conjugated Backbone and Disordered Lamellar Packing Impart Polymers with Efficient n-Doping and High Conductivities. Adv. Mater. 33, 2005946, doi:https://doi.org/10.1002/adma.202005946 (2021).
Han, J. et al. A New Polystyrene-Polyvinyl Pyridinium Ionic Copolymer Dopant for N-Type All-Polymer Thermoelectrics with High Stable Conductivity Relative to Seebeck Coefficient Giving High Power Factor. Adv. Mater. n/a, 2201062, doi:https://doi.org/10.1002/adma.202201062 (2022).
Nardes, A. M. et al. Microscopic Understanding of the Anisotropic Conductivity of PEDOT:PSS Thin Films. Adv. Mater. 19, 1196-1200, doi:https://doi.org/10.1002/adma.200602575 (2007).
Xu, K. et al. Ground-state electron transfer in all-polymer donor-acceptor heterojunctions. Nat. Mater. 19, 738-744, doi:10.1038/s41563-020-0618-7 (2020).
Yang, C.-Y. et al. A high-conductivity n-type polymeric ink for printed electronics. Nat. Commun. 12, 2354, doi:10.1038/s41467-021-22528-y (2021).
Naab, B. D. et al. Role of Polymer Structure on the Conductivity of N-Doped Polymers. Adv. Electron. Mater. 2, 1600004, doi:https://doi.org/10.1002/aelm.201600004 (2016).
Bardagot, O. et al. Revisiting doping mechanisms of n-type organic materials with N-DMBI for thermoelectric applications: Photo-activation, thermal activation, and air stability. Applied Physics Letters 118, 203904, doi:10.1063/5.0047637 (2021).
Jacobs, I. E. et al. High-Efficiency Ion-Exchange Doping of Conducting Polymers. Adv. Mater. n/a, 2102988, doi:https://doi.org/10.1002/adma.202102988 (2021).
Bredas, J. L. & Street, G. B. Polarons, bipolarons, and solitons in conducting polymers. Acc. Chem. Res. 18, 309-315, doi:10.1021/ar00118a005 (1985).
Jenekhe, S. A., Lu, L. & Alam, M. M. New Conjugated Polymers with Donor-Acceptor Architectures: Synthesis and Photophysics of Carbazole-Quinoline and Phenothiazine-Quinoline Copolymers and Oligomers Exhibiting Large Intramolecular Charge Transfer. Macromolecules 34, 7315-7324, doi:10.1021/ma0100448 (2001).
Tait, C. E. et al. Spin-spin interactions and spin delocalisation in a doped organic semiconductor probed by EPR spectroscopy. Physical Chemistry Chemical Physics 23, 13827-13841, doi:10.1039/D1CP02133H (2021).
Wang, S.-J. et al. Long spin diffusion lengths in doped conjugated polymers due to enhanced exchange coupling. Nature Electronics 2, 98-107, doi:10.1038/s41928-019-0222-5 (2019).
Lu, Y. et al. Rigid Coplanar Polymers for Stable n-Type Polymer Thermoelectrics. Angew. Chem. Int. Ed. 58, 11390-11394, doi:10.1002/anie.201905835 (2019).
Yuan, D. et al. Cholesteric Aggregation at the Quinoidal-to-Diradical Border Enabled Stable n-Doped Conductor. Chem 5, 964-976, doi:https://doi.org/10.1016/j.chempr.2019.02.010 (2019).
Zhao, X. et al. High Conductivity and Electron-Transfer Validation in an n-Type Fluoride-Anion-Doped Polymer for Thermoelectrics in Air. Adv. Mater. 29, 1606921, doi:10.1002/adma.201606928 (2017).
Guo, X. & Facchetti, A. The journey of conducting polymers from discovery to application. Nature Materials 19, 922-928, doi:10.1038/s41563-020-0778-5 (2020).
Poehler, T. O. & Katz, H. E. Prospects for polymer-based thermoelectrics: state of the art and theoretical analysis. Energy Environ. Sci. 5, 8110-8115, doi:10.1039/C2EE22124A (2012).
Neese, F. The ORCA program system. WIREs Computational Molecular Science 2, 73-78, doi:https://doi.org/10.1002/wcms.81 (2012).
Yang, K. et al. Stable Organic Diradicals Based on Fused Quinoidal Oligothiophene Imides with High Electrical Conductivity. Journal of the American Chemical Society 142, 4329-4340, doi:10.1021/jacs.9b12683 (2020).
Tang, H. et al. Organic diradicals enabled N-type self-doped conjugated polyelectrolyte with high transparency and enhanced conductivity. Giant 6, 100053, doi:https://doi.org/10.1016/j.giant.2021.100053 (2021).
Un, H.-I. et al. Understanding the Effects of Molecular Dopant on n-Type Organic Thermoelectric Properties. Advanced Energy Materials 9, 1900817, doi:https://doi.org/10.1002/aenm.201900817 (2019).
Curcó, D. & Alemán, C. Computational tool to model the packing of polycyclic chains: Structural analysis of amorphous polythiophene. Journal of Computational Chemistry 28, 1743-1749, doi:https://doi.org/10.1002/icc.20687 (2007).
Miller, E. D. et al. Optimization and Validation of Efficient Models for Predicting Polythiophene Self-Assembly. Polymers 10, doi:10.3390/polym10121305 (2018).
De Rosa, C., Guerra, G., Petraccone, V. & Pirozzi, B. Crystal Structure of the Emptied Clathrate Form (δe Form) of Syndiotactic Polystyrene. Macromolecules 30, 4147-4152, doi:10.1021/ma970061q (1997).
Jacobs, I. E. et al. Structural and Dynamic Disorder, Not Ionic Trapping, Controls Charge Transport in Highly Doped Conducting Polymers. Journal of the American Chemical Society 144, 3005-3019, doi:10.1021/jacs.1c10651 (2022).
Ni, Z. et al. Quinoline-Flanked Diketopyrrolopyrrole Copolymers Breaking through Electron Mobility over 6 cm2 V-1 s-1 in Flexible Thin Film Devices. Adv. Mater. 30, 1704843, doi:https://doi.org/10.1002/adma.201704843 (2018).

While various embodiments of the present invention have been described above, it should be understood that they have been presented by way of example only, and not limitation. Thus, the breadth and scope of the present invention should not be limited by any of the above-described illustrative embodiments, or following examples, but should instead be defined only in accordance with the following claims and their equivalents.

The embodiments illustrated and discussed in this specification are intended only to teach those skilled in the art how to make and use the invention. In describing embodiments of the disclosure, specific terminology is employed for the sake of clarity. However, the disclosure is not intended to be limited to the specific terminology so selected. The above-described embodiments, and following examples, may be modified or varied, without departing from the invention, as appreciated by those skilled in the art in light of the above teachings. It is therefore to be understood that, within the scope of the claims and their equivalents, the invention may be practiced otherwise than as specifically described. For example, it is to be understood that the present disclosure contemplates that, to the extent possible, one or more features of any embodiment can be combined with one or more features of any other embodiment.

1. A polymer having the structure 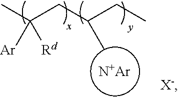
wherein N⁺ Ar is a N-containing monocyclic or bicyclic aromatic ring having 1 or 2 N atoms, at least one of the N atoms is substituted with R^{a} to have a positive charge and the ring is optionally substituted with R^{b},
wherein R^{a} is H, thiophene, furan, pyridine, benzene, thiazole, C₁-C₁₂ alkyl optionally substituted with one or more F atoms, or polyoxyethylene (—(CH₂CH₂O)ₙ—H and R^{b} is H, C₁-C₁₂ alkyl, aralkyl, or C₁-C₁₂ alkoxy, wherein any of the alkyl groups is optionally substituted with one or more F atoms;
Ar is a phenyl or naphthalene ring, optionally substituted with R^{c}′ or CO₂Ph, wherein any of the phenyl or naphthalene rings is substituted with R^{c}, wherein R^{c} is H, C₁-C₁₂ alkyl optionally substituted with one or more F atoms, or C₁-C₁₂ alkoxy optionally substituted with one or more F atoms;
R^{d} is H or Me;
X is halogen, bicarbonate (HCO₃⁻), carbonate, bisulfate (HSO₄⁻), bisulfite (HSO₃⁻), methane sulfonate (MeSO₃⁻), triethyl borohydride (Et₃BH⁻) or a C₁-C₆ carboxylate; and
the ratio of x:y is from about 99:1 to about 1:99.

2. The polymer of claim 1, wherein N⁺ Ar is selected from the group consisting of

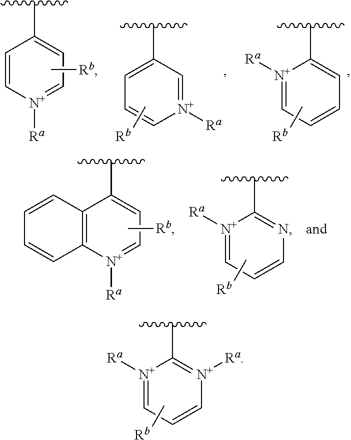

3. The polymer of claim 1, having the structure

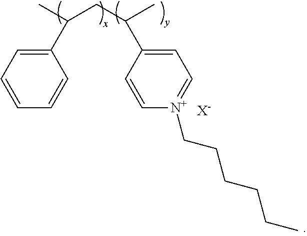

4. A polymer having the structure 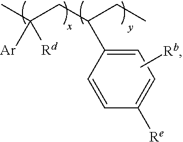
wherein Ar is a phenyl or naphthalene ring, optionally substituted with R^{c}′ or CO₂Ph, wherein any of the phenyl or naphthalene rings is substituted with R^{c}, wherein R^{c} is H, C₁-C₁₂ alkyl optionally substituted with one or more F atoms, or C₁-C₁₂ alkoxy optionally substituted with one or more F atoms;
R^{b} is H, C₁-C₁₂ alkyl, aralkyl, or C₁-C₁₂ alkoxy, wherein any of the alkyl groups is optionally substituted with one or more F atoms;
R^{d} is H or Me;
R^{e} is 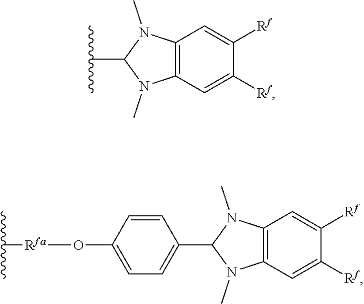
or
—CH₂N⁺R₃ X⁻ or —CH₂P⁺R₃ X⁻,
wherein R^{fa} is a chemical bond, thiophene, furan, pyridine, benzene, thiazole, or C₁-C₆ alkyl optionally having one or more oxygens substituted for carbon and optionally having one or more F atoms on the alkyl chain, R^{f} is H, thiophene, furan, pyridine, benzene, thiazole, or C₁-C₆ alkyl optionally having one or more oxygens substituted for carbon and optionally having one or more F atoms on the alkyl chain, R is C₁-C₆ alkyl and X is halogen, bicarbonate (HCO₃⁻), carbonate, bisulfate (HSO₄⁻), bisulfite (HSO₃⁻), methane sulfonate (MeSO₃⁻), triethyl borohydride (Et₃BH⁻) or a C₁-C₆ carboxylate; and
the ratio of x:y is from about 99:1 to about 1:99.

5. The polymer of claim 4, wherein R is butyl.

6. The polymer of claim 4, wherein R^{f} is H and R^{fa} is a bond.

7. The polymer of claim 1, wherein Ar is a phenyl or naphthalene ring, optionally substituted with R^{c} and R^{d} is H.

8. The polymer of claim 1, wherein the ratio of x:y is from about 95:1 to about 80:20.

9. The polymer of claim 1, wherein the ratio of x:y is from about 95:5 to about 90:10.

10. A polymer comprising the subunit 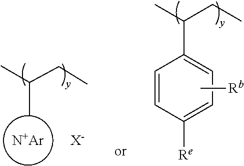
N⁺ Ar is a N-containing monocyclic or bicyclic aromatic ring having 1 or 2 N atoms, at least one of the N atoms is substituted with R^{a} to have a positive charge and the ring is optionally substituted with R^{b},
wherein R^{a} is H, thiophene, furan, pyridine, benzene, thiazole, C₁-C₁₂ alkyl optionally substituted with one or more F atoms, or polyoxyethylene (—(CH₂CH₂O)ₙ—H;
R^{b} is H, C₁-C₁₂ alkyl, aralkyl, or C₁-C₁₂ alkoxy, wherein any of the alkyl groups is optionally substituted with one or more F atoms; and
R^{c} is 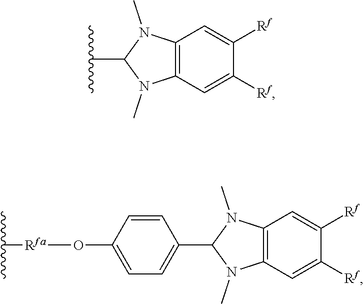
or
—CH₂N⁺R₃ X⁻ or —CH₂P⁺R₃ X⁻,
wherein R^{fa} is a chemical bond, thiophene, furan, pyridine, benzene, thiazole, or C₁-C₆ alkyl optionally having one or more oxygens substituted for carbon and optionally having one or more F atoms on the alkyl chain,
R^{f} is H, thiophene, furan, pyridine, benzene, thiazole, or C₁-C₆ alkyl optionally having one or more oxygens substituted for carbon and optionally having one or more F atoms on the alkyl chain,
R is C₁-C₆ alkyl and
X is halogen, bicarbonate (HCO₃⁻), carbonate, bisulfate (HSO₄⁻), bisulfite (HSO₃⁻), methane sulfonate (MeSO₃⁻), triethyl borohydride (Et₃BH⁻) or a C₁-C₆ carboxylate.

11. The polymer of claim 10, selected from a polymer containing N⁺ Ar, wherein N⁺ Ar is selected from the group consisting of 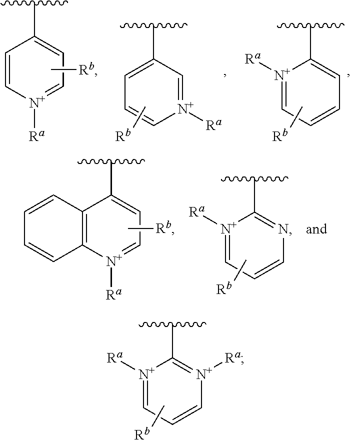
a polymer wherein R is buty; and
a polymer wherein R^{f} is H and R^{fa} is a bond.

12. The polymer of claim 1, wherein X is Br or F.

13. The polymer of claim 1, wherein X if F.

14. A dopant for use with a conducting polymer comprising the polymer of claim 1.

15. A composition comprising a conducting polymer and the dopant of claim 14.

16. The composition of claim 15, comprising about 75% of the dopant.

17. The composition of claim 15, wherein the conducting polymer has the structure 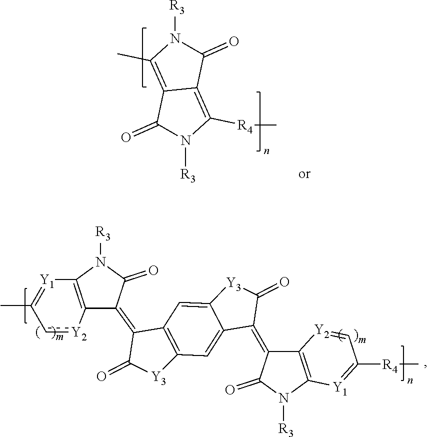
wherein Y₁ and Y₂ are independently —CH—, —S—, —O—, —N═, —NR₃—;
Y₃ is O or NR₃;
R₃ is C₁-C₁₂ alkyl optionally substituted with one or more F atoms;
R₄ is vinyl, acetylene, or a five or six membered aromatic ring optionally having one or two heteroatoms independently selected from N, S, and O; and
m is 0 or 1 such that,
when m is 0, Y₂ is —S—, —O—, or —NR₃—, and [symbol] is a single bond, and
when m is 1, Y₂ is —CH or —N═, and [symbol] is a double bond.

18. The composition of claim 17, wherein the conducting polymer is selected from the group consisting of 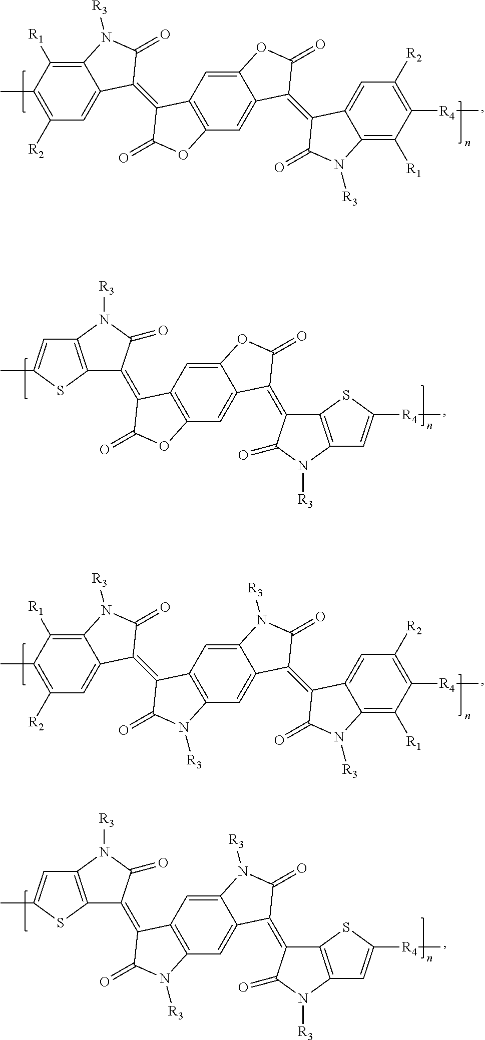 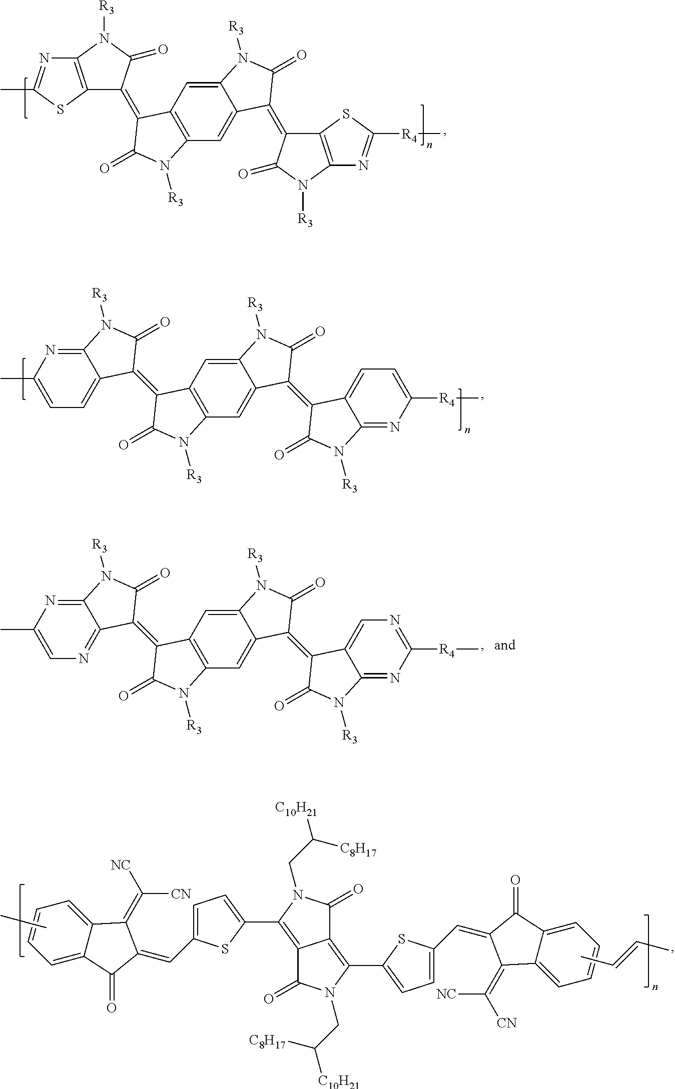
wherein,
R₁ and R₂ are independently H, a halogen, —CN, C₁-C₁₂ alkyl or C₁-C₁₂ alkoxy,
R₃ is C₁-C₁₂ alkyl optionally substituted with one or more F atoms,
R₄ is a five or six membered aromatic ring optionally having one or two heteroatoms independently selected from N, S, and O, vinyl or acetylene.

19. The composition of claim 18, wherein R₄ is selected from thiophene, furan, pyridine, benzene, thiazole, phenyl, or a derivative thereof.

20. The composition of claim 15, wherein the conducting polymer is

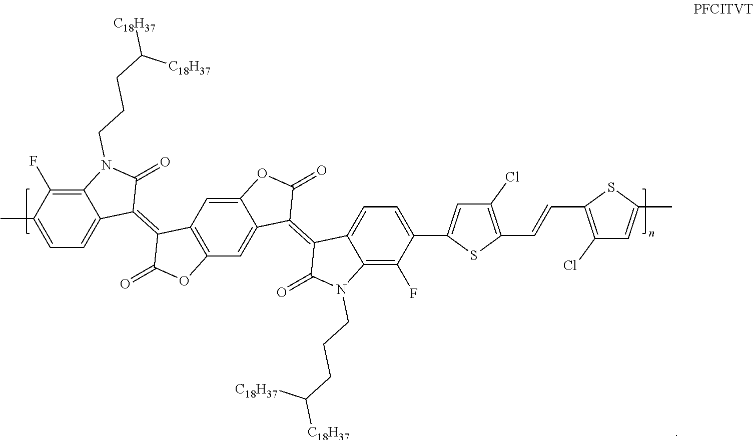

21. The composition of claim 15, wherein the dopant comprises

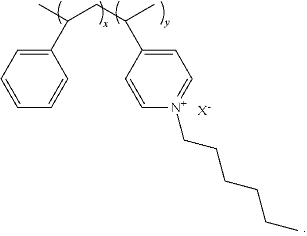

22. A polymer having the structure 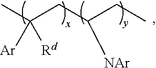
wherein NAr is a N-containing monocyclic or bicyclic aromatic ring having 1 or 2 N atoms and substituted with R^{b}, wherein R^{b} is C₁-C₁₂ alkyl, aralkyl, or C₁-C₁₂ alkoxy, wherein any of the alkyl groups is optionally substituted with one or more F atoms;
Ar is a phenyl or naphthalene ring, optionally substituted with R^{c}′ or CO₂Ph, wherein any of the phenyl or naphthalene rings is substituted with R^{c}, wherein R^{c} is H, C₁-C₁₂ alkyl optionally substituted with one or more F atoms, or C₁-C₁₂ alkoxy optionally substituted with one or more F atoms;
R^{d} is H or Me;
the ratio of x:y is from about 99:1 to about 80:20.

23. The polymer of claim 22, wherein NAr is selected from the group consisting of

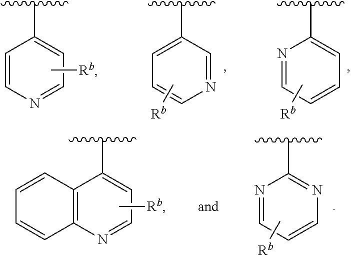

24. An electronic and/or electro-optic device comprising at least one polymer according to claim 1.

25. A device, comprising:
a first electrode;
a second electrode spaced apart from said first electrode; and
at least one of an electrically conducting or semiconductor material arranged between said first and second electrodes,
wherein at least one of said first and second electrodes comprises at least one polymer according to claim 1.

26. The device according to claim 25, further comprising a third electrode arranged proximate said active material,
wherein at least one of said at least one of an electrically conducting or semiconductor material is a semiconductor,
wherein said third electrode is a gate electrode,
wherein one of said first and second electrodes is a source electrode and the other of said first and second electrodes drain electrode such that said device is a transistor.
